(19) United States
(12) Patent Application Publication
(10) Pub. No.: US 2013/0285739 A1
(43) Pub. Date: Oct. 31, 2013

(54) Methods, apparatus and system to support large-scale micro- systems including embedded and distributed power supply, thermal regulation, multi-distributedsensors and electrical signal propagation

(71) Applicants: CORPORATION DE L ' ECOLE POLYTECHNIQUE DE MONTREAL, (US); UNIVERSITÉ DU QUEBEC À MONTREAL, (US)

(72) Inventors: Yves Blaquière, Chambly (CA); Yvon Savaria, Montreal (CA); Yan Basile-Bellavance, Montreal (CA); Olivier Valorge, Fontaine (FR); Ahmed Lahkssassi, Gatineau (CA); Walder André, Montreal (CA); Nicolas Laflamme Mayer, Montreal (CA); Mohamed Bougataya, Gatineau (CA); Mohamad Sawan, Saint-Laurent (CA)

(21) Appl. No.: 13/782,868

(22) Filed: Mar. 1, 2013

Related U.S. Application Data
(63) Continuation of application No. PCT/CA2011/050537, filed on Sep. 6, 2011.
(60) Provisional application No. 61/275,722, filed on Sep. 7, 2010.
(60) Provisional application No. 61/420,766, filed on Dec. 7, 2010.

(51) Int. Cl. H01L 25/00

(52) U.S. Cl. CPC H01L 25/00; H01L 25/50
USPC 327/565; 29/832

(57) ABSTRACT

The present invention relates to technologies for integrated circuits and Large Area Integrated Circuits (LAICs), which are integrated circuits made from photo-repetition of one or several reticle image fields, stitched together on at least one lithographic process layer. It also relates to a specific class of LAIC that can connect to the contacts of other ICs placed on its surface, where specific contact detection algorithms means are disclosed. The innovations include means for defect tolerance of serial communication links, means for efficient diagnosis of short and stuck-at faults in regular reconfigurable network, means for a programmable interposer for rapid prototyping of 3D stacked chips, means to build efficient large area micro-system devices (LAMS), with distributed and configurable hierarchical structures for power supply, thermal regulation and signal propagation, means to reduce mechanical/thermal/thermo-mechanical issues in LAMS devices, means to propagate analog signal on a configurable digital network, means to predict thermo-mechanical stress peaks.

The present application is a continuation of PCT/CA2011/050537 designating the United States, which claims the benefits of U.S. provisional application Ser. Nos. 61/275,722, filed on Sep. 7, 2010 and 61/420,766 filed on Dec. 7, 2010.

### STATEMENT REGARDING JOINT RESEARCH

The present invention was made under joint research agreements involving École Polytechnique de Montréal, Université du Québec à Montréal and Gestion TechnoCap dated Nov. 23, 2006 and Jan. 1, 2009 and expanded to include among the parties Université du Québec en Outaouais on Nov. 29, 2007 and a Financing and Invention Agreement between Gestion TechnoCap Inc. and Richard Norman dated May 6, 2006.

### FIELD OF THE INVENTION

The present invention relates to integrated circuits, and more particularly to integrated circuit interconnect devices and support circuits and devices for integrated circuit systems.

### SUMMARY OF THE PRIOR ART

This section is dedicated to explain the prior works on which the present technical contributions are based.

Prior Art of the Invention: Software and Hardware Strategies for Defect Tolerance in Large Area Integrated Circuit.

The size of an integrated circuit (IC) increases not only its cost, but also the probability that manufacturing defects appear on its surface. When the surface of an IC is that of an entire wafer, the probability to find at least one defect on the surface increases toward certainty. Not all defects cause dramatic global failure on the entire IC. Some defects are benign; some generates various faults such as opens, shorts, stuck-at-one, stuck-at-zero. Some defects can be overcome by defect-tolerant strategies.

It is not possible with current deep-sub-micron lithography to process an entire wafer as single reticle image. LAIC systems are fabricated with reticle image fields that span a maximum typical area of about 2 cm×3 cm. The size of a wafer is more than an order of magnitude greater than the biggest reticle image, so every Wafer Scale Integrated (WSI) design must take this into account and design a functional circuit composed of big “macroscopic” repetitive cells. The larger the reticle image field is, more defects can appear on each reticle image, so, each reticle-sized circuit must tolerate more defects.

Even for mature microfabrication processes, manufacturing defects significantly reduce the yield of large functional ICs. A conventional yield is the fraction of functional ICs produced without defect. Defects appear randomly on a LAIC, and most of the time they cannot be detected by visual inspection, so it is impossible to know where defects are located by means other than electrical testing. It is therefore required to add “test” phases in the workflow of the LAIC under production.

Fast fault diagnosis is needed by the microelectronics industry. Rapid test allows cutting diagnosis cost in the production chain and if done in a defect aware design flow, can be advantageous for increasing productivity. Also, a fast diagnosis algorithm applied in a defect aware design flow can make the difference between a product that is usable and one that is not from a user standpoint.

FIG. 1 depicts the simplest expression of a test or configuration system based on JTAG ports. In every JTAG test or configuration system, there is a test controller 101 (TC) associated with a unit under test 102 (UUT). The same basic configuration can be applied to any unit under configuration or unit under programming. UUTs are stimulated with test vectors and the responses are evaluated to decide if the UUT is functional or not. The test controller (TC) can be any software or any hardware able of controlling the emission of test vectors and the system under test responses. Then TC must decide or is used to decide if the UUT is functional and, if required. TC can make diagnosis or are used to support making diagnosis according to the data received from the UUT.

While FIG. 1 is the simplest possible topology, other architectures are possible. For example, FIG. 2 presents another well known boundary scan control architecture where the UUTs are daisy-chained in a ring. The first 202 UUT and the last 204 UUT are the only UUTs directly in contact with the 201 TC. This architecture offers an efficient access with a narrow port to an arbitrary number of UUTs. Moreover, it is relatively easy to program the 201 TC with this architecture. But the daisy-chained UUTs have a major vulnerability: if only one UUT in the ring is dysfunctional, the whole ring is not testable and not configurable, so the whole system becomes non-functional.

In general, a Test Controller (TC) takes into account that the links and the topology connecting UUTs together are static. The internal programming of a TC is based on the topology of the UUTs and the relative position of every UUT being known in advance and not changing.

FIG. 3 is another architecture known as the star architecture, where the TC 301 is directly in contact with all the UUTs (302,303,304). This architecture provides rapid test to all the UUTs, because they can be done in parallel. Moreover, this architecture resolves the vulnerabilities encountered with the daisy-chained UUTs. However, if there are N UUTs, the whole system requires a very large number (4N or 5N) of connections. If the JTAG trst* signal is included, every UUT needs 5 connections rather than 4.

A very good hybrid solution that offers the best of star architecture and the best of daisy-chain architecture is the multi-dropout architecture, as depicted in FIG. 4. In a multi-dropout testing architecture, the UUTs are not daisy-chained together, but are linked like memory chips on a bus. This requires special drop-out hardware 401 to be installed on each IC to enable random access for each IC connected to the bus. Each addressable UUT can receive test vectors from the test controller 402. Similarly the test controller can manage to receive test vectors coming from all UUTs in a one-to-one communication scheme. This solution is very desirable because it offers narrow access to all UUTs (403,404) and provides test acceleration and significant fault tolerance. But this solution requires an addressable multi-dropout module resulting in an increase of IC's area consumption.

If the multi-dropout bus contains a single fault, the whole PCB or IC is dysfunctional. However, if only a one-to-one link between ICs or between the IC submodule and the bus is broken, only that submodule and the components it contains are isolated from the test controller. To improve the robustness of the system, other busses can be added, so even if one bus is defective, the system is still testable in part. The multi-dropout architecture improves defect tolerance and test time compared to the daisy chained PCB test architecture.

Designing a system architecture that can survive multiple defects can be very profitable for complex and large systems. The loss of a large and dense system due to failure of the test hardware can be very expensive and can impact its profitability. For the same reason, large and complex systems are preferably designed to have sufficient defect tolerance.

Various methodologies are known to produce fault tolerant LAICs. By default, LAICs produced with advanced semiconductor manufacturing are complex systems in which multiple defects are expected with a high probability. For example, a laser restructuring process can give a second life to an LAIC if the fault is properly diagnosed. If the defect is located, laser fuse or anti-fuse previously installed in the LAIC can be used to disable defective zones. Consequently, enabling fuses or anti-fuses allow proper isolation of defective zone and activate new zones in the LAIC. This healing process can be applied as long as the capability and wiring resources still exist to perform such operations.

Another transistor level technique for fault-tolerant LAICs is using self-healing sub-circuits able to overcome a finite number of faults. This is complex to implement and it usually demands redesigning logic cells using full-custom circuit layout.

Fault tolerance can be achieved by software-based partial reconfiguration and duplication of vulnerable functionality. This method consists of diagnosing systems to know exactly where the faults are located. Once all faults have been located, a software-based control system can make a partial reconfiguration of the system to exclude faulty zones in the circuit. Assuming each vulnerable functional module is at least duplicated, it is possible to preserve the functionality of the whole system.

Another well known solution is to use a voting scheme to increase the probability to get a functional scan chain. A group of 3 TAPs (Test Access Port) control the same portion of the system. Each TAP is associated with one redundant scan chain for one cell of the system. Each group of TAPs produces a viable communication links to its adjacent cell, because the probability to have two dysfunctional scan chains or two dysfunctional TAPs in the same cell is very low. The use of a voting scheme allows the external controller to view the defect-tolerant scan chain as one scan chain, reducing reprogramming and redesigning cost on the controller level. This solution is patented by Savaria and Lu in U.S. Pat. No. 6,928,606 entitled “Fault tolerant scan chain for a parallel processing system” [2] and published in [3].

Test of interconnect traces between every IC soldered on a PCB can be done through so-called boundary scans. This has been standardized [53] and is a well known method to access and control from the outside all the input and output pins of every IC soldered on a PCB. A boundary scan chain (BS) can be set up using different methods. Another well known method is to connect all BS cells in a daisy-chain scheme or to have a set of test busses to get parallel access to ICs' JTAG ports (multi-dropout boundary scan control architecture). If every pin of every IC is associated to one unique BS cell and if the order of appearance of every BS cell is known in the scan chain, it is possible to achieve very efficient diagnosis by applying special test schemes.

Another well known method for PCB diagnosis is a “walking one” sequence that can be easily generated with special built-in hardware. The output from a counter can be connected to a NOR(OR) gate of the same width as the width of the counter output. The resulting generated sequential vectors are 1000 . . . (0111 . . . ). This walking sequence allows shorts and stuck-at fault (SA) detection. Diagnosis is possible provided that the location of every PCB input and output terminal is known in the scan chain. The walking one sequence is used as input sequence in the scan chain applied to every output terminal. A test compactor can be used to compress the data coming out of the PCB to improve test speed. Counting the number of “1” that comes out of the PCB is an efficient compression method.

Another example of method used for short and stuck-at fault detection and localization is the checkerboard method. Using boundary scan, and knowing the location of every boundary scan in the PCB and its respective order in the scan chain spanning the PCB, it is possible to diagnose shorts and stuck-at faults SAFs efficiently in log₂n time. The concept is to apply a special vector schemes on the PCB. Rather than a walking one vector scheme, checkerboard applies a sequence of decreasing periodic “cyclic” structure to every output terminal of the PCB. For example, with a PCB containing 8 output terminals, the test vector sequence is “11110000, 11001100, 10101010”. With 16 output terminals the test vector sequence is “1111111100000000, 1111000011110000, . . . ” and so on.

Using the concepts described above with proper modifications, improvement and adaptation for a regular reconfigurable network on chip (RRNoC) allows the design of an efficient diagnosis methodology. The difference between PCB test and diagnosis and RRNoC test and diagnosis lies in not all network on chip input and network on chip output being associated with a boundary scan. On the other hand, the network is by definition reconfigurable, so methods can take advantage of the network reconfigurability to improve its observability and controllability.

FPGA test and diagnosis methods have been proposed for finding faults (1) in configurable logic blocks (CLBs) and (2) in interconnect resources. Only fault diagnosis in interconnects relates to the present invention. A subdivision exists in each class of methods: fault diagnosis using the programmable fabric of the FPGA and fault diagnosis using DFT (design for testability).

There exist numerous papers (such as [4-7]) and U.S. Pat. No. 7,302,625 entitled “Built-in self test (BIST) technology for testing field programmable gate arrays (FPGAs) using partial reconfiguration” [8] covering the approach of fault diagnosis in interconnect resource using the programmability of FPGA. The key idea underlying this subclass of diagnosis methodology is to use the existing FPGA's configuration hardware infrastructure to auto-validate test of interconnects using a built-in self test (BIST) built from CLBs. The goal is to create as few as possible temporary and global data paths that travel along the FPGA to test interconnects. The number of configuration cycles can be optimized to make the diagnosis more efficient. FIGS. 5a and 5b show examples of such type of diagnosis. A TPG 501, 505 (Test pattern generator) and an ORA 503, 507 (output response analyzer) are the basic hardware of the BIST architecture. TPG and ORA are generated from the existing CLB resources. Multiple vertical/horizontal 504 and diagonal 506 wires are tested and evaluated using paths crossing various FPGA slices 502, as shown in FIG. 5a.

U.S. Pat. No. 6,966,020 entitled “Identifying faulty programmable interconnect resources of field programmable gate arrays” [9] discloses background information relating to “on-the-fly” diagnosis of FPGA interconnects. Test patterns are generated and this data travels via two or three identical groups of selected interconnect resources (called Wires under test (WUT)). If a difference is observed between two or three identical group of WUT, it proves that a fault exists somewhere in these WUTs. Then, the FPGA's interconnects can be reprogrammed and re-tested to narrow down the possible location of the faults. Based on this principle, searching can locate as precisely as possible faults in the network. Three identical groups are also used to allow multiple fault detection.

Design for testability principles have also been exploited in a second class of solution for diagnosing faults in interconnects. In this category, the main approach is to use power supply current (known as I_{ddq}) monitoring as a means for locating faults. As the test vector sequence is applied to the IC under test, if the I_{ddq} increases, then a bridging fault can be detected. Fault diagnosis using a search algorithm can be accurate enough to locate faults in interconnects, and bridging fault coverage of 100% is reachable with this technique. This method is very efficient for detecting faults in regular structures.

The present inventors have recently developed and published in [10] basic foundations of a test methodology related to the present disclosure.

As shown in FIG. 6, the WaferNet is part of the WaferBoard™ technology covered in U.S. Pat. Application Publication No. 2008/0143,379, entitled “Reprogrammable Circuit Board with Alignment-Insensitive Support for Multiple Component Contact Types” [1]. The goal of the WaferBoard technology is to improve the speed and quality of prototyping and validation phase of the design flow for digital systems. The core technology of the WaferBoard is a reconfigurable active substrate called WaferIC™. This LAIC system is obtained from photo-repetition of reticle field images. The WaferIC is a regular structure based on an array of cells each containing thousands of CMPIOs (Configurable Multi-Purpose I/Os). Therefore, a WaferIC is a sea of CMPIOs allowing easy and alignment-insensitive placement of integrated circuits (ICs), called user's ICs (uICs), on its surface. Each uIC's pins can be connected together through programming the WaferIC to create any netlist defined by the user. Therefore, the main function of the WaferNet is to interconnect uIC's pins to fit the topology of an existing netlist. Each WaferIC cell 608 is interconnected with its neighbor cells in the four directions 601, 602, 603, 604. Two programmable structures are represented in FIG. 6: a crossbar 609 and an array of 4×4 CMPIOs 610. In a possible implementation, two signals 611 can be redirected from at most two IC pin signals, contacted with CMPIOs, to other cells. All cells are daisy-chained and configured through custom scan chains 612, 613.

FIG. 7 shows examples of faults that could possibly occur in the WaferNet. The crossbars in cell 608 are depicted by rectangles and CMPIOs 605 are represented by circles. CMPIOs are shown in the illustration, but they are not considered as part of the WaferNet. Some interconnects 601 are depicted in this figure, but to simplify the abstract model of the WaferNet, not all interconnects are shown. Stuck-At 701 (SA) faults can be observed and detected in the network as well as shorts between parallel traces (704 and 702), and shorts between perpendicular traces (703). Traces are referred to as parallel traces if the overall directions that they carry signal in are substantially parallel.

The preferred embodiment of the configurable crossbar from the prior art is shown in FIG. 8. The crossbar is a real crossbar core 801 surrounded by dedicated hardware resource for test and diagnosis (an improved diagnosis methodology is proposed later in this disclosure). LFSR 802 can be used as a test pattern generator to test the crossbar alone. The MISR 806 shown in FIG. 8 plays the classical role of an output response compactor. A long scan chain 804 is used to configure the crossbar and a register 803 is used to trigger the state of the configurable crossbar in a “test state” or “normal state”. Every register (802, 803, 804, 806) surrounding the crossbar core can be daisy-chained together 805 as shown on FIG. 8, or can be part of a multiple scan chain depending of the design needs. Other types of test generators and compactors known in prior art could also be used. The main limitations with these relatively generic prior art solutions are the test time and diagnosis resolution.

The prior art includes a crossbar of 7 incoming interconnects and 7 outgoing interconnects in each four directions. Two signals can be redirected to at most two IC pin signals, therefore, m=2 and n=7 according to the convention of FIGS. 6 and 8. The formal representation of these crossbar input ports is CI_{0,[0 . . . 6]}, CI_{1,[0 . . . 6]}, CI_{2,[0 . . . 6]}, and CI_{3,[0 . . . 6]} respectively in the N-E-S-W physical directions. The crossbar output ports follow the same logic. This formal representation is depicted in FIGS. 9, 10 and 11.

In the prior art the basic walking-one diagnosis methodology is applied in 3 phases as explained in [10]. From each phase, a specific test type is applied. They are Test Type A, B, and C to refer respectively to phases A, B, C. Test Type A is depicted in the FIG. 9, test type B in FIG. 10 and test type C in FIG. 11. The same logical representation is used for these three figures. Examples of possible fault locations are shown in the figures and their resulting effects on the output signature are illustrated. Furthermore in FIGS. 9, 10 and 11, a notation such as L=(0, 1, 2, 4 . . . ) is used to differentiate long links from shorts links in the network For example, the long interconnect between the distant crossbar source and the CI_{3,3} input terminal crosses 4 cells (L=4) and the control scan coming from the input port CI₀ or CI₁ does not cross any cell (L=0) because it is included in the CUT.

Test type A: this test takes advantage of the available local control and observation registers to test concurrently each crossbar of the network. FIG. 9 depicts an example of test type “A” applied to a single crossbar 801 with a SA1 901 fault. Moreover, FIG. 12 shows the flowchart version of the algorithm. Both figures will be used to illustrate the test type A. The first step 1201 of the flowchart is to use reconfigurable capabilities of the network to configure all crossbars into a broadcast mode. Then, all crossbars must receive a walking ‘1’ on each crossbar input (1203, 1204, and 1205). The same process must be repeated for a walking zero to reveal the SA1 faults. All network crossbars 801 are configured in broadcast mode (one-to-all configuration). Test phase A consists of applying a ‘0’ and a ‘1’ on all crossbar inputs configured in a broadcast mode. Therefore, each ‘0’ or ‘1’ applied on a crossbar input port corresponds to a single test, and there are twice as many tests as there are crossbar inputs, i.e. 2(4n+m) tests. Two types of registers are depicted on FIG. 9. The first type, control register 606, is filled in black. The logical value forced on these registers is shown as an example and its resulting effect on the observation register 607. The black dot represents a SA fault 901. This SA1 fault is revealed as a ‘0’ and is applied to the crossbar input CI_{3,3}. All test results are shifted outside of the device under test for analysis.

Test type B (covered in the flowchart in FIG. 13) applies the walking ‘1’ concept to every control register of the network to reach a 100% test coverage and a good diagnosis precision by means of an intercellular scan chain 1301. It is well known that a walking ‘1’ test vector scheme is able to detect SA as well as shorts. Every walking one applied to each crossbar input implies a shift-out procedure. During the application of the walking ‘1’ 1004, all other control registers must force a ‘0’ in order to reveal all possible shorts associated with the control register and interconnects under test 1302,1303. Such precaution enables the diagnosis of shorts on any pair of interconnects (parallel or perpendicular). Concurrency can be added to the basic algorithm. FIG. 10 illustrates the effect on the observations registers (1005-1007) of multiple faults such as short 1009 or SA0 1008 and two SA1 (901) on the same path but not on the same interconnect. The SA1 901 fault in the crossbar masks the detection of a fault in interconnects. Outputs 1006 and 1007 are observation points where the effect of the short 1009 between two interconnects can be observed.

Test type C is depicted in FIG. 11. Test phase B is able to detect shorts and SA faults, but fails to locate precisely the SA fault. At this point, it is known that there is a fault associated to two test points in the network, but the faulty interconnect responsible of the detected fault is not known. Further algorithmic search must be implemented to get a precision that allows efficiently configuring the network around those faults. Test phase C is applied only to crossbar that triggered a SA fault. The same broadcast configuration is used for this test, but the control registers comes from the distant cells at the other end of the long interconnect. FIG. 11 shows a possible fault overlap between two SA1 faults. The first SA1 fault is located at 1003 and the second on 1002. The SA1 1002 can be detected with test type A and test type B that detect a fault interconnect path between the control register and the receiver, but fail to detect the 1003 fault. The example of FIG. 11 shows how it is possible to reveal the 1003 faults.

Test phase C begins with the test result from test phase A and B to generate a list of suspect cells 1401. In each suspect cell, a subset of suspect interconnects exist. Therefore, the next step 1402 is to create, for each suspect cell the list, a list named “ttp” of suspect interconnects. For each element of the list “ttp”, a unique network reconfiguration must be completed 1403. Each network reconfiguration is associated to a path, i.e. a set of activated interconnects between to distant point in the network 1404. At the end of the path is created the broadcast on the crossbar as explained earlier. Both broadcast “1” and “0” are applied on the crossbar. The result of the test can be shifted out 1405 to complete the defect map of the circuit 1407. It is important to notice that each suspicious cell can be tested concurrently because of the local nature of this test. However, if there are multiple suspect interconnects on the same cell, they must be tested sequentially.

It is known from previous work that the basic walking one approach is too slow to test and diagnose large networks. Improvements and new methods are needed to reach acceptable diagnosis efficiency.

A common use of logic diagnosis is to support fault tolerance of reconfigurable circuits. Knowing the precise location of faults in any homogenous and highly regular structure with reconfigurable capabilities permits the system to adapt to those faults. Fault tolerance (or defect tolerance) becomes an unavoidable topic as the scale of ICs is decreasing toward the physical limits of the photolithographic process. Furthermore, the increasing interest in wafer scale packaging and wafer scale integration system make defect tolerance a very important design issue to improve production yields.

Prior Art of the Invention: Configurable Interposer for Three Dimensional Large Area Integrated Circuits.

Three-dimensional (3D) chip integration is a means to create miniature, low-power and high-performance electronic systems. Significant improvements in performance of future electronic systems could be obtained from 3D chip stacks of at least two or more dies enabling dense, high-bandwidth and low-delay Z-axis interfaces between chips included in the 3D system.

3D stacked ICs are a very hot research topic [11-13]. There are already several 3D stacked ICs in production and the market is increasing significantly. A research and development roadmap has been proposed by the 3D stacked IC industry [14].

The main function of an interposer is to make mechanical and electrical connections between two layers. Interposers are used extensively in the microelectronic industry for three dimensional connections of integrated circuits (3D IC), such as in system in package (SiP), multi-dies stacks or multi-stack packages.

Designers working on 3D chip architectures face the major problem of increased power density. Power generates heat that must be channeled outside of the 3D structures. High temperatures create problems such as frequency throttling, increased noise, decreased chip life expectancy and degraded chip reliability. The disclosed configurable interposer with dynamic thermal management can alleviate thermal management issues.

Another problem created by heat appears in LAICs. Thermal gradients generate thermal stress in the silicon substrate. If the gradients are too large, it could result in breaking the silicon substrate and permanently damaging the system.

In 3D stacked ICs, multiple active die layers are stacked vertically and are interconnected together. Stacked layers are very densely interconnected making observation of 3D interconnects very difficult. Efficient and standardized tests of 3D stacked ICs are difficult to achieve. Furthermore, for the same reason, it is harder to diagnose faults in 3D stacked IC for devices being prototyped and devices under validation.

Several interposers used in 3D stacked ICs have already been patented. For example, U.S. Pat. No. 7,649,368, entitled “Wafer level interposer” [15] discloses an interposer that is designed to ease chip testability. This interposer is static and no configurable device is integrated. Other patents to protect special static interposers without active components are presented in the U.S. Pat. Application Publication No. 2008/0265,391 entitled “Etched Interposer for Integrated Circuit Devices” [16].

Some aspects of programmable interposers that map a packaged or unpackaged component's contacts to a different pattern have been disclosed in U.S. Pat. Application No. 2008/0143,379, entitled “Reprogrammable Circuit Board with Alignment-Insensitive Support for Multiple Component Contact Types” [1], and were based on the WaferIC™. This WaferIC™ is achieved by adding through-wafer vias for signal contacts as well as for power contacts. These programmable interposers can then map a component's contacts to a different pattern. This can be used, for example, to avoid redesigning a PCB when the contact pattern of a layer changes with a new generation of that layer, or when substituting a layer with a different contact pattern when assembling a PCB. Such an interposer is also used to adapt a component to a programmable PCB that does not support the contact type or spacing of that component. Using the alignment-insensitive contacts and programmable connectivity of the programmable interposer eliminates the need to have a custom interposer design for each component whose contacts are to be re-mapped. The configurable interposer is in fact an active substrate that can transmit data between any IC pins connected on this surface. The IC can be any CPU, microcontroller, FPGA or any IC whose pinout is compatible with the configurable interposer.

Several test methods exist that essentially control and observe many internal points and state bits through a limited of access points using some suitable protocol generally supported a controller or wrapper or some sort. Some are based on conventional scan often implemented using the IEEE1149.1 standard [53] that proposes Test Access Port and Boundary-Scan Architecture. Other standards extend the capability of the IEEE 1149.1 such as IEEE1149.6 [54] that includes AC-coupled and/or differential nets, IEEE1149.7 [55] that reduces the number of pins and enhances the functionality or the p1500 standard [56] that particularly supports a wide range of previously known test standards using a bus interface. This facilitates design, test and verification and provides a useful means of partitioning a system across large design teams.

Configurable Network on Chips (NoC) are extensively used in the SoC and FPGA industry to improve communication bandwidth and latency between various functional parts of the system. Configurable interposers offer a configurable network on chip that spans on the entire active surface of the interposers. This feature does not exist on any previously reported interposer.

Hardware assertion checking is becoming an important method to debug complex electronic systems in the semiconductor industry [17]. Hardware assertion checking is an efficient means to detect errors in complex digital systems where complex communication protocols are used. Circuits for assertion checking are synthesized in FPGA or in SoC logic and are embedded in devices under verification, and observe key signals to compare the actual circuit behavior with previously defined logical and temporal behavior of the design modeled in a high level language. In case of a fault in the hardware or a bug in the software, an assertion checker embedded in the device under verification can precisely identify the source of the problem in space (localized fault) and time (when the fault occurs according to what condition). Techniques already exist to create an efficient implementation (hardware synthesis) of assertions expressed in a high level language. But no existing system can program assertions in dedicated hardware inserted in a programmable interposer.

A scan chain spanning a whole 3D stack of chips is used to observe and force signals in a circuit for logical test of that circuit. As in the PCB industry, Design for Testability (DFT) is therefore used to test shorts and stuck-at faults between metal traces. At-speed observability and controllability of 3D stacked chips is hard to achieve because interconnects could be buried in the core of the 3D stacked chips. Therefore, the increased miniaturization of the 3D stacked chips makes at-speed DFT harder to achieve. No previous system offers the possibility to observe all the digital pins of all chips in the system.

Built-in self test (BIST) is a class of techniques through which a system can test itself using embedded electronic modules that generate test vectors and interpret the results locally in a circuit. BIST is extensively used in industry, but no existing interposer offers the possibility to program a BIST for rapid prototyping of DFT in 3D stacked chips. To diagnose problems encountered in some system under test, it is desirable to implement a BIST specialized for diagnosis; however, no existing interposer can configure an embedded BIST circuit dedicated to diagnosis of 3D stacked chips.

Prior Art of the Invention: Distributed Hardware and Software Strategy for Rapid Prototyping of Reliable and Energy-Efficient Three Dimensional Large Area Integrated Circuit System

Higher performance electronic systems are required by many applications. On the other hand, energy efficient electronic systems are becoming a strategic issue in electronics. For example, the market of portable devices is increasing every year and new products are designed demanding a very high level of performance for handheld devices. To maximize battery life, it is required to create energy efficient electronic systems. Furthermore, one of the most important challenges is to invest resources on research to develop new technologies that can make easier an evolution towards a more sustainable society. Reducing energy use of electronic systems can be very positive.

Electronic systems can be viewed as a set of heterogeneous interacting components. Some components are analog (e.g. a radio frequency filter circuit), some are purely digital (e.g. a CPU) and some contain electro-optical elements such as display. For example, a smart phone contains a central CPU connected to a cell phone, which is interacting with the user through a touch screen. Each component can be activated according to logical rules and according to the context. They can be activated in parallel or serially. They can be activated while a portion of the system is in a sleep state depending on the power budget.

To be competitive, an electronic system must be able to achieve peak performance on-demand [18]. The peak duration may not last for a long time. Therefore, components of the system can be forced into a sleep or idle state to minimize power consumption during most of the time. The ability to dynamically shut down and/or adjust the level of performance of each module is a way to reduce system energy consumption. Designing a system that is able to reconfigure its own state according to pre-defined rules to maximize energy efficiency is called dynamic power management (DPM). This methodology is used in portable devices, but increasingly used in stationary systems to create non-negligible energy savings in buildings, data centers, etc.

Extensive research has been done on Dynamic Power Management (DPM) to create more energy-efficient systems [18, 19]. The existing types of DPM are related to predictive capabilities of a PM (power manager) able to observe the components under its control. Most of the time, DPM policies are implemented in an operating system (OS). This class of methods is called OS Power Management (OSPM) [18]. The control and the intelligence needed to analyze data coming from the hardware in relation to DPM is done by the OS [20].

The power state machine (PSM) can be used as a model to represent the behavior of power managed components (PMC). Each state transition is associated to a power and delay cost. FIG. 15 represents an example of PSM where the PMC can be in one of three states. The Idle state (1501) is a low power and low performance state. The “run” state (1503) is the normal operation state where the maximum performance can be experienced. The state “sleep” (1502) is a state where the PMC does nothing except wait for a wake-up event; therefore, it must be a very low power state. This simple model can represent many types of PMC such as processors, disk drives, memories, wireless network end device.

Some conditions must apply in order to be able to save energy with the DPM design methodology [18]. The first condition is to have components that consume variable power during system operation. The second condition is to be able to predict the future workload of the most power hungry components of the system. The third condition is to be able to achieve such prediction with negligible power consumption. These conditions can be satisfied by observing signals that trigger shut-down or power-up events. Furthermore, it is required to use a Power Manager (PM) implementing the control of shut down and power-up of components. Such components are called power managed components (PMC). The set of all control commands for power managed components is called a policy.

A recent initiative, known as the advanced configuration and power interface (ACPI) standard, has been proposed by the industry [21]. This standard targets personal computer power and defines the interface between the motherboard and the control system, which is implemented in software. However, the standard does not provide specific DPM methods to improve energy efficiency.

Adaptive techniques for power management exist in the academic literature [22]. Adaptive techniques consist of learning from the statistical coverage taken from the past workload. When workload statistical behavior is changing over the time, the accuracy of the wake-up and shut-down predictions is directly compromised. In order to avoid predictive degradation, the DPM policy depends on a learning algorithm based on past events. Some existing learning algorithms were implemented in software part [23]. No existing method can capture data coming from the software and from any digital pin of the system to learn from the past workload because having observability on every pin of every system component has never been done before.

The existing DPM policies are very basic due to the complexity of the problem. The presented DPM are mainly used on personal computers and to apply a DPM methodology on other important electronic designs such as smart phones, telecom electronic systems, digital video or FPGA based systems [19].

Dynamic thermal management (DTM) is already a very well known research subject [18, 19, 24, 25]. This method can dynamically respond to temperature when it is larger than a certain threshold in 2D ICs or 3D stacked ICs by reducing processor power or other power manageable components. DTM pro-actively reacts to predicted thermal crisis by using scheduling algorithms, but inevitably with performance degradation.

Boulé et al. [17] have proposed the synthesis of hardware assertion integrated in ASIC or in FPGA designs. This specialization is relatively new and a lot of research must be done in order to achieve a high level of maturity.

Prior Art of the Invention: Differential Electrical Signal Propagation in Integrated Circuit Networks with Configurable Pair Location

The use of differential signaling is prevalent in high speed I/Os. Existing solutions include LVDS (low-voltage differential signaling), LVPECL (low-voltage positive emitter-coupled logic), CML (current mode logic), HSTL (High-speed transceiver logic) and many others [26].

A solution to propagate a differential signal on a LAIC has already been proposed [24], however, such approach does not offer spatial reconfiguration as needed by the system.

Several electrical and physical constraints to support differential signaling must be met. Differential buffers transmit two different signals that are compared at the receiver end. The configurable interface must support a pair of balanced input signals and a pair of balanced output signals to transmit differential data. The differential signal quality is strongly dependent on the symmetry between the complementary signals. Dissymmetry induces jitter between the two differential signals and can lead to loss of the transmitted information. Very stringent jitter constraints exist for most high-speed interfaces. For example, in the PCIe transmission protocol, 30 percent of the bit length is the maximum allowed jitter [27, 28], which represents a jitter of 120 ps for a data rate of 2.5 Gbps. This very short propagation time difference can be caused by slight length or load dissymmetry between paired signal paths.

Proper signal integrity is required to propagate high frequency differential signals on long PCB traces, to avoid wave reflections, attenuations as well as parasitic couplings [27]. This is typically achieved with impedance matching at every level of the transmission chain. In a configurable integrated interconnection system, there is no PCB trace and the input and output driver impedances of the configurable differential interface need to match the uIC (user IC) input/output differential pin impedances in order to meet their input and output specifications. The input/output impedances in differential signaling are typically set to 50 Ω [27]

Prior Art of the Invention: Apparatus and Methods to Sustain Thermo-Mechanical Stability in Large Area Integrated Circuit Systems

Prior Art of the Invention: Smart Thermo-Mechanical Prediction Unit and Monitoring Methods to Reliably Sustain Transient Thermo-Mechanical Stress Peaks in LAIC (Large Area Integrated Circuit) Systems

Wafer-scale integrated circuits provide the advantage that interconnections between different sub-circuits on the wafer are made during manufacture of the wafer. The number of handling steps and the manufacturing time are then reduced.

Furthermore, wafer-scale integration allows faster switching speeds since the interconnection lengths on a wafer between the subcircuits are shorter than interconnections and bonding wires in classical printed circuit board technologies.

Wafer-scale integration is a way to implement the so-called more than Moore's law scaling, since a variety of functions can be implemented on the same wafer that is much larger than a conventional IC using standard lithographic technologies.

Wafer-scale integration offers the possibility of getting a large and unique active surface useful for many different applications such as high resolution display, high resolution sensor arrays or high resolution configurable network array.

The rapid development of semiconductor technology [41] has enabled integration of entire electronic systems on a single chip. Today's systems on chip (SOCs) can be designed to incorporate mixed-technology, including high-performance/low-power logic, analog, embedded SRAM/DRAM, radio frequency (RF) modules, micro-electromechanical systems (MEMS), and optical electronic systems [42].

From a mechanical perspective, ICs can be thought of as composite structures (multilevel) fabricated from highly dissimilar materials. These structures are commonplace in the electronic industry. Because these structures are made of materials that have different properties, specifically different coefficients of thermal expansion (CTEs), thermal stresses, distortion and warping are a source of concern. Additional thermally induced stresses can be produced from heat dissipated by local high power density during normal operation.

A main reliability challenge is to ensure transient thermo-mechanical stability in LAIC systems due to the multiple embedded heat sources and the presence heterogeneous materials assembled in a multi-layer structure. Typically, different materials will tend to have mismatches in Thermal Coefficients of Expansion (TCEs).

Heat expansion and contraction due to circuits operating can result in buckling and cracking of a LAIC system, particularly a full-wafer LAIC if attached to a rigid substrate. Performing experiments to measure or predict the stress and temperature generated in the multilevel devices using some finite element analysis tool is costly, time consuming and device dependant.

Transient thermo-mechanical stress issues are critical for large ICs industry. Thermal expansion and contraction due to the circuits performing normal operations can result in localized peak stress and cracking of the device, particularly in LAIC systems if they are supported or fixed to a rigid substrate or if such systems are insufficiently cooled.

Several mechanisms are used to measure temperature and stress in integrated circuits. U.S. Pat. No. 6,453,218 entitled “Integrated RAM Thermal Sensor” [29] discloses a method and apparatus for an integrated thermal sensor to regulate the temperature of RAM devices. This uses traditional techniques such as a diode to sense temperature variations to create an analog signal which will be converted into a digital signal prior to being sent to an external host computer for data processing.

Embedded test structure methods in U.S. Pat. No. 5,625,288 entitled “On-chip high frequency reliability and failure test structures” [43], use Self-stressing test structures for realistic high frequency reliability characterizations. An on-chip high frequency oscillator, controlled by DC signals from off-chip, provides a range of high frequency pulses to test structures. The test structures provide information with regard to a variety of reliability failure mechanisms, including hot-carriers, electromigration, and oxide breakdown. The system is normally integrated at the wafer level to predict the failure mechanisms of the production integrated circuits on the same wafer.

U.S. Pat. No. 5,639,163, an “On-chip Temperature Sensing System” [30], makes use of a differential pair of diodes to collect the temperature, and of two external resistors responsible to generate a constant current injected in each diode.

Moreover, in U.S. Pat. No. 4,768,170, a “MOS Temperature Sensing circuit” [31] formed on the silicon substrate has been disclosed. This circuit uses two diodes with different sizes, and exploits the canceling effect of the leakage current of a smaller diode with respect to a larger diode whose leakage is due to process variations; therefore creating a temperature dependent circuit.

As with thermal sensors, many ways to sense pressure have been disclosed, including the “Capacitive pressure sensor” of U.S. Pat. No. 4,322,775[32]. The use of capacitances as a transducer was very well documented in the past. Some of them are used in applications such as the “Silicon Pressure Sensor” defined in U.S. Pat. No. 4,317,126 [33].

Recently the tracking thermal mini-cycle stress method was used [44]. With this method, temperature excursions of an assembly experienced over its life is disclosed. A modifier value for a figure of merit (FOM) value is computed and added to a cumulative figure of merit value. In response to the cumulative figure of merit, values exceeding the cumulative stress figure of merit budget are proposed as a stress management solution.

Due to aggressive technology scaling, VLSI integration density as well as power density increase drastically. For example, the power density of high performance microprocessors has already reached 50 W/cm² at 100 nm technology and it will reach 100 W/cm² at 50 nm technology [45]. This evolution towards higher integration levels is motivated by the needs of advanced high performance, lighter and more compact systems with less power consumption. Meanwhile, to mitigate the overall power consumption, many low power techniques such as dynamic power management [46], clock gating [47], voltage islands [48], dual V_{dd}/Vₜₕ [49] and power gating [50, 51] were recently proposed.

These techniques, though helpful to reduce the overall power consumption, may cause significant on-chip thermal gradients and local hot spots due to different clock/power gating activities and varying voltage scaling. It has been reported in [52] that temperature variations of 30° C. can occur in a high performance microprocessor design. The magnitude of thermal gradients and associated thermo-mechanical stress is expected to increase further as VLSI and SoC designs move into nanometer processes and multi-GHz frequencies.

An important issue with VLSI systems and micro-systems is how to perform its thermal monitoring, to detect overheating, without complicated control circuits. The traditional approach consists of distributing multiple sensors over a chip, and then reading their outputs simultaneously and comparing them to a reference voltage recognized as the overheating level.

Prior Art of the Invention: Propagation of Analog Signals on a Digital Interconnect Network and Support for Analog Signals

More and more integrated circuits use analog pins to read or provide analog signals. For instance, several state-of-the-art processors that are landmark digital ICs such as the Intel Pentium 4 and Pentium M [34], as well as IBM PowerPC [23], use on-chip thermal sensors to monitor in real time their thermal profiles [28]. While some systems such as the POWER5 processors from IBM [35] uses digital thermal sensors based on a ring oscillator whose actual frequency increases with temperature, other used analog thermal sensors which are based on temperature-sensing diodes and whose output is a current whose intensity is temperature-controlled.

Several well known circuit techniques can be used to build Analog-to-Digital converters to convert the signals from analog to digital [36-38], such as direct conversion, successive-approximation, ramp-compare. Wilkinson, multi-slope, pipeline, Sigma-Delta conversion [30] and with intermediate FM stage.

Well known circuit techniques can also be used to build Digital-to-Analog converters to convert the signals from digital-to-analog [37-39], such as pulse-width modulation, oversampling, interpolating, binary-weighted, R-2R ladder and thermometer-coded.

Analog signals are important even in predominantly digital systems. While an interconnect network propagating analog signals could be implemented in parallel with a digital networks to transmit these analog signals, the capabilities of analog networks are limited (due to noise, crosstalk, delay, as well as voltage, current, and frequency range). A dedicated parallel analog network would also be costly and very frequently left unused in predominantly digital systems.

One way to perform Analog-to-Digital (ND) or Digital-to-Analog (D/A) conversion is to use of a voltage controlled oscillator (VCO). Some VCOs convert analog signals into a digital stream or a signal whose frequency varies with the magnitude of the analog input signal. A frequency to analog conversion can then be done at the destination. A similar conversion principle can be applied with delta-sigma modulation.

Integrated circuit, as depicted by 9401, 9402, 9403 in FIG. 94, comprises several surface contacts 9404, typically called pads. A surface contact is used to electrically contact one or more internal circuits to one or more external circuits. It can be used to feed power to the integrated circuit substrate, typically through so-called power pads. It can also be used to inject and/or extract signals into/from the surface contact, typically through so-called Input/Output pads.

### SUMMARY OF THE INVENTION

The present invention relates to tools and methodologies for interfacing with large area integrated circuits (LAIC), made from photo-repetition of one or more reticle image fields, and large area Micro-Electro-Mechanical Systems (LAMS).

The present invention can also be applied to any WSI (wafer scale integrated) system.

The present invention can also be applied to three dimensional stacked integrated circuit systems.

The present invention also relates to electronics serial communication systems needing robust defect tolerant features to improve production yields.

The present invention also relates to electrical signal propagation supporting configurable differential interconnects stage in LAIC.

The present invention also relates to distribution of power supplies integrated in LAIC structures.

The present invention also relates to massively distributed sensors integrated in LAIC structures and tools and methods to improve the reliability and integrity of the power distribution.

The present invention relates to supporting and supplying large area micro-systems (LAMS) and is particularly well suited for the WaferBoard™ defined in U.S. Pat. Application Publication No. 2008/0143,379, entitled “Reprogrammable Circuit Board with Alignment-Insensitive Support for Multiple Component Contact Types” [1].

The present invention also relates to hardware architecture and algorithms to locate short and stuck-at faults for efficient diagnosis in LAIC.

The present invention also relates to tools and methods for prototyping LAMS.

The present invention also relates to distributed analog-to-digital converters (or a subset of) and digital-to-analog converters (or a subset of) that are linked by a configurable digital interconnect network to propagate analog quantities.

The present invention relates to predicting and monitoring transient thermo-mechanical stress peaks in LAIC (Large Area Integrated Circuit) systems and it also relates to monitoring methods to sustain transient thermo-mechanical stress peaks that can affect system reliability.

It is an object of the present invention to provide a generic architecture of defect tolerant scan chain that is robust to manufacturing defects in LAIC. That scan chain supports test and diagnosis under the control of software or embedded hardware possibly located in an external computer.

It is a further object of the present invention to add recovering capabilities for one or more scan chain included in LAICs.

It is an object of the present invention to provide a configurable scan chain bus that can make bifurcation, loop back and direct access by “jumping above” an arbitrary number of cells in the scan chain by having a random access port to the input or output of any cell.

It is a further object of the present invention to provide a configurable scan chain bus that can be configured by external software or one or more embedded controller.

It is a further object of the present invention to provide a configurable scan chain that is divided into one or several modules, each having its own TAP controller, input and output data ports.

It is a further object of the present invention to provide modules in the configurable scan chain, with defects seen at the input data ports, to be replaced by extending the scan chain until it reaches a module with a functional input port. The same strategy can be applied to the output port.

It is a further object of the present invention to provide modules in the configurable scan chain, with defects seen at an output data port that can use another output data port to complete the scan chain.

It is an object of the present invention to provide physical links between input and output ports of adjacent modules, each controlled by an external controller or software, deciding how to activate these links to built a single macroscopic scan chain spanning all modules in a LAIC.

It is an object of the present invention to provide a TAP controller in each module that can potentially control its adjacent modules that has a faulty TAP controller.

It is an object of the present invention to provide a power domain supplying one or several modules in the LAIC to its adjacent modules.

It is an object of the present invention to provide independent clock or reset trees for each module in a LAIC to build fault tolerance onto these critical signals.

It is an object of the present invention to provide fault tolerant clock trees in a LAIC so that faults affecting clock trees branches do not compromise the integrity of the whole tree, but stay located to the defective branch and its associated children, and to avoid a defect at the root of the clock tree causing failure of the whole clock tree.

It is a further object of the present invention to provide independent clock trees (or a tree used for signal with large fanout) for each module in a LAIC, and share the clock root signal to ensure that when a clock root signal is blocked by a fault, a functional clock tree shares its root signal to the faulty tree to recover from its breakdown.

It is a further object of the present invention to provide independent clock trees for each module in a LAIC and to share the successive children from the root of the clock tree to ensure that when a branch of the clock tree is defective, the clock signal from the same branch level of the clock tree can be used instead to drive the children of the defective branch.

It is a further object of the present invention to provide a diagnosis algorithm capable of locating all the faults included in the configurable scan chain network.

It is an object of the present invention to provide several possible paths to link all functional modules in the configurable scan chain of a LAIC, to bypass or go-around a faulty link or faulty TAP that is blocking a path according to a map of defect locations.

It is a further object of the present invention to provide a software mechanism to register one or several of these paths in a database, that behave as a standard scan chain, i.e. that can be used to test and configure the non-defective modules on each path.

It is a further object of the present invention to provide a mechanism to extract paths in the database to know how the modules with their respective TAP controllers are linked together to properly generate the data stream and to properly interpret the data stream that comes out of the path.

It is a object of the present invention to provide for the configurable scan chain different ways to implements inter-TAP connections that can each be configured by control software: the CICU link (configurable inter-cell unidirectional link), the CICB (configurable inter-cell bidirectional) link, the RA link (random access link).

It is a further object of the present invention to provide the CICU link (configurable inter-cell unidirectional link) for inter-TAP connection that does not allow a path to return back to a used module.

It is a further object of the present invention to provide the CICB (configurable inter-cell bidirectional) link for inter-TAP connection that can make a link to its neighbor modules and can receive a feedback from them.

It is a further object of the present invention to provide the RA link for inter-TAP connection that creates links via a bus, where each bus is connected to more than one TAP controller, enabling parallel access or the serial information to jump directly and randomly from a module to a distant module, requiring a special multi-dropout module.

It is an object of the present invention to provide the mechanism to control the internal resource of a module in the configurable scan chain from the module's TAP controller or from a TAP controller in adjacent modules to increase the robustness of the fault-tolerant capabilities of a configurable scan chain.

It is an object of the present invention to provide different combination of defect tolerant strategies (CICU link, CICB link, RA link, external control, clock sharing) that can be adapted to a particular implementation of the configurable scan chain.

It is an object of the present invention to provide diagnosis strategies for regular reconfigurable network (RRN). Most of the diagnosis methodologies are currently done using stimulation on every I/O port of an IC to increase the speed of the diagnosis. It is an object of the present invention to provide a software-based fault diagnosis methodology requiring a smart diagnosis controller to optimize the test sequence according to the collected data from the configurable scan chain.

It is a further object of the present invention to provide three main classes of solutions to effectively diagnose faults in the RRN. The common basis to all three methods is the limited control used to perform tests. Only JTAG ports are used or multiple scan chains can be used in parallel. The main class of solutions are: (1) Optimized and concurrent diagnosis with versatile fault tolerant scan chain (2) concurrent BIST with multiple scan chain (3) BIST and ring signal propagation.

It is also an object of the present invention to provide test and diagnosis using versatile reconfigurable scan chains such as with CICU, CICB and RA link architectures, to make the diagnosis more robust to defects as well as faster by the use of cells connected together by daisy scan to configure only a specific crossbar and a very specific register in the crossbar.

It is also an object of the present invention to provide techniques to test short faults. A significant increase in test speed can be reached with this technique.

It is also an object of the present invention to provide methods that use the reprogrammability of the network to create rings of any form, particularly closed loops, and associating a test pattern generator (TPG) that plays the role of the transmitter and a response analyzer playing the role of a data receiver is associated with each ring.

It is an object of the present invention to provide a third class of methods using a concurrent BIST architecture with multiple scan only.

It is an object of the present invention to provide a new domain of application of the walking one diagnosis can be applied to detect and locate shorts in a matrix of CMPIO integrated on various kind of LAIC.

It is an object of the present invention to provide a new kind of interposer containing advanced design for testability and diagnosability modules to accelerate the test and diagnosis of 3D IC circuit or 3D LAIC.

A further object is to accomplish these objectives with interposer that embeds configurable logic cells to create intelligent and dynamic power and thermal management.

Yet a further object to accomplish this objective with an array of identical cells that spans the entire active surface of an interposer.

Another further object is to accomplish these objectives with multiple cells that use the CMPIO (Configurable Multi-Purpose I/O) technology enabling alignment insensitive interconnection between IC dies deposited on the interposer.

It is an even further object of this invention to combine this interposer with embedded configurable logic cells that spans its entire active surface with CMPIO technology with a fault tolerant JTAG configuration system such as the versatile serial communication system as disclosed above in the configurable interposer.

It is a further object of the present invention to provide configurable interposers that can be used as a means to interconnect heterogeneous LAICs stacked in a 3D structure. A yet further object of the invention is to accomplish this with interposers interconnected through configurable crossbars to create a configurable 3D network of interconnects. A yet further object of the invention to provide a configurable interposer where configuration is controlled by software. This software supports on-the-fly reconfiguration of the network that enables rapid prototyping of systems embedding 3D stacked chips or 3D stacked LAICs.

It is a further object of the present invention to provide programmable assertion checkers embedded in a LAIC.

It is a further object of the present invention to provide programmable assertion checkers embedded in a configurable interposer.

It is a further object of the present invention to provide observability on the majority of electronic system pins using a special network for System on Chip (SoC) that posses the ability to redirect a large number of signals to external software able to analyze the captured data.

It is also an object of the present invention to provide programmable logical cells integrated in the LAIC or in the configurable interposer that can emulate the behavior of complex Built-In Self Test (BIST).

It is yet an object of the present invention to provide for wafer-scale integrated circuit and especially 3D stack of chips, dynamic thermal stress management to avoid the silicon crystal to break because of temperature gradient. Implementation of the dynamic behavior can be done by means of temperature sensors. A further possibility is to have an array of local controller that generates heat with a special resistive heating circuit to get the temperature gradient smoother along the substrate XY, XZ and YZ planes. Dynamic thermal stress management can be implemented inside the configurable interposer or inside any type of LAIC

It is yet an object of the present invention to provide a system capable of supporting advanced computer-aided design for rapid prototyping of digital low power electronic systems.

It is further an object of the present invention to provide ability to the computer-aided design tool to get signal data (observability) from every I/O pins and current consumption on every VDD pins.

It is therefore an object of the present invention of knowing the current consumption and the voltage level through a dense array of current sensor and voltage sensor that allows the CAD tool to be aware of the real-time power consumption of the system under prototyping developed with a configurable interposer or a WaferIC.

It is yet an object of the present invention to provide a LAIC or a configurable interposer with an array of temperature sensors.

It is an object of the present invention to provide algorithms applicable on the electronic system under prototyping to minimize the applied voltage level of every PMC and digital IC of the system.

Another object of this invention is to provide passive and active: mechanical, thermal and electrical solutions to support and allow the correct operation of any fragile and thin Large Area Micro System (LAMS) and wafer-scale integrated circuits.

A further object of this invention is to allow the implementation of a high-density programmable system board that includes a wafer-scale integrated circuit (WaferIC), a fault tolerant interconnect network implemented on the WaferIC, called WaferNet, and a circuit that allows detecting ICs laid over the WaferIC.

It is therefore one object of the present invention to provide a stable mechanical support to Large Area Micro-Systems (LAMS) that includes large area integrated circuits, large area Micro-Electro-Mechanical Systems (MEMS) and Nano-electro-mechanical systems (NEMS) that can compensate thermal and mechanical stresses applied to the large and fragile LAMS substrates, stresses due to difference between different coefficients of thermal expansion (CTE) of material or due to applied external mechanical stresses.

It is a further object of the present invention to provide a mechanical and electrical support to LAMS devices by keeping their active surfaces clean of any mechanical or electrical components.

It is a further object of the present invention to have active and passive thermal devices that efficiently evacuate the heat generated by the normal activity of LAMS devices.

It is also an object of the invention to have a smart network of embedded thermal and pressure sensors distributed on the whole surface of LAMS device to get feedback of the thermal behavior of the supported application and then to enhance its operations by adjusting some parameters such as its power supply voltages, its power consumption, its operating speed, its clock frequencies or other system parameters that can be externally configured and tuned.

It is a further object of the invention to have a network of embedded programmable heaters and coolers distributed on the whole surface of the LAMS device to smooth its surface temperature distribution and then to avoid thermal spots and high thermal gradients which can cause local mechanical breaks, operating dysfunctions or variations.

It is yet further object of the invention to provide several programmable AC-DC and DC-DC voltage converters and robust ground planes needed to support operation of the electrical features of the supported LAMS devices.

It is another object of the invention to have a network of programmable voltage regulators and passive electrical devices distributed on the whole surface of the LAMS device in order to provide hierarchical power supply that is programmable, stable and provides good signal integrity.

It is also an object of the invention to provide power from one side of the LAMS device through Through Silicon Vias, to free up the other side.

It is an object of the present invention to have a network of embedded electrical (voltage, current, radiations) and physical (temperature, pressure, stress . . . ) sensors distributed on the whole surface of the LAMS to get feedback on physical and electrical spatial distributions of the supported application and then to enhance its operations by adjusting some of its controllable external parameters.

It is an object of the invention to provide all electronic circuitry, electrical connections and structures needed to generate, to probe, to propagate, to amplify or to process any electrical signal generated or needed by the supported LAMS device.

It is also an object of the invention to provide a mean to support differential electrical signal propagation in the supported LAMS device.

It is a further object of the present invention to provide a network of programmable circuits and passive devices distributed on the whole surface of the LAMS device needed to generate, to probe, to propagate, to amplify or to process any electrical signal generated or needed by the supported LAMS device.

It is a further object of the invention to provide methods and apparatus to leverage configurable digital interconnect to propagate analog quantities.

It is a yet further object of the invention to provide method and apparatus to leverage configurable digital interconnect to propagate analog quantities by using distributed analog-to-digital converters and digital-to-analog converters that are linked by a configurable digital interconnect network to propagate analog quantities.

It is also one object of the present invention to propagate analog signal through dedicated metal grids (typically used for power supply distribution) coupled with large transmission gates. That option is of interest when such metal grids are not used for their primary intended purpose.

It is therefore one object of the present invention to provide a thermal sensor cell network and dynamical thermal peak prediction to control thermal stress on a Large Area Integrated Circuit system.

It is a further object of the present invention to provide LAIC systems with a configurable temperature sensor cell network embedded into a LAIC use data provided by the temperature sensors network in a dynamical thermal management policy.

It is a further object of the present invention to have active and passive thermal devices that efficiently evacuate heat generated by the normal activity of devices in a LAIC system.

It is a yet further object of the present invention to provide a smart thermo mechanical prediction unit and peak stress monitoring to control transient thermal stress in LAIC systems.

It is also an object of the present invention to provide LAIC systems with temperature sensor arrays and smart thermal stress prediction units, embedded into LAICs, and a further object to use data provided by these sensor cell networks in a dynamic management policy to increase the reliability of the LAIC system by adjusting some parameters such as its power supply voltages, its power consumption, its operating speed, its clock frequencies or other system parameters.

It is therefore one object of the present invention to provide a stable mechanical support to the LAIC system.

It is a yet further object of the present invention to provide a configurable sensor cells to 3D LAIC system.

It is a further object of the invention to have a network of embedded configurable sensor cells distributed in LAIC system or LAIC to predict its peak surface temperature location and then to avoid thermal spots and high thermal gradient which can cause local mechanical break, device operating dysfunctions or electrical parameter variations.

The present invention also relates to methodologies to make integrated circuit components that include surface contacts for making contact with a plurality of integrated circuit components. These surface contacts typically receive and process external data from said surface contacts and drive some other surface contacts with processing results. The integrated circuit component may or may not be a LAMS or LAIC. When the integrated circuit is not a LAMS or LAIC, the wafer from which it is derived is separated in dies embedded into packages protecting them from scratches, from environmental conditions and providing mechanical strength facilitating manipulation by humans or by system assembly equipments. The pads of the die are normally connected to external pins or balls through embedded conducting paths to make further contact to system integration technologies such as printed circuit boards or multiple chip modules that allow connecting together multiple pins or balls from the same chip or from different chips

It is an object of the invention to have a network of programmable voltage regulators and passive electrical devices distributed in the integrated circuit component in order to provide hierarchical power supply to internal and external components that is programmable, more stable and that provides better signal integrity.

It is an object of the present invention to have a network of embedded electrical (voltage, current, radiations) and physical (temperature, pressure, stress . . . ) sensors distributed in the integrated circuit component to get feedback on physical and electrical spatial distributions of the supported application and then to enhance its operations by adjusting some of its controllable external parameters.

It is an object of the invention to provide all electronic circuitry, electrical connections and structures needed to generate, to probe, to propagate, to amplify or to process any electrical signal generated or needed by the integrated circuit component.

It is a further object of the present invention to provide a network of programmable circuits and passive devices distributed on the whole surface of the integrated circuit component needed to generate, to probe, to propagate, to amplify or to process any electrical signal generated or needed by the supported integrated circuit component.

It is further an object of the present invention to provide the ability to get signal data (observability) from every I/O pins and current consumption on every VDD pins.

It is a further object of the invention to provide methods and apparatus to leverage configurable digital interconnects to propagate analog quantities in the integrated circuit component.

It is a yet further object of the invention to provide methods and apparatus to leverage configurable digital interconnect to propagate analog quantities by using distributed analog-to-digital converters and digital-to-analog converters that are linked by a configurable digital interconnect network that can propagate analog quantities by digital means.

It is also an object of the present invention to propagate analog signals through dedicated metal grids (typically used for power supply distribution) coupled with large transmission gates. That option is of interest when such metal grids are not used for their primary intended purpose.

### DEFINITIONS

The following definitions are provided in an alphabetical order to facilitate searching.

By the expression “Alignment-insensitive” as used herein is meant not rendered inoperable by small changes in placement or angle of something affixed relative to what it is affixed to.

By the expression “Alignment-insensitive contacts” is meant an array of substrate contacts of a size and spacing such that components can be placed in registration anywhere within the array of substrate contacts such that at least one of the substrate contacts will be in contact with each one of the component contacts and none of the substrate contacts will be in contact with more than one of the component contacts. Switch circuitry can be used for selecting substrate contacts in contact with component contacts for providing an interconnecting path for the component contacts to other devices.

The expression BIST as used herein is the acronym for Built-In Self-Test. BIST is often used as the name of an embedded electronic sub-module that permits an IC to test itself. The BIST technique is used to improve test time and reduce test cost, reducing the demand for external test equipments (ATE). Properly designed, BIST can be used for defect diagnosis.

The expression “boundary scan” as used herein is a scan chain inserted in IC input and output pins to create control and/or observation points otherwise difficult to access by other means. Boundary scan cells can collect data from IC pins or force data or signals on IC pins

The expression “cell” as used herein refers to a hardware module that is instantiated/printed/fabricated on the substrate of an IC.

The expression “CHAC” as used herein is the acronym for Configurable Hardware Assertion Checker.

The expression CMPIO as used herein is an acronym for Configurable Multi-Purpose IO. A CMPIO array forms an array of tiny pads with respective dimensions of the order of 50 μm×50 μm and even smaller for subsequent generation of the same technology. CMPIOs can provide data and power to other devices. CMPIOs can be configured as floating, as digital or analog input/outputs, as power supplies or as ground.

The expression “defect” means a physical alteration on a circuit as compared to its designed parameters. A fault, which is a logical discrepancy over the specified behavior, is often, but not always, the consequence of a defect. Not all defects cause faults, and not all faults are visible to some user on the system boundaries.

The expression “Defect tolerant architecture” as used herein means an architecture that can be reprogrammed or reconfigured to avoid one or more dysfunctions of a system due to defects in its fabrication process.

The expression “diagnosis” as used herein is the process of locating faults.

The expression “direct contact” as used herein means an electrical contact between balls, pads or surface contacts of integrated circuits through IC pins, where an IC pin touches directly another IC pin. Electrical contact in a direct contact can be made through any short conductive material, such as a metallic ball or a Z-axis film with embedded conductive paths.

The expression “fault” as used herein means a behavior of an electronic circuit that departs from the nominal or specified behavior. In a digital circuit, a static fault is a change of its logical behavior. Some faults can be transient or dynamic and some may only affect timing. Faults are often, but not always, caused by defects.

The expression “fault-tolerant architecture” as used herein means an architecture that can be reprogrammed or configured to avoid one or more dysfunctions of a system.

The expression “green meter” as used herein means modules of an instrumented electronic system that can extract energy consumption in real-time to help optimizing power consumption on existing designs.

The expression “hardware assertion module” as used herein means a circuit that verifies properties of a design. Some properties may manifest themselves over time. Some others can be verified statically. These properties typically define logical and temporal behavior of the design. A hardware assertion module is a hardware device that can identify when and where a specified property is violated.

The expression “IC”, or “integrated circuit” as used herein means an electronic circuit fabricated over a monolithic substrate that comprises multiple components such as transistors, resistors, capacitors and/or inductors. An IC is a miniaturized version of an electronic circuit that could possibly exist as a set of discrete electronic or solid state devices connected together for a purpose. ICs are commonly integrated on a single die of silicon, but other technologies such as gallium arsenide (GaAs) exist. In conventional IC fabrication, multiple copies of the same circuit are ‘printed’ over a semiconductor wafer. That wafer is diced, and dies are mounted and encapsulated in packages to form ‘chips’ or ICs. A bare IC, die or encapsulated IC can also be identified as an integrated circuit or as an integrated circuit component.

The expression “Interposer” has used herein means a component that serves as an intermediate layer between two integrated circuits.

The expression “LAIC” (Large-Area Integrated Circuit) as used herein means any integrated circuit made from photo-repetition of one or several reticle image fields on the same circuit layer that are interconnected into a single integrated circuit.

The expression “large area micro-system (LAMS)” as used herein means an array or collection of micro-systems larger than a reticle image produced with one or several monolithic substrates such as LAICs.

The expression MEMS as used herein means Micro-Electro-Mechanical Systems. The term MEMS is often used loosely, in which cases MEMS integrates one or more of the following components: mechanical elements, sensors, actuators, and electronics on a common substrate using some microfabrication technology.

The expression “micro-substrate” as used herein means a small piece of planar material that mechanically, electrically and thermally support another fragile planar material deposited on it.

The expression “micro-system” as used herein means some electronic or mechanical components, usually made through a lithographic process, that contain small parts with dimensions between one micron and one millimeter on a side.

The expression MISR as used herein means a multiple input signature register. A MISR is a parallel input register that can be used for test response compaction. MISRs are usually used as part of BIST systems to increase test speed by compressing results produced by a set of test vectors.

The expression NEMS as used herein means Nano-Electro-Mechanical Systems. A NEMS integrates one or more of the following components: mechanical elements, sensors, actuators, and electronics on a common substrate through nanofabrication technology.

The expression “NoC” as used herein means Network on Chip.

The expression “NoW” as used herein means Network on Wafer.

The expression “PCB” as used herein means Printed Circuit Board. A PCB is a mechanical support that also electrically connects discrete electronic components or ICs using conductive traces etched from conductive sheets laminated onto a non-conductive substrate.

The expression “PMC” as used herein means Power Manageable Component.

The expression “PSA” as used herein means Programmable Shut-down Assertion.

The expression “PSM” as used herein means: Power State Machine

The expression “PWA” as used herein means Programmable Wake-up Assertion.

The expression “Reticle” used herein refers to a physical object used as part of a micro-fabrication process to print an image of one layer of one or more IC over some area of a wafer. More than one IC may be printed at a time when they are sufficiently small. To improve resolution of manufacturing processing, the reticle is often enlarged by some factor; say 5×, compared to the part of a wafer printed in one exposure. Typically, the maximum size that can be printed on wafer with a reticle is 2.5 cm by 2.5 cm. That maximum image size corresponds to the normal maximum size of an IC. A reticle image field is what gets printed on a wafer.

The expression “reticle image field” as used herein means the geometrical zone that gets printed on the surface of a wafer where some micro-fabrication step such as a lithographic process step takes place. It defines the maximum size that a regular IC that is not stitched can have. By stitching multiple field images together, a Large Area Integrated Circuit (LAIC) is formed. In the most common micro-fabrication processes, a stepper covers a whole semiconductor wafer that can be large than 30 cm in diameter, by imaging multiple copies of the reticle at regular interval.

The expressions RRN, RRNoC or RRNoW as used herein stand for Regular Reconfigurable Network (RRN), RRN on Chip and RRN on Wafer. This type of network includes the WaferNet network, but can include every type of network on chip (RRNoC) or on Wafer (RRNoW) that contains a regular array of reconfigurable crossbars interconnected together.

The expression “Scan chain” as used herein means a sub-circuit within an IC that is composed of a chain of memory elements. This chain is typically accessed through a serial protocol like JTAG or any other types of interconnect network to minimize the number of connections.

The expression “Scan chain path” as used herein means a path between two distant points in a circuit made of a scan chain. Several scan chain paths can exists between two distant points in a circuit.

The expression “SiP” as used herein means System in Package.

The expression “SoC” as used herein means System on Chip.

The expression “SoW” as used herein means System on Wafer.

The expression “stuck-at fault” has used herein relates to a most common fault model where it is assumed that the logical value on some electrical node is “stuck” at a constant logical value. Therefore conventional stuck-at faults can be of two types, either stuck at logic-0 or at logic-1, respectively named stuck-at-0 (SA0) and stuck-at-1 (SA1).

The expression “support frame” as used herein refers to a multi-layer stack structure such that each layer can be a heatsink, PCB, ceramic, silicon PCB, thermal grease, balls, MEMS, NEMS or any material that can be used to reduce mechanical stress on fragile LAMS devices and/or to interconnect devices for power supply or data signal propagation.

The expression “support circuitry” as used herein refers to any circuit that support another circuit, which can include devices, such as and not limited to passive devices (e.g. resistor, capacitor, inductor), active devices (e.g. transistors, diodes, etc.) and any combination of devices to build functional or control modules.

The expression “substrate” as used herein means the base layer of a structure such as an integrated circuit, multichip module (MCM), printed circuit. Silicon is the most widely used substrate for integrated circuits. Fiberglass (FR4) is mostly used for printed circuit boards, and ceramic is used for MCMs.

The expression “Test controller” as used herein refers to a module that controls the transfer of test vectors or data. A test controller can be a simple “go/no-go” logical unit. It can include software capable to provide complex diagnosis about the functionality of the unit under test or generate complex sets of data streams. A test controller can be used to communicate data between two modules, such as data to configure or test one module or data from/to sensor modules or actuator modules. A test controller can be substantial serial when it uses a scan chain protocol or substantially parallel when it uses a bus based protocol. Some test controllers include one or more test access ports (TAPs)

The expression “TSV” as used herein means Through Silicon Via. TSVs play the role of direct vertical interconnects in 3D ICs.

The expression “UUT” as used herein means Unit Under Test. A UUT can be any IC, SoC module, or part of a LAIC (including WSI) that is under test. A UUT is controlled by an external means such as an external test controller. The term UUT is therefore used in relation to configuration, programming or testing of a system.

The expression “VDD” as used herein is the abbreviation used for the power supply voltage of integrated circuits.

The expression “Wafer” as used herein refers to a slice of very pure semiconductor mono-crystal (typically silicon material even though other materials such as GaAs, InP and others are used). IC dies are micro fabricated over the surface of a wafer using photolithography and related processes. A wafer is typically disk-shaped, as a consequence of how it was obtained by slicing it from a mono-crystal cylindrical ingot.

The expression “WSI” as used herein means Wafer scale Integration. WSI is a process from which integrated circuits that cover substantially the whole surface of a semiconductor wafer are fabricated.

The expression wafer-scale micro-system device as used herein means an array or collection of micro-systems larger than a reticle image produced on a full wafer or a superposition of different wafers.

The expression WaferBoard as used herein refers to dynamically reconfigurable and reusable platforms that can be used to rapidly prototype and validate electronic systems.

### BRIEF DESCRIPTION OF THE DRAWINGS

These and other objects, features and advantages of the invention will be more readily apparent from the following detailed description of the preferred embodiments, in which:

FIG. 1 is an illustration of the prior art of the basic test architecture used in the context of JTAG test;

FIG. 2 is an illustration of the prior art of the most currently used JTAG test architecture: the daisy-chained scan chain;

FIG. 3 is an illustration of the prior art of another well known JTAG test architecture: the star architecture;

FIG. 4 is an illustration of the prior art of the PTA (parallel test architecture, or multi-dropout architecture;

FIGS. 5A and 5B are examples of the prior art of testing and diagnosing using the FPGA reconfigurability feature;

FIG. 6 is a global view of the prior art of RRN architecture and its relation to CMPIO and boundary scan. The notations used to describe the network line are introduced here too;

FIG. 7 is an example of defects in a RRN;

FIG. 8 is an illustration of the prior art of the hardware architecture proposed for the regular reconfigurable network diagnosis;

FIG. 9 is an example of the prior art of test type A applied to crossbar to detect stuck-at one or zeros faults;

FIG. 10 is an example of the prior art of test type B applied to a network containing both short and stuck-at faults, with the effect of the defect on the test result is shown;

FIG. 11 is an example of the prior art of test type C applied to a single crossbar to detect stuck-at faults;

FIG. 12 is the workflow of the prior art of test type A applied to a configuration and test system containing reconfigurable scan chain;

FIG. 13 is the algorithm of the prior art expressed in term of workflow for diagnosis short and stuck-at faults in the network with the test type B;

FIG. 14 is an illustration of the prior art of the test type C workflow;

FIG. 15 is an illustration of the prior art of an example of a power state machine;

FIG. 16 is high-level view illustrating the most important part of cell-matrix based test architecture with configurable bidirectional links and the test controller;

FIG. 17 is high-level view illustrating the most important part of cell-matrix based test architecture with configurable unidirectional links and the test controller;

FIG. 18 is high level view of the preferred embodiment of a fault-tolerant test architecture specialized for WSI systems;

FIG. 19 is a more precise depiction of the matrix inter-cell architecture of the CICU links where a portion of the cell based matrix architecture is shown;

FIG. 20 is a depiction of the internal architecture (block diagram) of a CICU cell circuit including its JTAG and TAP modules;

FIGS. 21A, 21B, 21C and 21D are an example of the basic steps required to complete the configuration of a 4×4 cell CICU architecture. These configuration steps are executed in the particular case with no faults in the circuits;

FIG. 22 is an illustration of the external control capabilities;

FIG. 23 is an example of the defect tolerant capabilities in the presence of various faults;

FIG. 24 is an example of the defect tolerant configuration capabilities using CICU links that go through two reticles. Two kinds of inter-reticular links are shown;

FIG. 25 is a depiction the matrix inter-cell architecture of the CICB links where a portion of the cell based matrix architecture is shown;

FIG. 26 is a depiction of the internal architecture (block diagram) of a CICB cell circuit including its JTAG and TAP modules;

FIGS. 27A, 27B, 27C and 27D are an example of the basic steps required to complete the configuration of a 2×2 cell CICB architecture. These configuration steps are executed in the particular case with no faults in the circuits;

FIGS. 28A, 28B and 28C are an example of a fault diagnosis procedure for the UICL architecture;

FIG. 29 is an illustration of the algorithm workflow applied for faults diagnosis in the serial configuration system;

FIG. 30 is an example of the defect tolerant capabilities in the presence of various faults;

FIGS. 31A, 31B, 31C and 31D are an example of a fault diagnosis procedure for the BICL architecture;

FIG. 32 is a depiction of the configurable clock sharing for fault tolerance;

FIG. 33 is a configurable unidirectional inter-cellular link application to PCB or LAMS;

FIG. 34 is a depiction of an algorithm for searching a cleared path through all UUTs;

FIG. 35 is an illustration of the capabilities of the reconfigurable scan chain to avoid faults and to deploy scan chain in multiple reticles;

FIG. 36 is an illustration of the cone of influence associated with an arbitrary output terminal of the network;

FIG. 37 is an example of the effect on the result of the test type B on a network containing multiple shorts on the same trace;

FIG. 38 is an example of the test rings used for short, stuck and dynamic faults diagnosis;

FIG. 39 is an example of multiple configuration of test rings used to avoid faulty crossbar or any other known faults;

FIG. 40 is the flowchart to diagnose short or stuck-at faults with test rings;

FIG. 41 is a depiction of an internal architecture used to implement the concurrent BIST architecture;

FIG. 42 is the flowchart expressing the required steps for completing the BIST W10 algorithm;

FIG. 43 is an illustration of the contact detection mechanism between LAIC CMPIO matrix and IC's pin;

FIG. 44 is an illustration of the contact detection algorithm based on a walking sequence;

FIG. 45 is an illustration of a preferred embodiment for a System In Package (SiP) containing a configurable interposer;

FIG. 46 is a logic block diagram for the repeatable cell included in the LAIC or in a 3D LAIC containing a set of configurable interposers;

FIG. 47 is an illustration of an example application of a configurable interposer;

FIG. 48 is an illustration of an example internal structure of a 3D chip stack or 3D LAIC, showing the XY plane and the XZ plane;

FIG. 49 depicts an extensible in the XY plane of a 3D stacked chip or 3D LAIC structure stacked chips;

FIG. 50 is a datapath illustration for the 3D LAIC connected by configurable interposer;

FIG. 51 is a version of the 3D stack interposer structure in FIG. 45, which is enclosed in a conventional IC package and composed of multiple layers that can be non-programmable interposers, programmable interposers, or integrated circuits or a film of compliant materials such as existing Z-axis film;

FIG. 52 is a dummy dies that can be a piece of silicon that can be thinned to the desired thickness to match that of other dies on a target die layer and that is separated in die form and is covered of a regular array of through silicon vias (TSVs).

FIG. 53 is an example of an heterogeneous 3D stacked dies composed of multiple layers with different sizes, that can be interposers, integrated circuits or a film of compliant materials such as existing Z-axis film, with connections between the substrate and one of the layers in the stack. It can be packaged in a single components;

FIG. 54 is a logic block diagram for the power distribution system enabled by the configurable interposer in the 3D LAIC DIE;

FIG. 55 is a logic block diagram for a preferred embodiment of the configurable hardware assertion;

FIG. 56 is an illustration of the internal architecture of a configurable assertion module;

FIG. 57 is an illustration of an example LUT network integrated in a NoW or in a configurable interposer;

FIG. 58 is an illustration of an example LUT network and its interaction with an external device such as FPGA or CPU for DFT or fault diagnosis;

FIG. 59 is a flowchart for the system level adaptive power management with a configurable interposer;

FIG. 60 is a logic block diagram for the predictive dynamical power management system;

FIG. 61 is a flowchart for the power aware design flow;

FIG. 62 is a flowchart explaining the system level power supplies voltage minimization;

FIG. 63 is a depiction of the top and side view of a wafer-scale LAMS device with its mechanical and electrical support in which a specific interface (6303) allows electrical connections and mechanical support of a semiconductor wafer (6301) to a support frame (6302).

FIG. 64 illustrates a support frame composed of a main PCB (6400) with a flat area (6401) to receive the fragile LAMS device and its dedicated electronic components (6402) shifted from the active area, with strong mechanical support ensured by a large heatsink (6403) that allows also a good thermal behavior of the whole device.

FIG. 65 depicts a possible variation of the preferred embodiment where a large heatsink (6500) with a top flat area (6501) to receive the LAMS device, with a main dedicated PCB (6502) is placed under the heatsink and some electrical wiring (6503) allows interfacing with the LAMS device;

FIG. 66 is a depiction of the support frame (6600)—LAMS device interface made of a solder ball layer (6601) and thermal underfill (6602), with connections made on the LAMS active side (6603);

FIG. 67 is a depiction of the Support Frame (6700)—LAMS (6701) device interface when the active side (6702) of the LAMS device must be cleaned of any other structures. The connections and fixtures are made on the LASM device backside with solder balls (6703) and through LAMS vias TLV (6704);

FIG. 68 is a depiction of the side view of an array of miniature-substrates (6800) that interfaces with a LAMS device (6801). Each miniature substrate can or cannot be connected to its neighbors through cables or flexible PCBs (6803);

FIG. 69 depicts the detailed side view of the interface of the LAMS (6900) with the array of miniature substrates (6901). Solder balls or solder columns (6902) ensure the electrical and mechanical connections. Each multi-layer miniature substrate can include or not integrated circuits, passive elements connectors, interconnect layers and all needed structures (6903) for the LAMS operating. It can be encapsulated in a metal box (6904) filled with or not with specific filling material (6905). Each miniature substrate can or cannot be connected to its neighbors through cables or flexible PCBs (6906);

FIG. 70 is a global depiction of the preferred LAMS application support. The interface between the LAMS device (7000) and the support frame (7001) is a mosaic of miniature substrates (7002). The large metallic heat sink (7003) is placed at the backside of the system and electronic devices (7004) are shifted on the support frame;

FIG. 71 is a global depiction of the LAMS application support. The interface between the LAMS device (7100) and the support frame is a mosaic of miniature substrates (7101). The main PCB (7102) of the support is placed on the backside of the whole system fixed to a large heatsink (7103). Electrical wires, cables or flexible PCB (7104) that go through the heatsink allow connections with the LAMS device;

FIG. 72 is a global depiction of a LAMS application made of multi-LAMS devices (7200) on a unique large support frame (7201). A specific material (7202) ensures the interfaces between the two layers;

FIG. 73 depicts the preferred embodiment of a multi-LAMS device (7300) on a unique large support frame. A main PCB (7301) with its electronic components (7302) on its backside is connected to the LAMS device with solder balls and thermal underfill or with Z-axis films (7303). The main PCB and its components can be encapsulated in a large metallic box (7304) and flooded in a specific filling material (7305) for thermal, electrical and mechanical reasons.

FIG. 74 is a block diagram of the proposed hierarchical and distributed power supply architecture. The first physical stage (7401) is supplied by conventional AC power voltage sources and ensures the conversion to stable DC voltages. The main stage (7401) can supply an array of second stages that are DC-DC converters with active and passive device layers (7402). Some mechanical and electrical structures (7403) allow distributing power and data to the LAMS substrate (7404). Those structures (7403) can be TLV, bonding wires, flex PCB or other electrical current transfer systems. Each second stage (7402) supplies a third level of hierarchy which is an array of active programmable voltage regulators (7405) coupled with integrated passive devices (7406) embedded in the LAMS substrate (7404).

FIG. 75 is a depiction of the solder ball/TLV distribution of power (7501) and ground (7502) connection between the LAMS device and its support. Their distributions are regular on the whole LAMS device surface in order to get the same density for all power domains. Only 2 kind of power domains are represented on this FIG. 75, but unlimited number of voltages can be use.

FIG. 76 is a depiction of the power and ground grid geometries (7602; 7604) used to distribute power and ground on the top or bottom surface of the LAMS device. Power and ground references are provided by surface distributed TLV or solder balls (7601; 7603) and then distributed to the whole LAMS surface with horizontal and vertical interleaved metal stripes connected with vias. The number of power domains, the stripe and TLV densities can vary depending on the application power needs

FIG. 77 is a depiction of the hierarchical architecture of embedded power supply voltage regulators. A main voltage source (7701) supplies a programmable voltage reference circuit (7702) and the voltage regulator master stage circuit (7704). The voltage reference (7703) provided by (7702) is used by (7704) to command several voltage regulator slave stage circuits (7705) located at different places on the LAMS device. Each slave stage (7705) provides a clean and regulated DC voltage source (7706) for LAMS surface circuits or devices.

FIG. 78 is a depiction of the Configurable Integrated Passive Device Network built with the superposition of Wafer Level Packaging layers that provide integrated passive devices (7804), Micro-Electro-Mechanical System switches (7803), a LAMS device (7802) that control the passive devices networks obtained and a main frame (7801) that supports the whole layered structure.

FIG. 79 is an illustration of the logical structure of a spatial configurable differential network. This configurable H-tree allows, through its 4 hierarchical levels, to read or distribute differential signals from differential pairs placed anywhere on the active surface.

FIG. 80 is the logical schematic of the first stage of the configurable differential network.

FIG. 81 is the logical schematic of any stages of the configurable differential network except the first and the last ones.

FIGS. 82A and 82B are the logical schematic of the last stage of the configurable differential network.

FIG. 83 is a conceptual block diagram depicting a whole smart thermo-mechanical prediction unit to sustain transient thermo-mechanical stress peaks reliability in LAIC (Large Area Integrated Circuit) systems.

FIG. 84 is a depiction of an embedded thermal or pressure sensor network (8401) (or both) on LAIC systems;

FIG. 85 is a depiction of one unit cell sensors (8504) configured by grouping three sensors (8501, 8502 and 8503) from any sensors in (8401);

FIG. 86 is a depiction of a detailed one possible configurable thermal sensor cell couple (9507) selected from (8301) on LAIC systems to allows the surface temperature peak value measured and position to be localized;

FIG. 87 is a conceptual block diagram depicting a critical thermo-mechanical zone localization based on first measurement of temperature sensors network;

FIG. 88 is a conceptual block diagram depicting a module for appropriate configurable thermal sensor cells network;

FIG. 89 is a conceptual block diagram depicting a module for confirmation of peak temperature and localization of the heat source;

FIG. 90 is a conceptual block diagram depicting a module to extract dynamic thermo mechanical map;

FIG. 91 is a conceptual block diagram depicting a transient thermo mechanical peaks stress monitoring and prediction unit;

FIG. 92 is a conceptual block diagram depicting a peak surface stress limit characterization.

FIG. 93 is a 3D stack component through which an array of TSVs is repeated as a TSV pattern.

FIG. 94 shows integrated circuit components electrically interconnected through surface contacts.

FIG. 95 shows an integrated circuit substrate 9401 with surface contacts 9401, with support circuitry 9501 serving one or several surface contacts.

### DESCRIPTION OF THE PREFERRED EMBODIMENTS

First Family of Preferred Embodiments: Software and Hardware Strategies for Defect Tolerance in Large Area Integrated Circuit

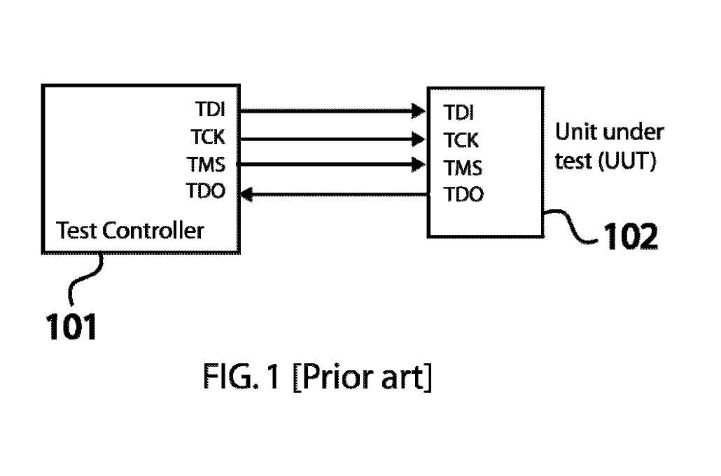

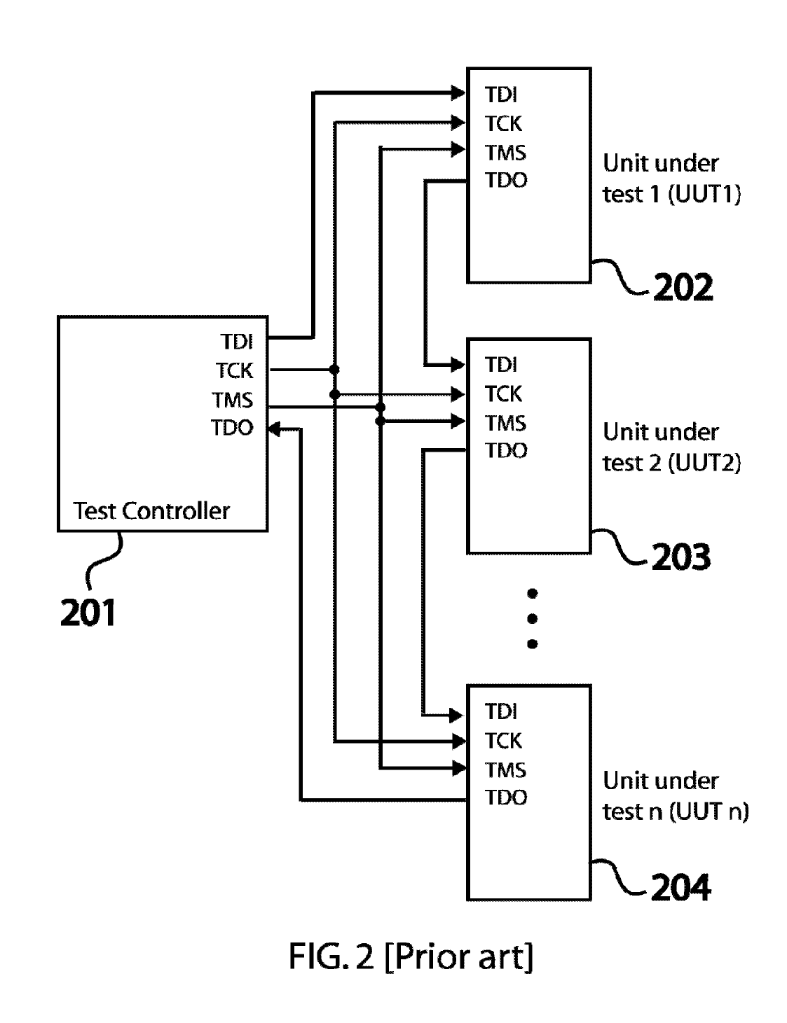

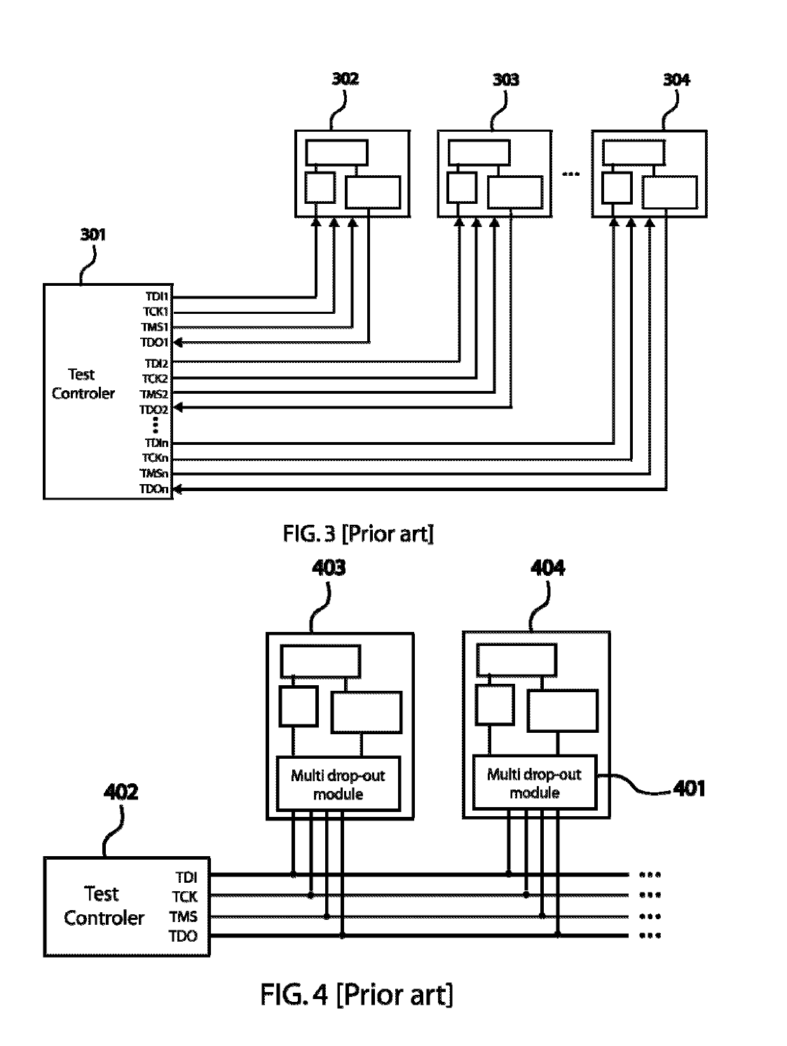

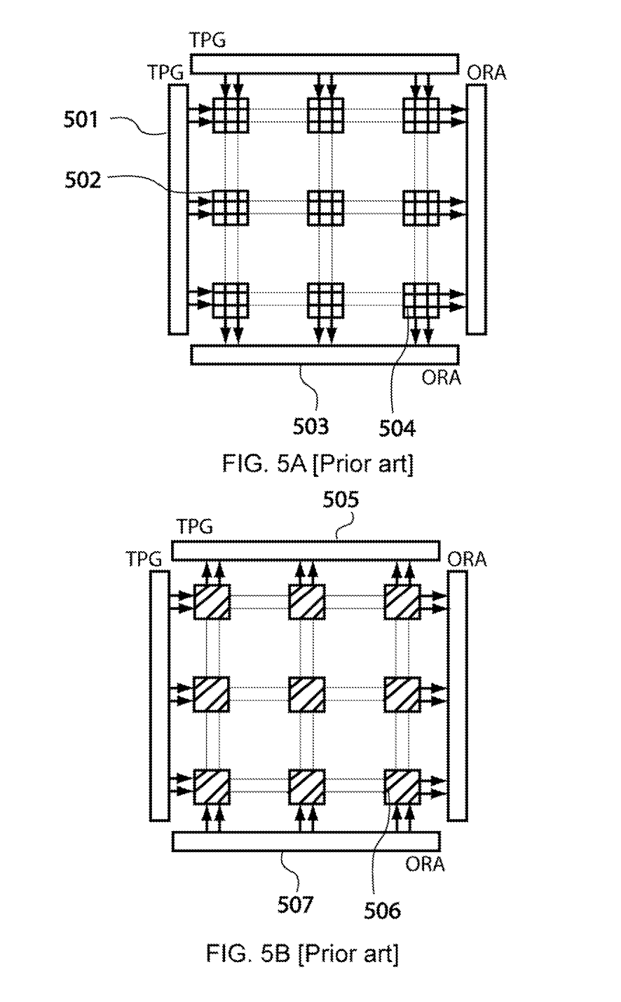

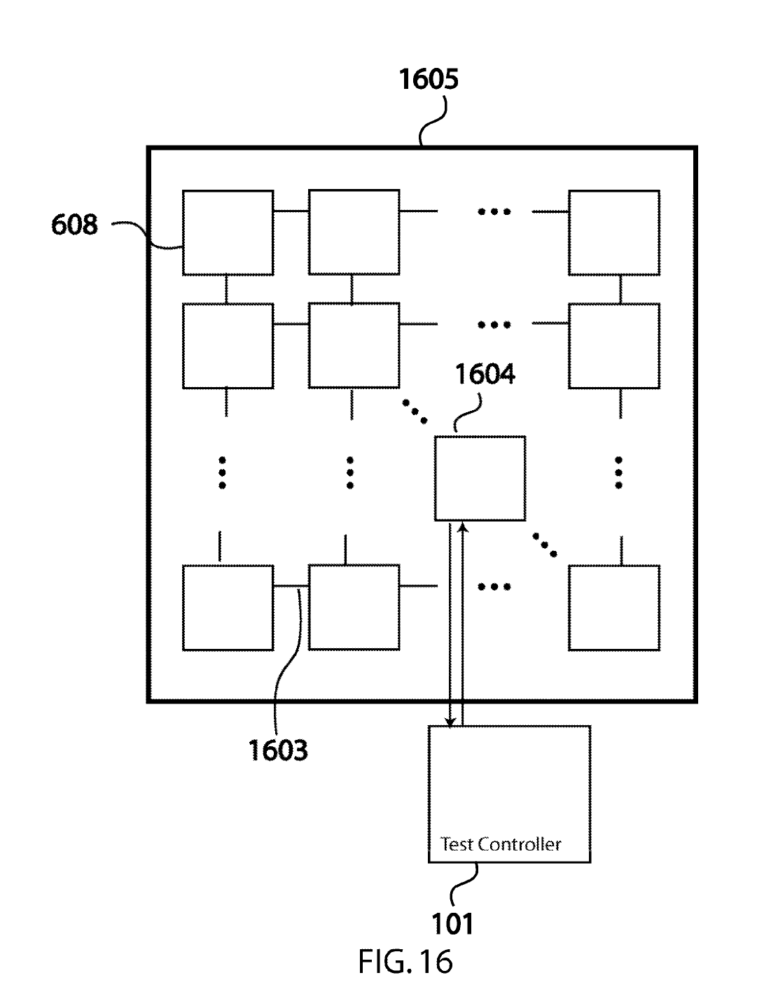

An efficient and fault tolerant scan chain for large and complex LAICs can use the generic reticle image architecture depicted in FIG. 16. Cells 608 are not necessarily identical (size, functions, circuits), and include functional modules, such as logic circuits, processors, CPUs, FPGAs, memories, DSPs, networking circuits, etc. Those cells are part of a larger system 1605 tested or configured by a TC 101. As was depicted in FIG. 1, there is one TC 101 interacting with one UUT, system 1605. Each cell has links 1603 to several neighbor cells (FIG. 16 shows the case where each cell is linked to four adjacent cells). This architecture contains two types of cell: interface cells 1604 that have direct communication links with TC and inner cells 608. The interface cell can be any cell in 1605.

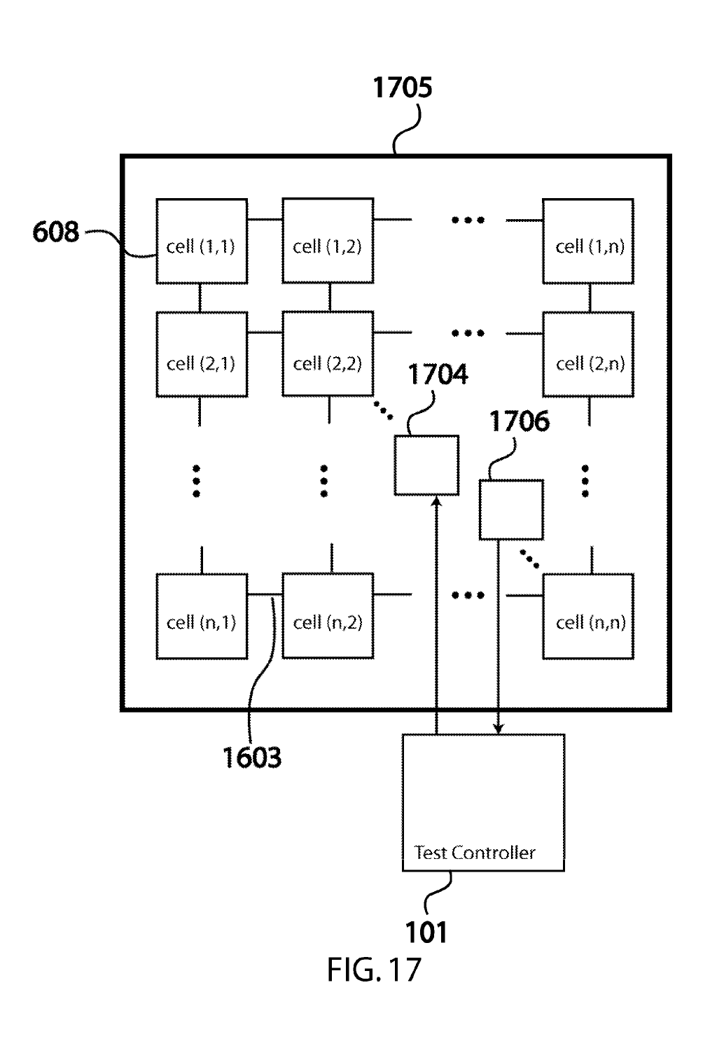

Communication links can be bidirectional (as shown in FIG. 16 with the Bidirectional inter-cell link (BICL) architecture or unidirectional (as shown in FIG. 17 with the unidirectional intercellular link (UICL) architecture). BICL can have a single interface cell 1604 while UICL requires at least one head cell 1704 and one tail cell 1706.

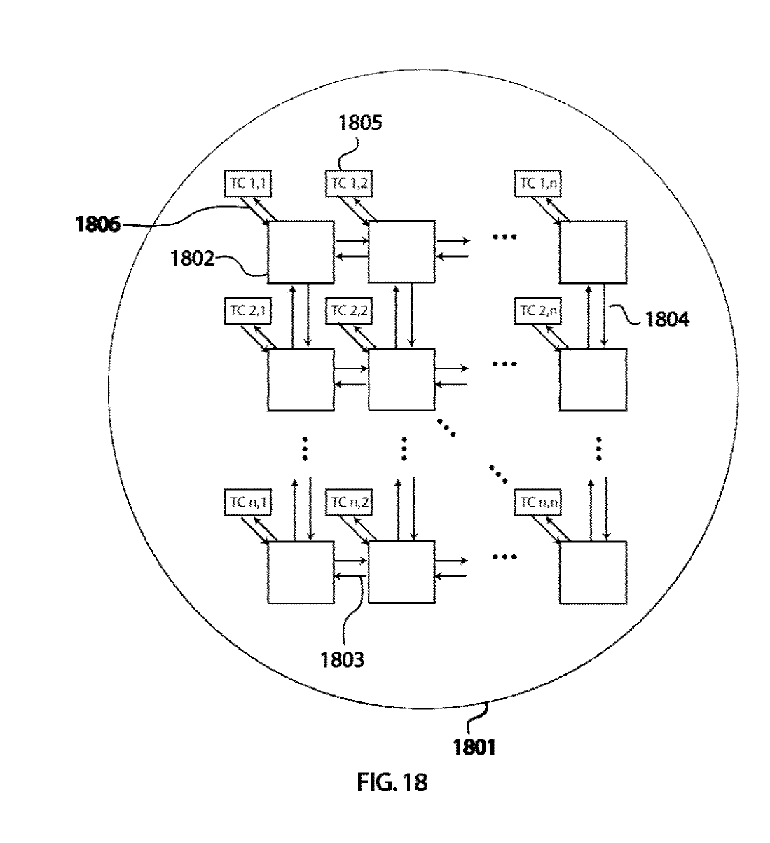

The preferred embodiment for the LAIC architecture shown in FIG. 18 has several external TC 1805, each linked to its own reticle field image 1802. Each reticle field image 1802 can be linked 1803, 1804 to its adjacent reticle image fields. This LAIC architecture allows parallel communication between reticle field images and external TCs, thus providing possible fault tolerance if any link between an external TC and the wafer is defective.

Each TC can be embedded in the LAIC or can be externally implemented (off-LAIC TC) with their respective control software.

Fault tolerance is achieved with the multi-reticle field image architecture of FIG. 18 where any defective reticle field image 1802, TC 1805 or links 1806, 1803 or 1804 can be replaced or bypassed.

Each reticle field image can be linked to its adjacent neighbors. Links 1803 and/or 1804 can be activated in case of failed communication links1806 between an external TC and a reticle. Therefore, if a TC-reticle link is dysfunctional or for any reticles not linked to a TC, then one of its adjacent reticle field images can dispatch the data stream to this reticle.

One independent external TC 1805 can be used to control one or more reticle field images. Each link 1806 is independent from the others, which means that it provides and gets its own set of signals to/from its reticles.

For example, the preferred embodiment for link 1806 is a standard JTAG link that includes a clock signal (tck), an optional reset signal (trst), a control signal (tms) and two data signals for the serial communication protocol (tdi and tdo).

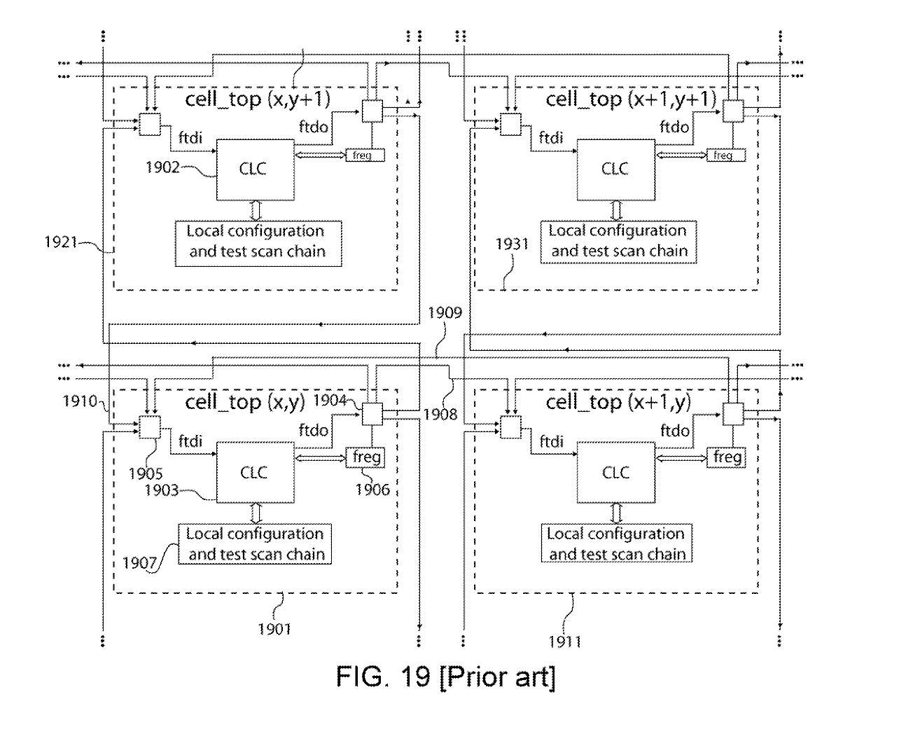

FIG. 19 shows the cell's internal architecture of the unidirectional inter-cell link (UICL) architecture. Only four cells (1901, 1911, 1921 and 1931) are depicted in the figure to show how cells can be connected and how they can interact. This figure details only the hardware architecture to test and configure the system. The functional modules in each cell are not shown. The communication between the TC and the functional modules can be done with a proper set of configuration registers 107, similar to the user's registers found in JTAG. This communication between TC and the functional modules is done through multiple scan chains, used for example to change the internal state, to test or to configure the cell's functional modules.

In the preferred embodiment, each cell has a Test-Access-Port (TAP) module (1902, 1903) that controls the flow of data received from any neighbor cells. This TAP module allows a direct access to user's registers 1907 and to the forward link register (freg) 1906.

The goal of freg 1906 is to select the next cell to which the outgoing data stream is forwarded. All registers freg 1906 must be set such that one and only one cell forwards a data stream to a targeted cell. The mechanism used to select the cell-to-cell link can be based on demultiplexers, tri-state buffers, decoders or others.

A preferred embodiment is that register freg 1906 sets the state of an output demultiplexer 1904 which redirects the data stream toward one of the neighbor cells (through link 1c.2). For example, the link 1908 connects the cell (x, y) 1901 to cell (x+1, y) 1911. To forward data stream to 1911's TAP module from cell (x, y) 1901, the register freg 1906 is configured to set the demultiplexer 1904. Then, only the link 1908 forwards data to the OR gate 1905 of cell 1911, while all the other OR gates 1905 inputs of cell 1911 are set to zero.

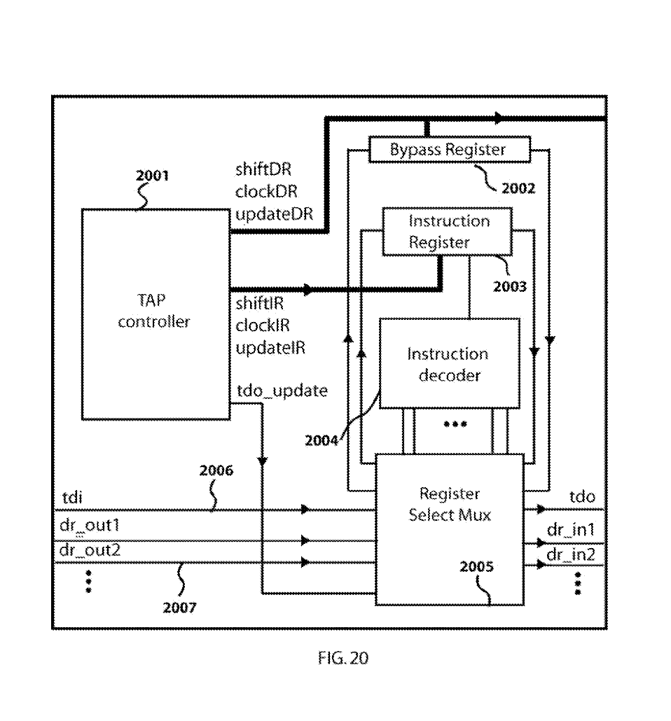

FIG. 20 depicts the preferred embodiment for the internal architecture of the TAP module 1903 associated with the UICL architecture. It is similar to the JTAG architecture. It contains a state machine known as the TAP controller 2001, an instruction decoder 2004 and a bypass register 2002. Moreover, the TAP modules contains a set of multiplexers 2005 that take the input data stream 2006 (tdi) and data coming from internal registers 2007, and redirects it toward the tdo line or other directions: dr_in1, dr_in2. The TAP controller is controlled by the external signal tms from the JTAG port. According to its internal state controlled by the tms signal, the TAP controller can write into the instruction register or read/write to data registers 107. The instruction register 2003 contains as many bits as needed and these instructions are processed by the decoder 2004 to set the multiplexer 2005. According to the JTAG standard, the bypass register is activated when the instruction “bypass” is scanned into the instruction register. It allows then the incoming data stream to be directly redirected to the next cell through tdo.

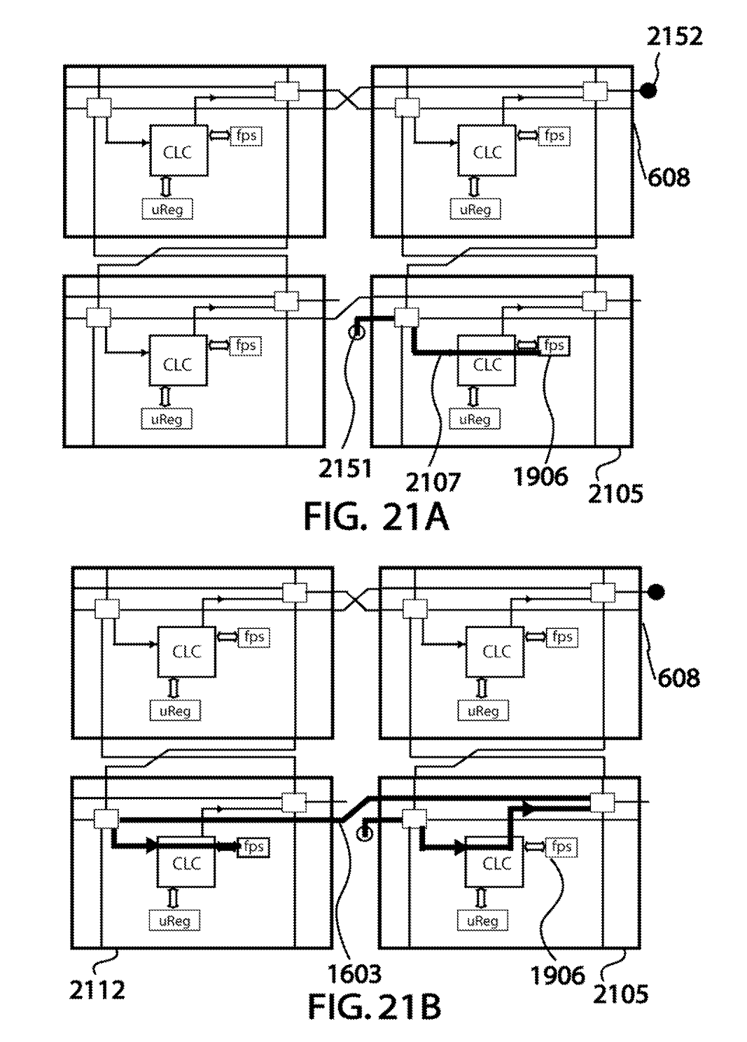

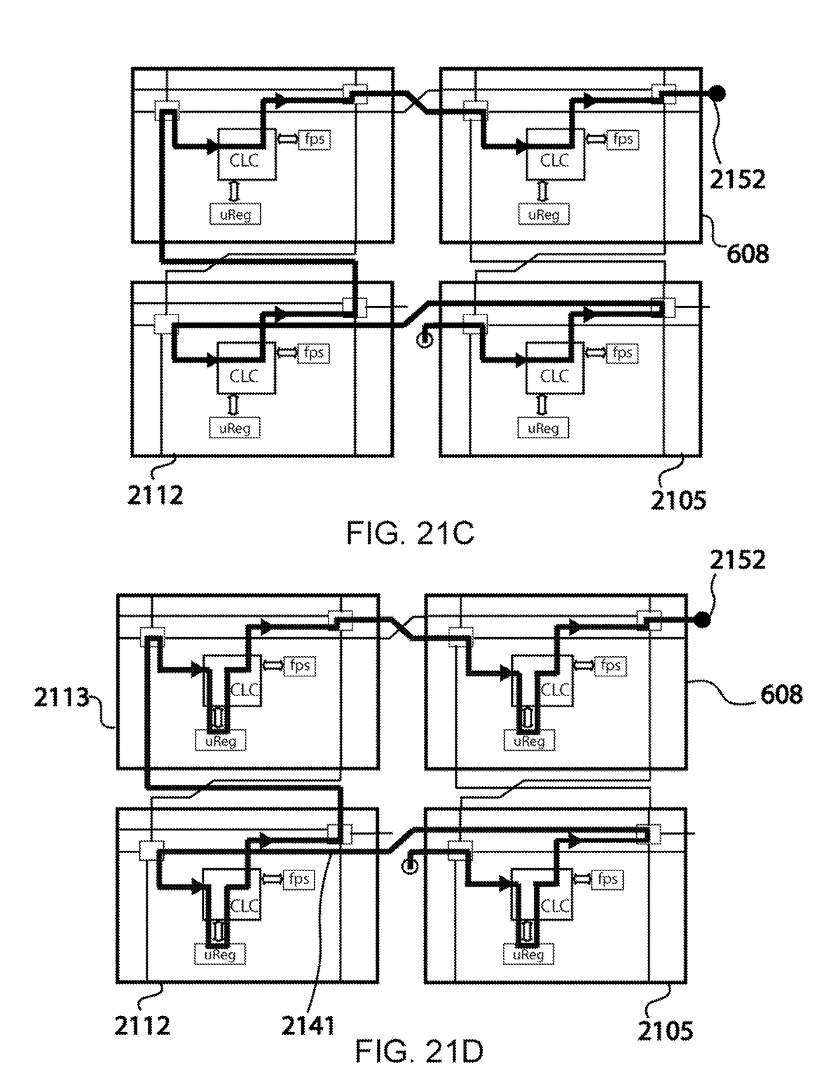

FIGS. 21a, 21b, 21c and 21d further illustrate the required successive steps in order to create a path between the head cell 2105, which has a direct connection 2151 to the TC and the tail cell 608, which sends data back through the direct connection 2152 to the TC. The example shows four successive steps 21a, 21b, 21c and 21d depicted for a very simple 2×2 cell reticle image field. Each step is associated with configuration commands sent to the 2×2 cells. The goal of the step 1 in FIG. 21a is to access the register freq 2108 of the head cell 2105. The register freg 1906 is set with a data register write command, sent to cell 2105's TAP module through path 2107.

Once the register freg 1906 is properly configured, a path between cells 2105 and 2112 through link 1603 is created. The instruction register 1906 of cell 2105 is set into bypass mode. Then the system is ready to access the next cell 2112 with the configured link 1603. The second step in FIG. 21b repeats the same process as in step 1, i.e. access and configure cell 2112's freg register and sets cell 2112 into bypass mode. These commands follow the path 1603 with cell 2105 set in bypass mode. The third and fourth steps shown in FIG. 21c depict the same successive commands applied to the third 2113 and forth 608 cells. At the end in FIG. 21d, a direct serial communication line exists between the head cell 2105 and the tail cell 608. In this state, the system is ready to access all the data registers 2141 for test or configuration, as shown in fourth step 2104.

The disclosed LAIC architecture is fault tolerant with respect to defective cells, defective cell-to-cell links, defective TC, defective TAP controllers can be bypassed, worked around or replaced. Several strategies can be implemented to overcome those faults.

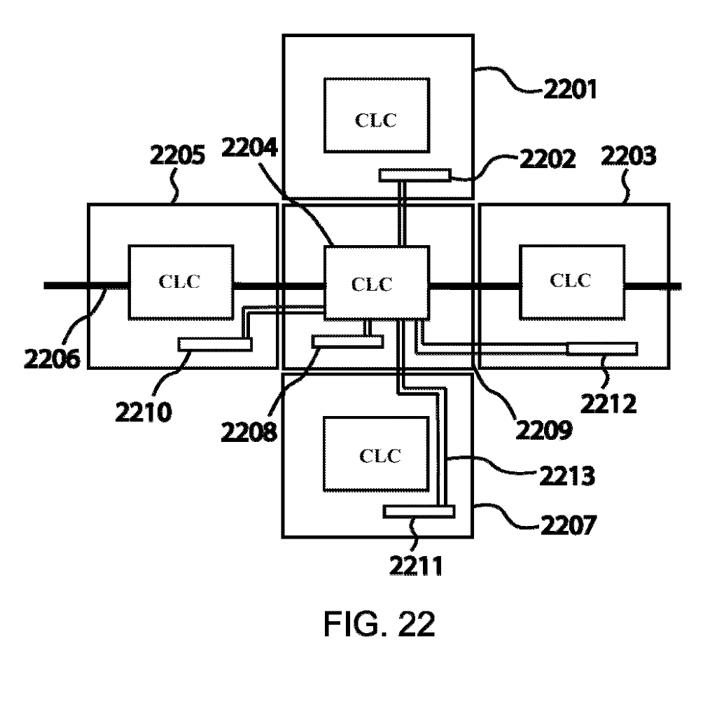

The first fault tolerance strategy is the “external control” that allows a functional module to be controlled by a neighbor cell. FIG. 22 shows a neighbor scan chain that can control its adjacent cell's scan chains. Every cell contains a CLC 2204 (cell logic core) that, when properly configured, can redirect the incoming data stream to its local scan chain 2208 or to its neighbor scan chains 2202, 2210, 2211, 2212. FIG. 22 shows a preferred embodiment with only four “external controls” to north 2201, south 2207, west 2205 and east 2203 cells. Each external scan chain (2202, 2212, 2211, 2210) is seen as an internal scan chain by the TAP module because this access is done via a direct inter-cell access 2213 starting from the actual cell that is part of the inter-cell scan chain. Each cell contains one or more scan chains reachable by external means. It is called “external control” because the CLC of a cell is used to get access to another cell. Therefore, even if a cell contains single or multiple faults in the CLC, the scan chain remains reachable by another cell containing a functional CLC.

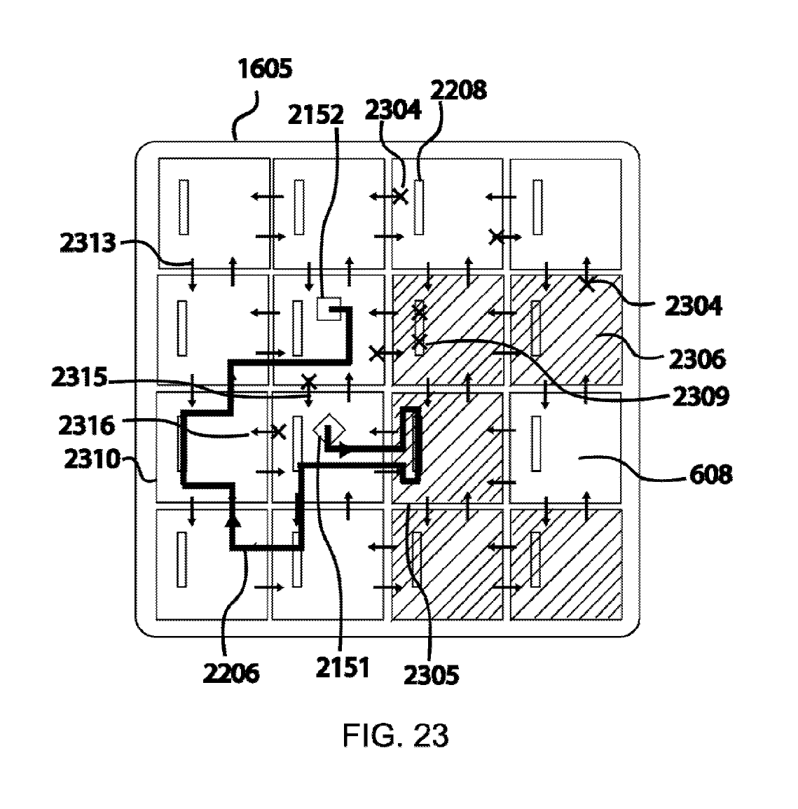

FIG. 23 shows an example of the external control where the goal is to configure the internal scan chains of cells 2305 and 2310. The dark cells, such as 2305, 2306 and 2309 have respectively dysfunctional or defective CLC. In each cell, there is a scan chain, shown as a smaller and vertical rectangle 2309, 2208, used for test, configuration or programming. A cell-to-cell link is represented by an arrow 1603. A scan chain (2309) or a cell-to-cell link (2304) with an “X” is identified a defective element. One active inter-cellular scan chain is shown in 2206. This scan chain starts from the head cell's TC 2151 and ends to the tail cell's TC 2152.

Each cell can be put in one of the following four states: (1) inactive state, where the inter-cellular scan chain or internal scan chain are not used (such as cell 608); (2) bypass state, where the internal scan chain is not used but the data stream is redirected to the next cell through the inter-cellular scan chain (such as 2206 in cell 2316); (3) scan-in state, where the cell's internal scan chain is accessed (such as cell 2310); (4) external scan state, where the cell takes control of the internal scan chain of a neighbor cell (such as cell 2151 takes control of 2305's internal scan chain).

A combination of one of these four states for each cell can be used to bypass or go around defective CLC, inter-cell links or internal scan chain.

For example, under a dysfunctional CLC in cell 2305, a fault tolerance strategy consists of reaching the internal scan chain in cell 2305 with cell 2151 configured in external scan state.

In another example, under dysfunctional links 2315 and 2316, a fault tolerance strategy consists of creating a path between head cell 2151 and tail cell 2152 by going around these broken links.

If the head 2151 or tail 2152 cells are dysfunctional, the entire reticle image field is lost. Other head cells or tail cells must be respectively used. Redundant head cells or tail cells can be added in the reticle or the head or tail cells of adjacent reticles can be used with links between neighbor reticle image fields also called inter-reticle links. Inter-reticle links are created with reticle stitching techniques. In the preferred embodiment, there is one head cell and one tail cell per reticle and inter-reticle links to each adjacent complete cell in the horizontal and vertical directions.

Inter-reticle links also increase the fault tolerance capability, especially for cells isolated due to dysfunctional inter-cell links or CLCs.

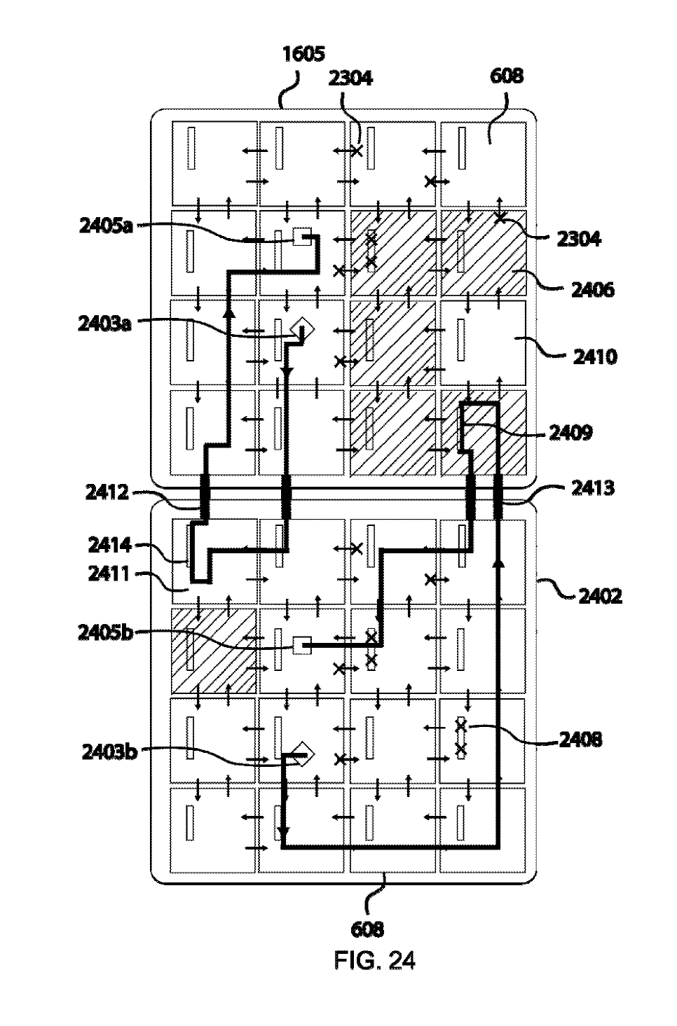

For example, FIG. 24 shows two reticle image fields, each with their own external test controllers TC, head and tail cells with defective cells identified with hatching. There are two reticle image fields 1605, 2402 of 4×4 cells with their respective head cells 2403a, 2403b, and tail cells 2405a and 2405b. If there was no inter-reticle link, cells 2410 and 2411 are isolated and cannot be accessed due to defects in surrounding cells and links.

With inter-reticle links, isolated cells 2410 and 2411 can be accessed with paths from head and tail cells in adjacent reticle (paths 2414 and 2413). Head and tail cells could also be in different reticles respectively.

The differences between the bidirectional intercellular link (BICL) and UICL architectures imply variations in the cell hardware architecture and the TC software. FIGS. 16 and 17 show high level views of BILL and UICL architectures respectively. Instead of having an input cell 1604 and an output cell 1706 as represented in the FIG. 17, FIG. 16 has a single interface cell 1604 to TC 101.

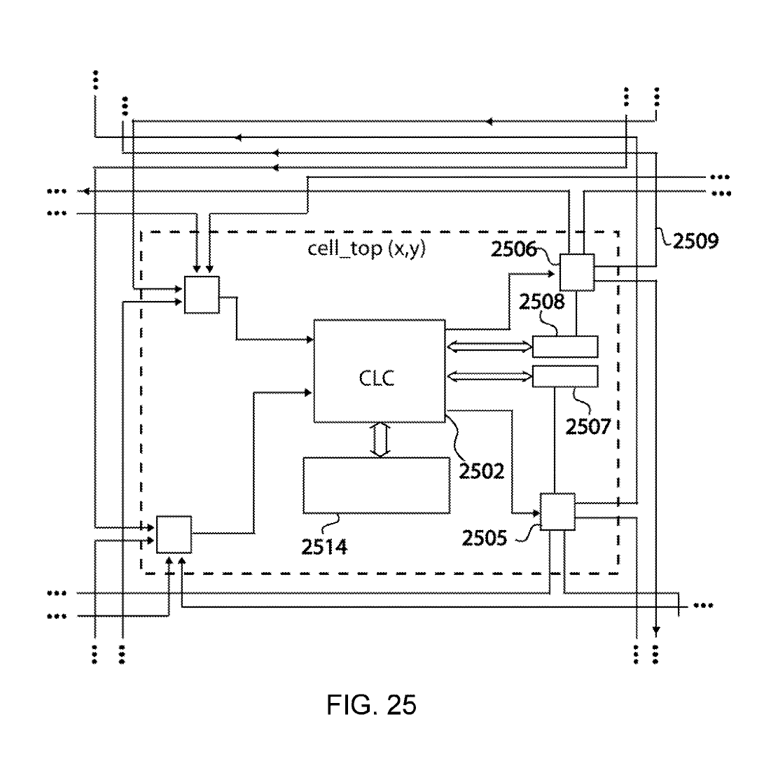

FIG. 25 shows in greater detail how BILL cells are interconnected together to provide the interconnection network. The head and tail cells are not shown. In a preferred embodiment and as in a UICL cell, the BILL cell has a cell logic core 2502 with configuration registers and scan chains 2514, forward register freg 2508, demultiplexer 2506, and cell-to-cell links 2509. The main difference between UICL and BICL cells is a second configurable demultiplexer 2505 that redirects data streams coming from the CLC 2502. The backward register 2507 (breg) configures the demultiplexer 2505. This configurable demultiplexer redirects the data streams coming from the forward cell coming back from the actual cell.

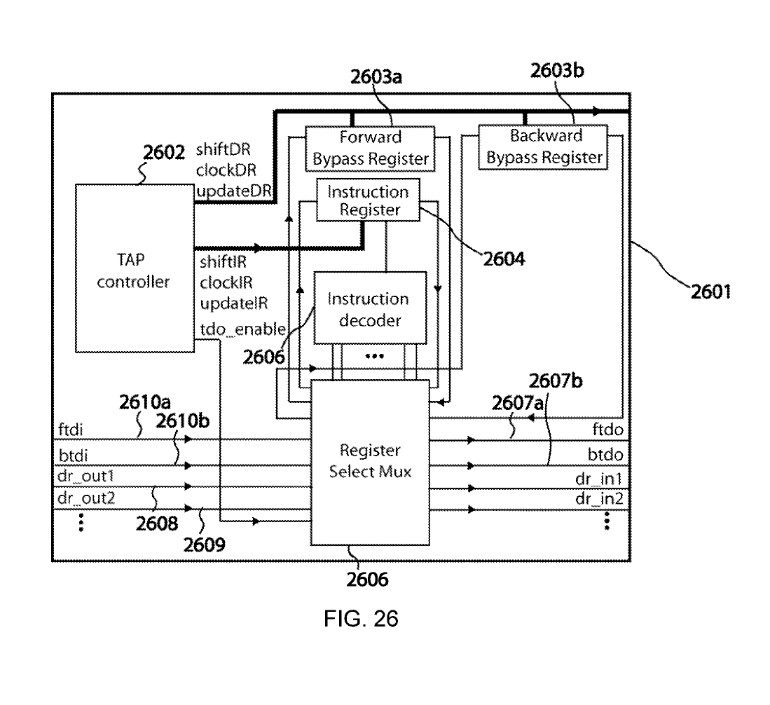

FIG. 26 provides details of the CLC structure for BICL cell. The difference between the BICL and UICL lies in the bypass register. In FIG. 26, there are two bypass registers (forward 2603a and backward 2603b bypass registers) to manage simultaneously forward data and backward streams and make two configurable paths in a single cell. A new set of custom JTAG instructions are required. Once the links between the actual cells and the backward cell and the forward cell are settled, the data stream can be redirected by the demultiplexers placed in the register select. The backward and forward data streams use the lines btdo 2607b, ftdo 2607a and btdi 2610b, ftdi 2610a. Furthermore the backward bypass register 2603b and the forward register 2603a are used to resynchronize the signal through the inter-cell path.

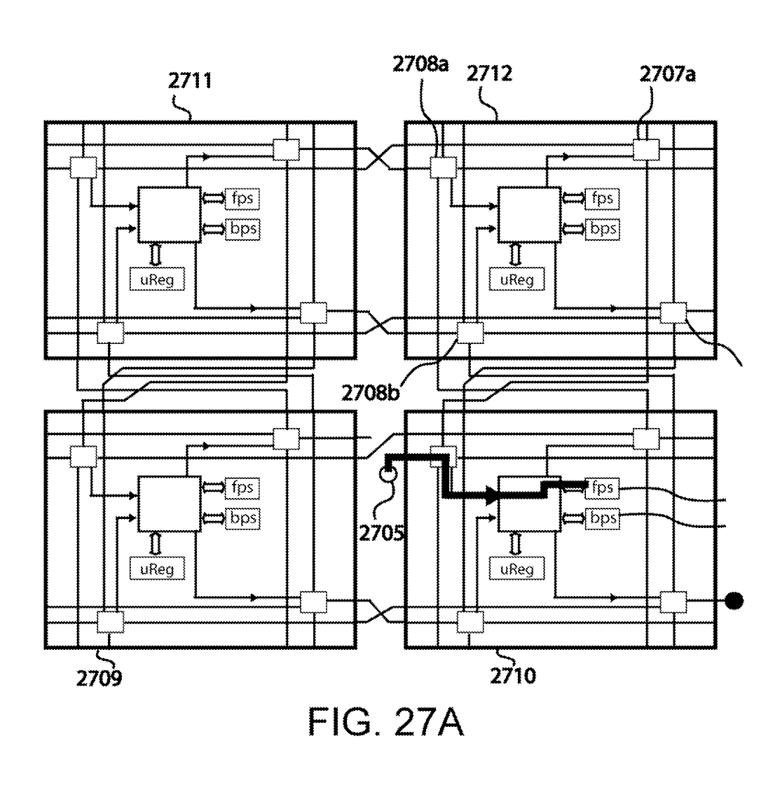

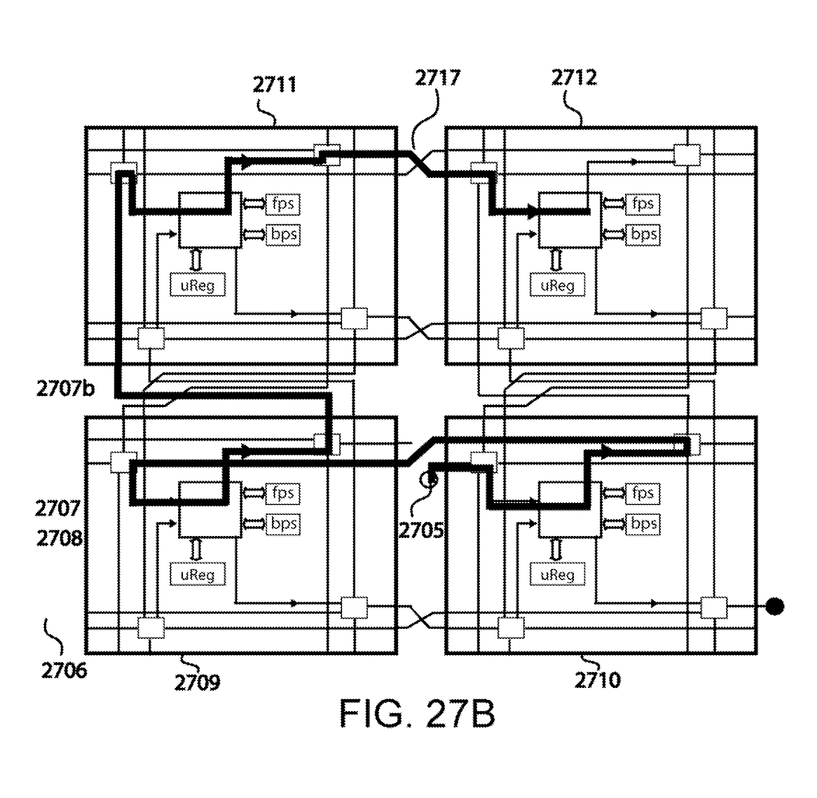

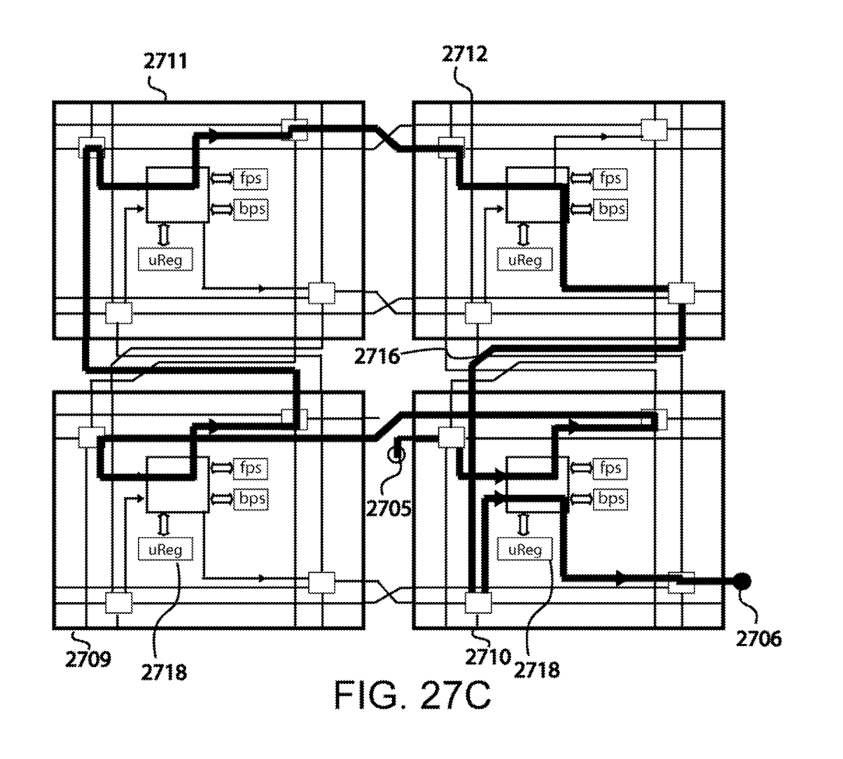

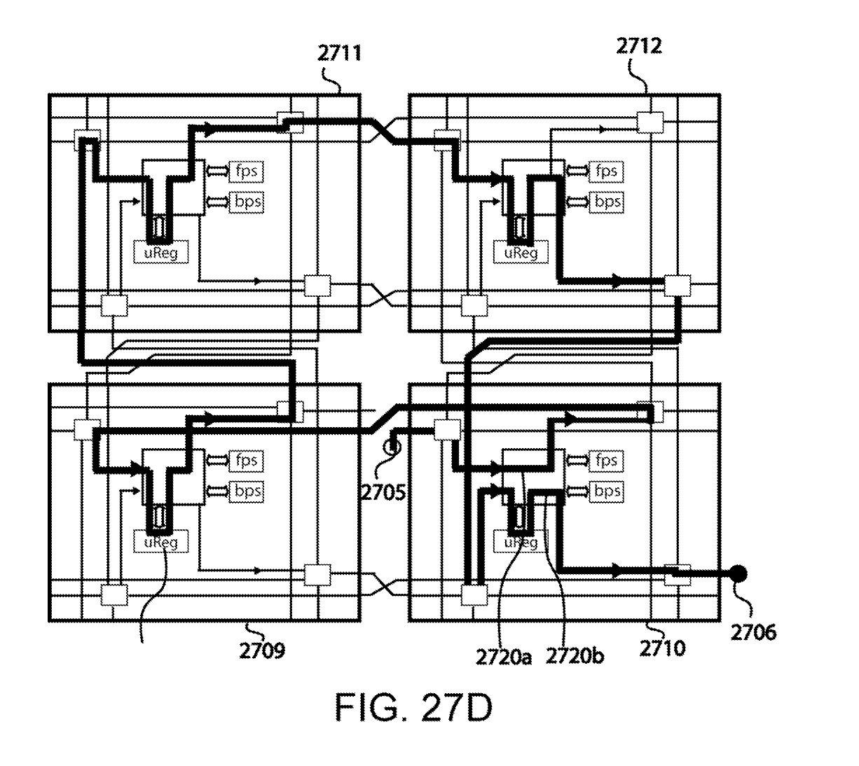

FIG. 27 depicts an example of the steps (FIGS. 27a, 27b, 27c, 27d) required to proceed to the settlement of an intercellular links 2716, 2717, 2718, binding 2×2 cells. The BICL architecture in FIG. 27 is equivalent to FIG. 21 with the demultiplexer 2707a and OR gate 2708a. The main differences are a second demultiplexer 2707b and OR gate 2708b and the same cell 2710 is used to connect to TC through head port 2705 and tail port 906. The steps attempt to set a path between the head port 2705 and the tail port 2706 that passes through cells 2710, 2709, 2711 and 2712. The first step 2701 configures the forward register of cell 2710 to reach the next planned cell 2709. This configuration step is repeated at steps 2702, 2703 to link cells 2710, 2709, 2711 and 2712. At the end of step 2703, the path is created, 2710 f>2709 f>2711 f>2712 b>2711 b>2710 where “f>” corresponds to a forward link and “b>” corresponds to a backward link.

Once the planned path is set and proven functional, step in FIG. 27d is then used to configure, program or test the cells on the path through the scan chain 2718.

While the routing resource needed to realize the BICL architecture, the test time is faster than UICL because the diagnosis is easier and faster to be completed. It also offers finer coverage of functional cells.

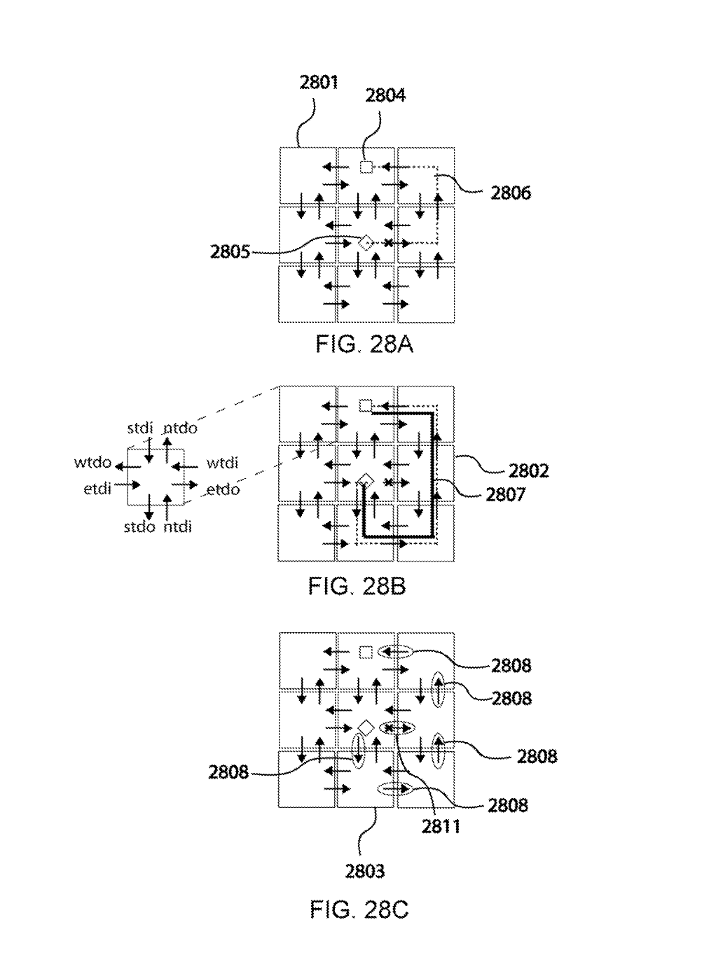

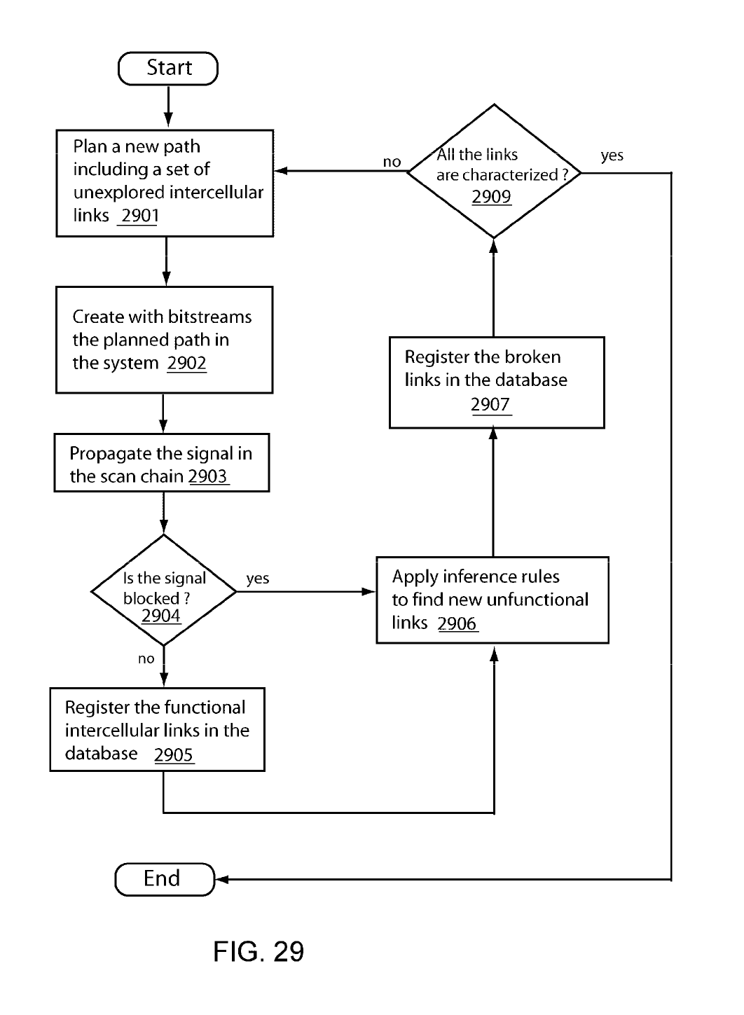

The test controller TC is an essential part of the solution and in a preferred embodiment; it includes a software resource to plan a possible path in the cell-matrix network and must be able to diagnose the faults. The diagnosis algorithm is shown in FIG. 29, and an example of each step is shown in FIGS. 28a, 28b and 28c.

At the beginning of the diagnosis process, the functional or dysfunctional status of each cell, CLC, internal scan chain and link is unknown. FIG. 28 shows an example with a 3×3 cell-matrix. The first step is shown on FIG. 28a where 2801 or 2901 plans a path between the head cells 2805 and the tail cell 2804. The planned path is represented with dotted lines 2806a. Then the next step 2902 of the algorithm is to generate the data stream to configure each cell on the planned path 2806. The data stream includes the data to configure each cell and then the data to exercise the planned path. Then on step 2903, the TC injects the generated data stream into the head cell 2804 and read the output stream on the tail cell 2804. Step 2904 compares the data stream received on tail cell with the expected output. If equal, the planned path is functional, if not the path is dysfunctional with at least one defective cell, CLC or links. The planned path and its status are registered in a database 2905. Inference rules are applied at each iteration using the information in the database 2906 to isolate defective links and cells. The example in FIG. 28 shows that there is a broken link 2811a that stops the data stream to reach the tail cell. The defect or defects cannot be located and this step.

As the database grows, inference rules are applied and defective cells are diagnosed and registered in a defect map 2907. Then, the iterations are stopped in 2909 when all cells have been diagnosed or when a satisfactory set of functional paths has been found.

For example, in FIGS. 28a and 28b, a dysfunctional path 2806 and a functional path 2807 are respectively found. An inference algorithm can be applied to state that the link 2806 is broken while links 2808 and cells on paths 2807 are characterized as functional.

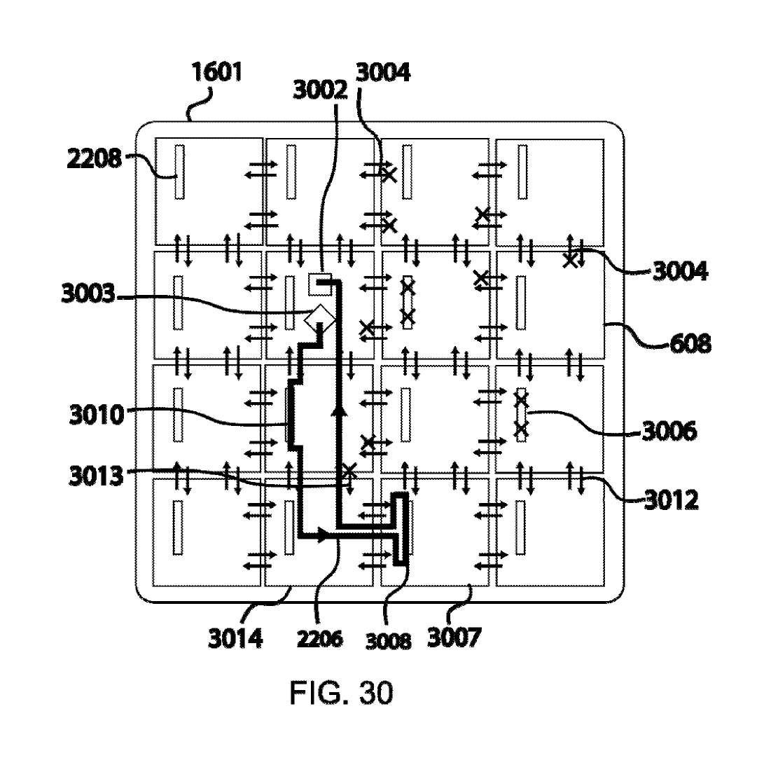

FIG. 30 depicts an example of the fault tolerance capability of the BICL architecture, with a 4×4 cells with faults on links 3004, cells 608 and internal scan chain 3006. The same pictographic representations are used as that in FIGS. 23 and 24. In this example: two cell's internal scan chains 3008 and 3010 are reached through an inter-cellular link 2206 in the presence of various faulty zones.

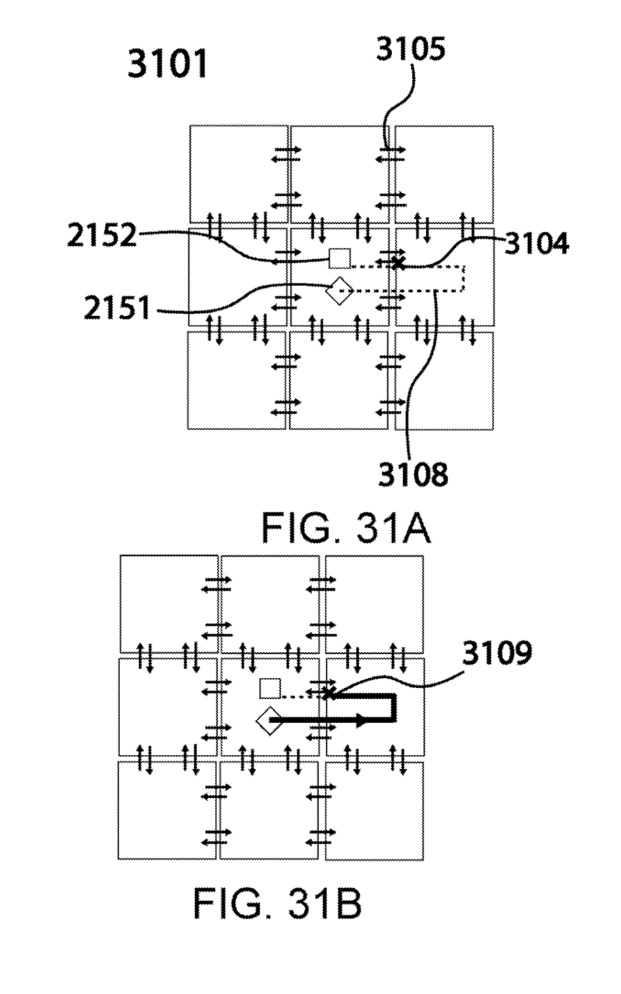

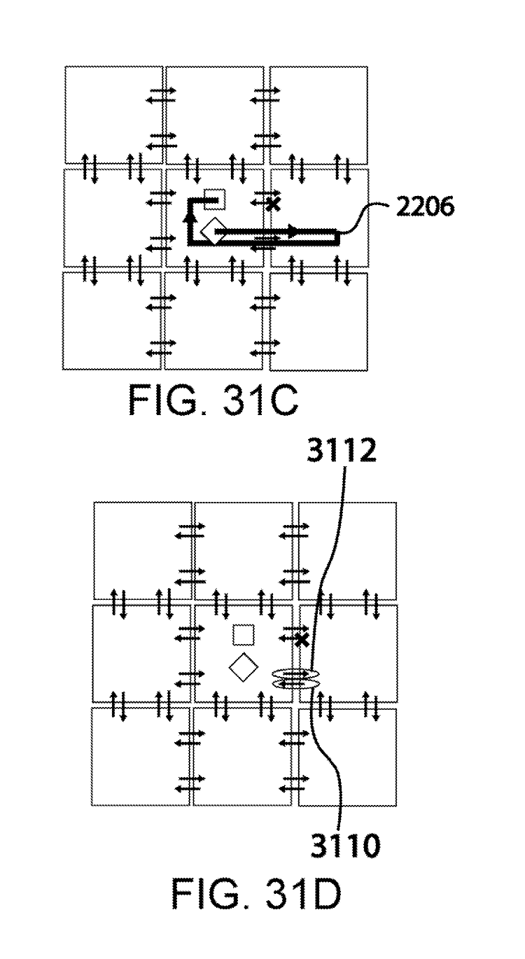

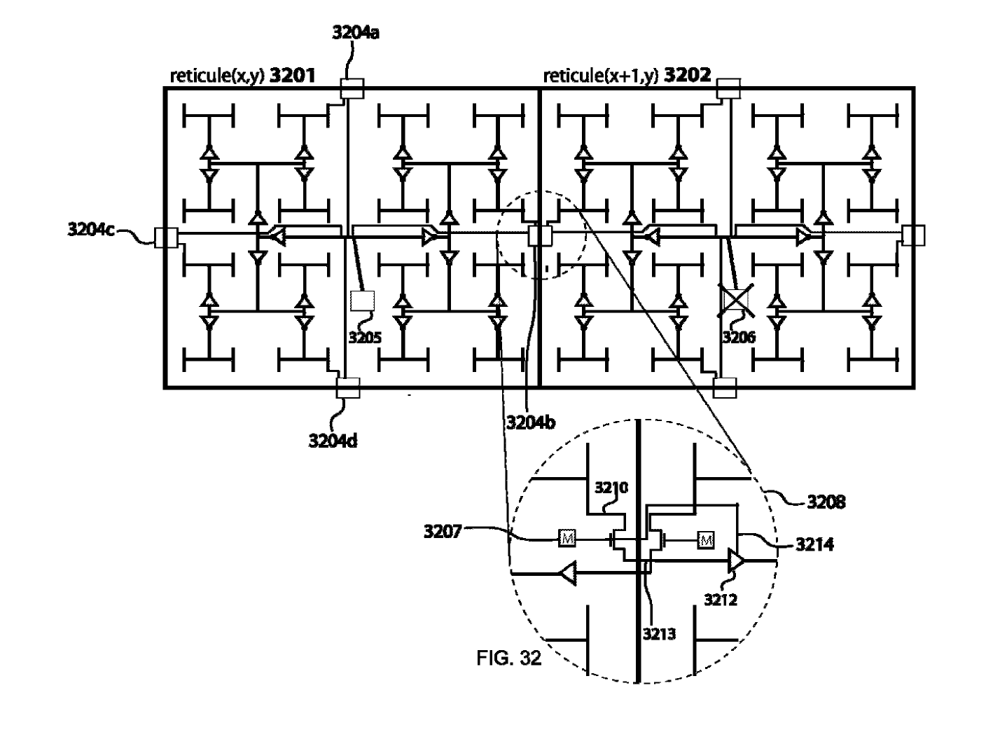

The example on FIG. 31 shows how a diagnosis algorithm can be applied on a 3×3 cell BICL architecture. The four basic steps 3101, 3102, 3103 and 3104 illustrate the diagnosis algorithm applied to a small 3×3 cells matrix. As defined in FIG. 29, a path is planned in step 3101, identified by the dotted line 3108. Once the inter-cellular scan chain is created, it is time to test it. In 3102, the signal is not propagated because of the presence of the dysfunctional links 3109. If there is no signal coming out of the output cell in 3102, then it means that there is either a broken links in the path or there is a dysfunctional cell. The result of this first test is simply registered in a database and inference rules will be applied on the database 2905 to produce a diagnosis on the state of a subset of links and cell visited by the bidirectional inter-cell scan chain. In the FIG. 31, the example shows that there is a broken link 3109 that stop the propagation signal to reach the output cell. This malfunction will be known from the application of the inferences rules 2905. In 3103, the inter-cellular scan chain can be propagated and therefore it proves that the links 3110 and 3112 are functional and the characterized state registered in the database. Inference rules can be applied proving that the link 3109 is not functional.

In most designs, there is one clock tree for simplicity. But in some designs, more than one clock tree is required. For example, in a LAIC system, a whole circuit cannot exist on the whole wafer, so a single clock tree cannot be implemented. Furthermore, each reticle must be identical because of the nature of the fabrication process (already discussed). Therefore, there is at least one clock tree on each reticle. If a clock tree is not functional, the whole reticle becomes dysfunctional. To overcome these vulnerabilities, it is possible to share clocks between reticles by configurable means. If the whole reticle is dysfunctional odds are good that the cause is a faulty clock tree. The FIG. 32 depicts at the gate level, an illustration of fault recovery from defect in the clock tree. A memory 3207 reached through a scan chain can be set to let the clock signal pass on the border between two reticle (3201 and 3202). In each reticle, the H tree clock is represented. In this preferred embodiment, each clock receives its signal from an external means through a TSV (through silicon via). Each TSV of the figure is represented by a dark square (3205 and 3206). The 3206 TSV contains a fault, so the entire reticle 3202 becomes dysfunctional. To recover from this fault, it is possible with the present invention to get the signal from the reticle 3201 and “share” it to the reticle 3202 with a configurable pass gate included on each side (example 3204a-3204d are for reticle 3201) of each reticle. A zoom 3208 has been included in the figure to show how the device works. In this portion of the figure, the signal that is shared 3210 comes from the functional reticle 3201. The signal crosses over the gap that exists between reticles with a special trace 3213 that has been added. The signal coming from clock tree is allowed to cross the first configurable gate and reach a tri-state buffer 3212 that re-amplify the signal and throws it to the root of the clock tree. Therefore, if the TSV was dysfunctional, the clock signal can be recovered from an external source.

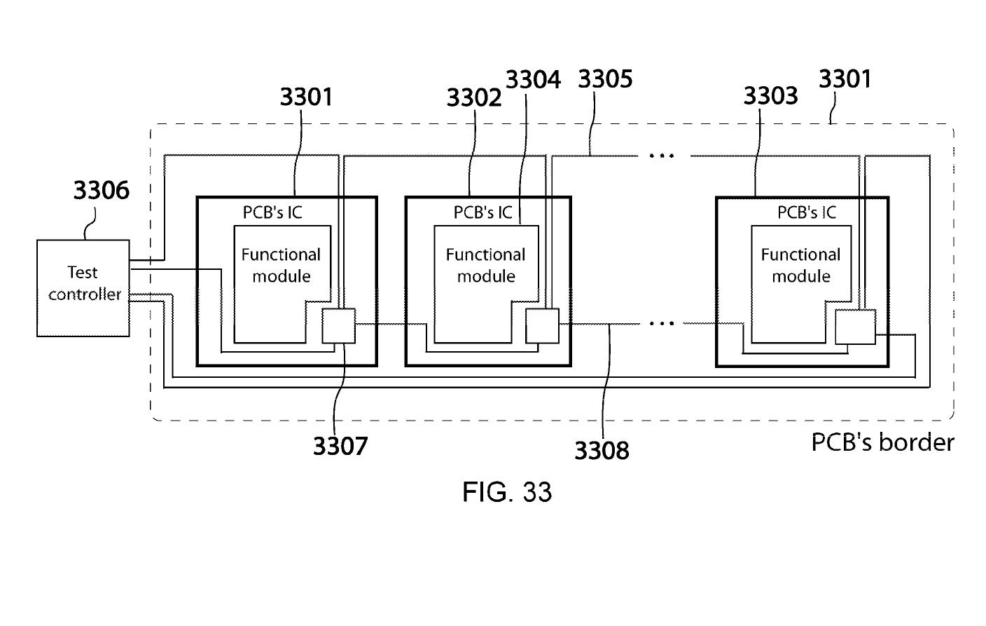

An extension of the first family of preferred embodiments is to apply the invention to make fault tolerant JTAG for Large area micro systems (LAMS). If there is only one daisy-chained scan chain between all units under test and if there is a fault in this scan chain, the whole LAMS becomes non testable, and therefore dysfunctional. This vulnerability can be avoided by the system embodiment depicted in FIG. 33. System 3301 is a particular application of the unidirectional inter-cellular scan chain. Instead of having a set of cells organized in matrix, it is a set of ICs 3302 organized in a daisy chain where every inter-IC link 3305 has a duplicate link 3308. The test controller 3306 has n points of access to feed data into the LAMS and receive data potentially from n sources. Each IC in the LAMS has two internal modules: (1) the test module 3307 and (2) the functional module 3304.

When n equal 2, if there is one fault in one link, it is possible to overcome the faulty link by using the other one. This process of bypassing the fault by finding an alternative path is fundamentally the same fault tolerance method as proposed in the first family of preferred embodiment with the UICL architecture for LAIC. The need for diagnosis remains in this system because it is required to know where the faulty link is located in order to activate the other path.

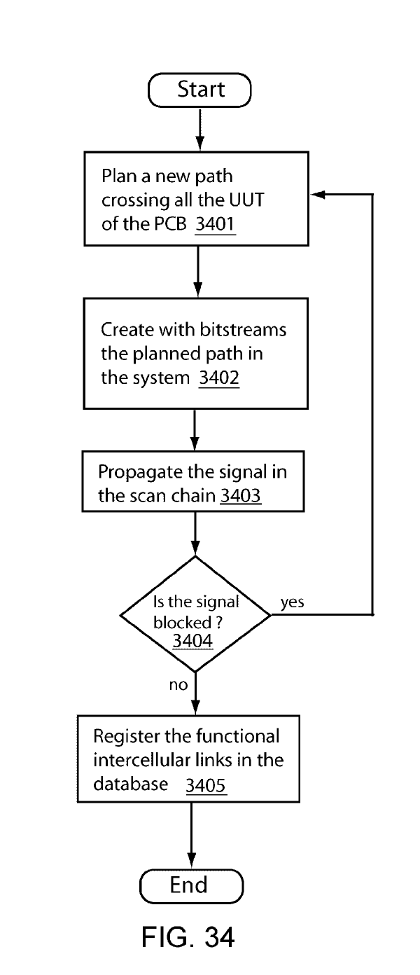

Because the network chaining all LAMS's ICs is not a lattice, the algorithm depicted on the FIG. 29 is not applicable. Another algorithm must be defined. The FIG. 34 depicts the state flow of the algorithm. The first step 3401 is to plan a path between ICs. There are as many as 2^{m×n}−1 permutations of paths between “m” ICs. The second step 3402 is to create the data stream for the planned pat. The third step injects the data stream into the LAMS 3403. If there is an output data stream and it is as expected the planned path is functional, step 3404. If the planned path is functional, it is registered in a database for further uses 3405. If there are one or more faults on the scan chain, then the signal is blocked and no signal is received on the TC end 3404. The process iterates until a functional path is found.

A versatile reconfigurable scan chain has been designed not only for defect tolerance but also to optimize the diagnosis and test speed of large NoC or NoW. The method disclosed here is a speed optimized version of the basic walking-one depicted in the Prior Art section.

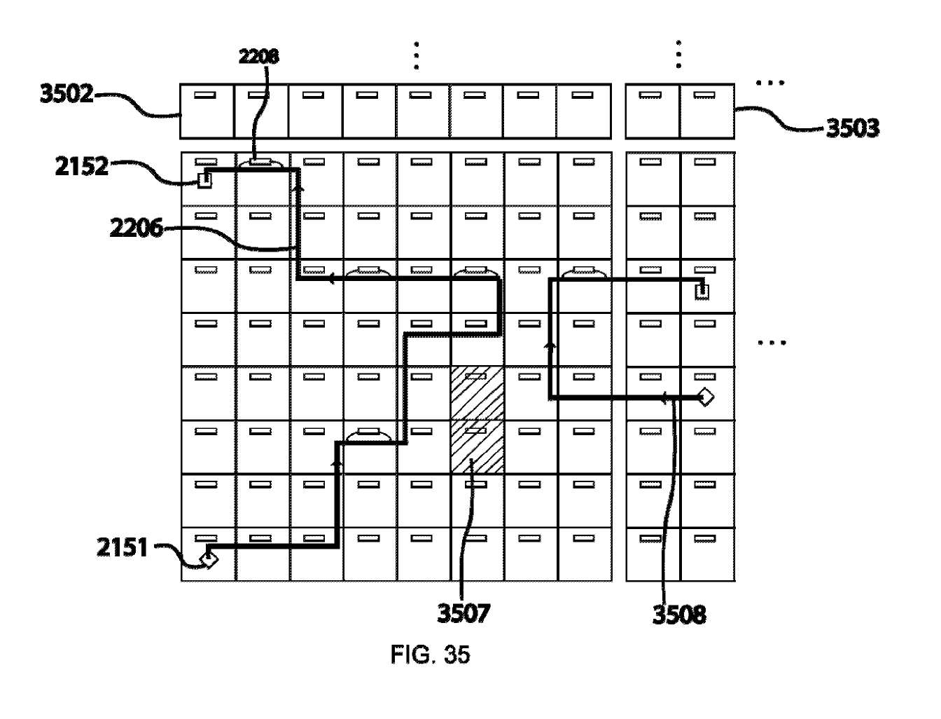

An example of the capabilities of the versatile reconfigurable scan chains is illustrated on FIG. 35. Each scan chain 2151 has at least a starting point 2151 (from the test controller) and a loop back point 2152 (to come back to the test controller for result analysis). Between the starting and the ending point defects 3507 can make the scan chain unable to propagate to the test controller. Having reconfigurable capabilities in the scan chain to avoid faults not only allows defect tolerance during a configuration phase, but also allows defect tolerance during the diagnosis phase.

Another benefit of having a versatile reconfigurable scan chain is to take advantage of the TAP controller array (not shown on the FIG. 35) to configure each cell that is part of the scan chain to be in a bypass or test state 2208. Multiple versatile scan chains (3508 and 2206) can make tests on the same area (for example on the same reticle).

As stated earlier, fault diagnosis using the walking one approach has three test phases. The first test phase (A) is fast and easy to complete, therefore it does not need optimization.

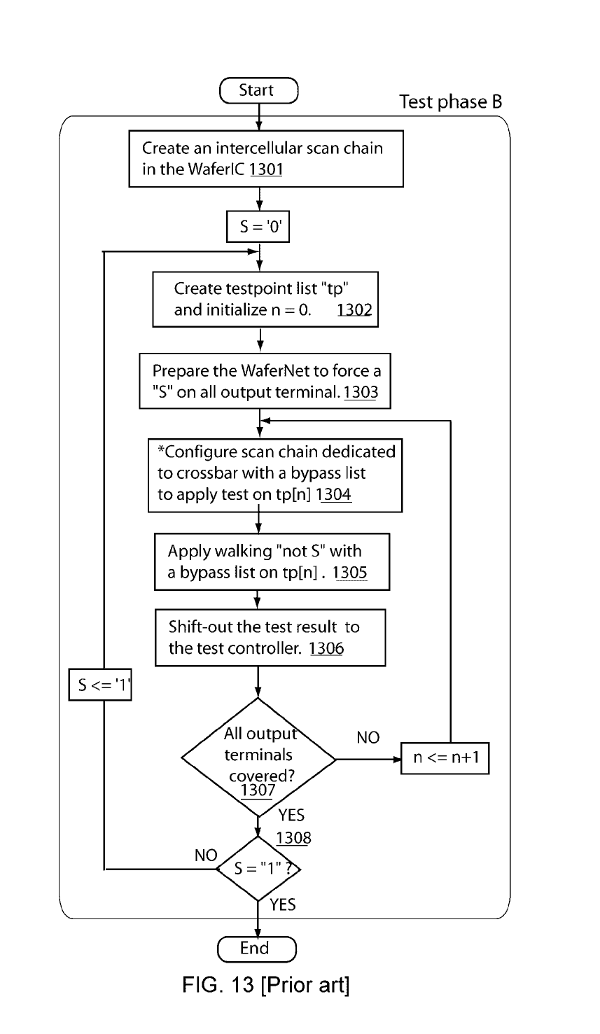

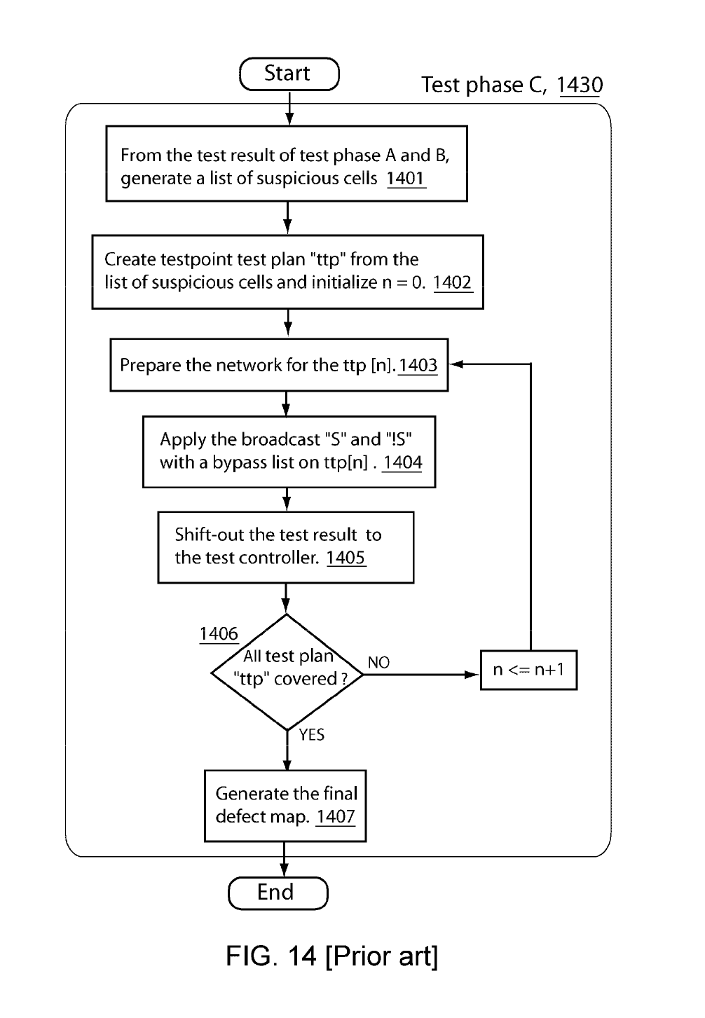

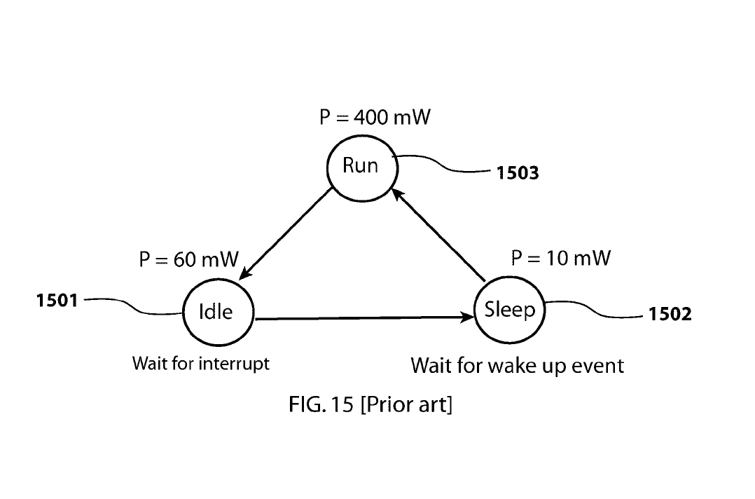

Test type B is by far the longest step of the walking one algorithm and therefore needs to be optimized. FIG. 13 shows the flowchart for the optimized version of the algorithm. The first step 1301 is to create the intercellular (or inter-crossbar) scan chain according to the defect map for configuration. It is important to remember that there are two defect maps: the configuration defect map for the configuration circuit; and interconnect defect map for the online, current usage of the LAIC circuit. There are also CMPIO defect maps, but test and diagnosis of CMPIO is so trivial that there is no need to disclose this method.

Because test type B can be used concurrently among network crossbars, a test point list must be created 1302 that schedules the test of each crossbar input of the circuit. This list, once created can be partitioned to share the test workload on more than one crossbar input (more detail on concurrent testing will follow shortly). Once the list is created the RRN must be prepared by forcing an “S” logical value on all input terminal of each crossbar 1303. At this step, each crossbar must be configured in a one-to-one state where every crossbar input is re-directed to one crossbar output to activate all interconnect and allows interconnect observation. The logical “S” value is 0 if the algorithm is shifting a walking “1” and “S” is “0” if the algorithm is applying a walking “0” on crossbar input.

The next step 1304, 1305 is to create a bypass list, i.e. a list of unused and unprogrammed cell to the application of the current walking one or zero in the network. From the bypass list, there is (implicitly) a test list that can be generated because test list and bypass list form a partition of the whole test point list. Step 1304 is simply to execute the network modification only on crossbars affected by the walking one or zero. Because of the bypass list, only affected crossbars are reconfigured. Furthermore only the proper crossbar inputs are changed through the crossbar test scan chain as the walking one moves forward in the test point list 1305. Therefore, unnecessary scans are limited and the test speed can be improved significantly. Once the algorithm has visited all test point list, the walking-one is repeated, but with a walking-zero 1308.

The flowchart step 1306 “shift-out the test result to the test controller” is the most time consuming sub-step of the test type B. Shifting out the result to the test controller means that all the observation registers of all crossbars are included in this shift. This can be a very substantial amount of data if the NoW or the NoC contains numerous interconnections. Therefore, this step must be optimized. There are two methods to accelerate this part the algorithm: (1) use concurrent walking ones; or (2) using the principle of cone of influence to shift-out only the needed information for every test.

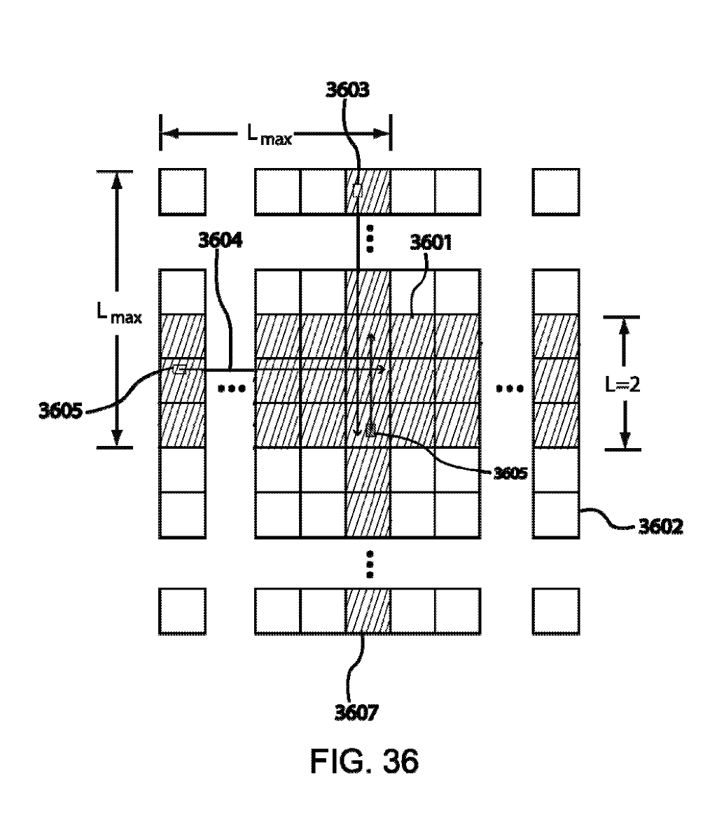

FIG. 36 shows how far the cone of influence extends over the array of cell 3602 in the network. Each cell contains a crossbar, which is not shown in the figure. The cone of influence is the zone created by the maximum distance between two points in the network. The first point is the input terminal on which the test vector pattern is applied (3605). The second point is the most distant interconnect source. The same point exist on both vertical 3603 and horizontal 3605 extend to form a large “cross” in the in the cell array. On the FIG. 36 is shown a particular example of a cone of influence for L=2, where L is the interconnect length of interconnects under test. The size of the cone of influence is dictated by the most distant interconnect from the interconnect under test (Lₘₐₓ). Cells that are part of the cone of influence are shown in dark 3607 and cells that are outside of the cone of influence are white squares 3602.

Knowing the exact extent and geometrical form of the cone of influence is the basis for a dramatic improvement in test speed of the test type B, and because of this, improvement of diagnosis speed of the whole algorithm is possible. Each new walking “1” or “0” applied to interconnect under test creates a new and unique cone of influence. Therefore, the algorithm must keep knowledge of the modification of the cone of influence as new walking one are applied to the network under test. This knowledge can then be leveraged to shift data only from cells that are part of the cone of influence. This is possible with the use of the TAP controller cell array available in any of the CICU, CICB or RA link architectures disclosed in this document. The list of cells part of the cone of influence is the basis for the generation of a test bypass list applied at the step 1306 of the flowchart of the test type B.

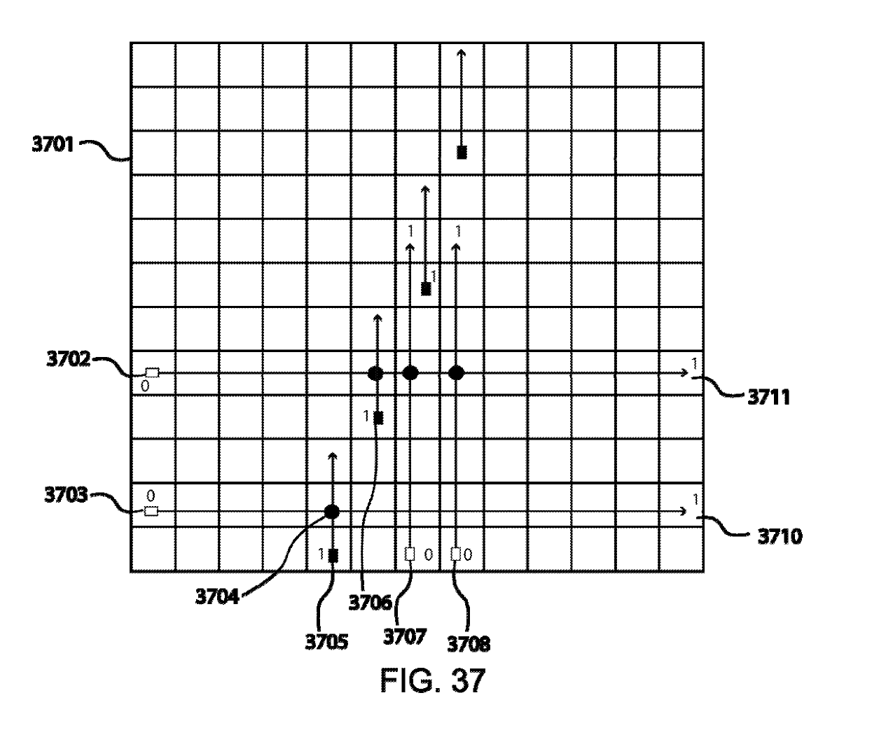

The second method to improve speed is to use multiple walking ones concurrently, as shown in FIG. 37. In this method, the cone of influence of each walking-one is allowed to overlap lightly. Instead of shifting only the relevant register for test result as explained previously, all the observation registers are shifted-out with as many as possible walking ones tested at the same time. This method improves speed at the cost of test coverage because fault masking and fault diagnosis problem emerges. FIG. 37 depicts a particular example limited to a portion of the cell array 3701, where crossbars are not shown and only relevant interconnect are depicted. The interconnects under test of a set of concurrent walking ones (3705, 3706, 3712, 3713) is depicted on the figure, each testing the same type of interconnect length (L=2) and direction (north). This example shows the resulting effect of multiple shorts on observation registers. Shorts are represented with dots (3704). Multiple shorts on the same interconnect can create problem when it is time to locate exactly those shorts. Shorts between 3705 and 3703 are easily tractable, but because of the multiple shorts on the interconnect defined by 3702 and 3711, it is not possible to track those fault with one test pass only. For example, it is not possible to differentiate with certainty two possible cause of the short. Is it a short between the interconnect pair 3712 and 3707 or between interconnect pair 3702 and 3707, or between 3712 and 3708, etc. A solution to this problem is to re-use the walking one algorithm without concurrency only for region of the network where faults are detected. Since faults occur on only a minute fraction of the multitude of interconnects, this rechecking is insignificantly in comparison to the time savings from concurrent walking ones.

A diagnosis method disclosed in this document is to create rings of any form, particularly close loops, and associating a test pattern generator (TPG) that plays the role of the transmitter and a response analyzer playing the role of a data receiver is associated with each ring. In the presence of a fault free ring, the transmitter and the receiver should receive the same signal; otherwise, a single fault is detected in the ring.

To avoid any fault mask caused by multiple fault in the network, each network interconnect are tested by multiple ring each having a unique form and location. BIST PR has the advantage of being able to test dynamical fault, SA and even short fault. Moreover, this document discloses special techniques to make diagnosis as efficient as possible and to enable the detection and localization of short fault.

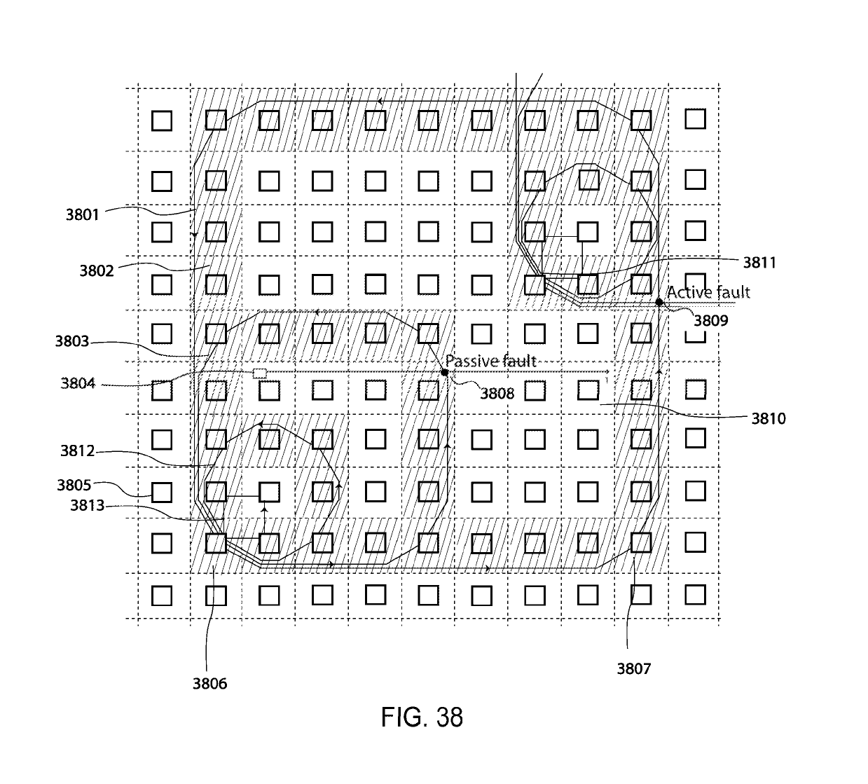

Another diagnosis method disclosed in this document is based on a “RING BIST”. BIST means build-in self-test. In order to design a BIST system, it is required to include a device that enables auto-generation and at least makes compaction of the result data generated from tests. RING BIST creates on the same cell position both test vector pattern and test vector reception and compaction. Moreover, this approach uses reprogrammable capabilities of the network to create multiple concurrent rings to test the circuit. Most of the faults detected from this RING BIST are localizable. FIG. 38 illustrates the diagnosis process. In this figure, four rings 3801, 3803, 3812, 3813 coming from the same source 3806 are created from a portion of a larger network. Source cells 3806 and 3811 activate cells 3802 in each ring, shown in hatched cells. The source cell contains both a test pattern generator and test response compactor (not shown on this figure). Every activated cell can use a crossbar to re-direct the signal 3807 in a new direction or participate to the diagnosis as a repeater cell.

Ring BIST is able to detect crosstalk faults. In order to do so, multiple signal rings must intersect each other or be closed together in as many combinatory patterns as possible. Moreover, at-speed test can be completed, because the signal emitter and signal receiver can be clocked by the same signal coming from a closed source to maximize clock speed. An example of overlapped RING is shown on the FIG. 38.

Multiple “RING BIST” can overlap each other in order to reveal crosstalk fault, or shorts. Such faults are called active faults 3809, because it implies at least two known interconnects in the process. If used as non-overlapped rings, tests can reveal the location of at least noise faults or delay faults. Locating with precision active faults needs a special algorithm. This special algorithm is detailed later in the present application.

On the contrary, passive fault 3808 implies one activated interconnect transmitting a signal and one passive interconnect capturing a constant value from a distant source. In order to detect and locate such faults, the same logic is used as in walking-one algorithm.

During the application of the walking ‘1’, it is required to force a ‘0’ on all control registers of the network. Such precaution enables the diagnosis of shorts on any pair of interconnect (parallel or perpendicular). The same idea applies for shorts diagnosis. Every passive cell (for example 3804 and 3810) must force a constant logical value that is the complement of the logical valued forced on the ring interconnects. If there is a short (such as 3808) between a ring and any passive interconnect such as the interconnect that is shown on the figure between 3804 and 3810, then the capture register will reveal the fault.

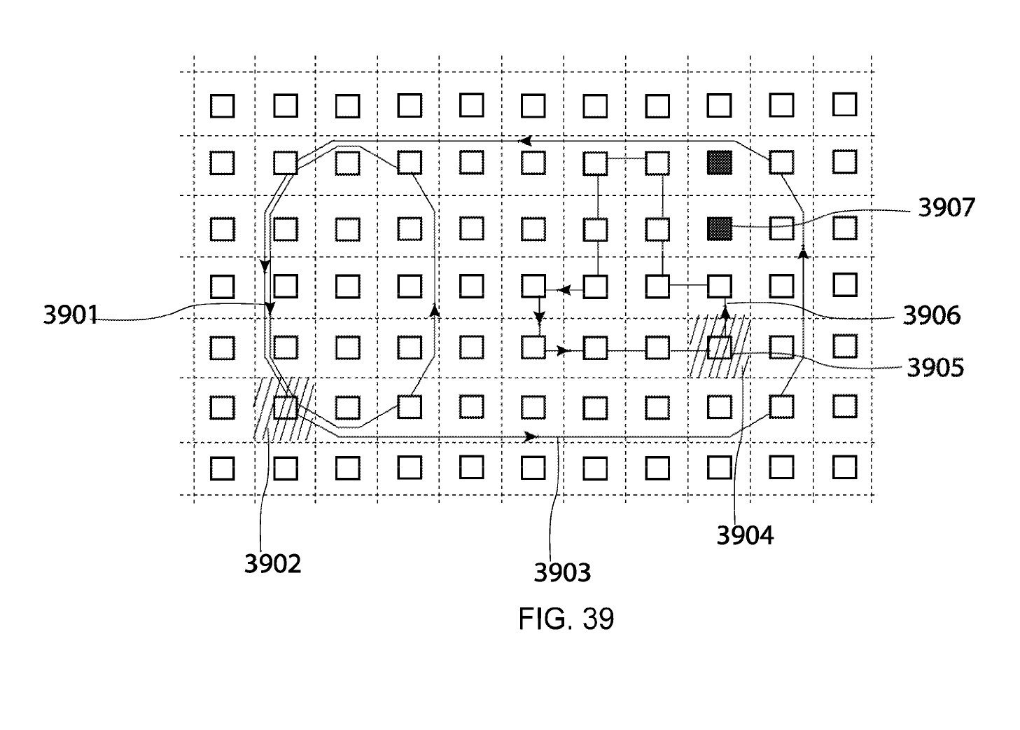

FIG. 39 depicts various ring forms that can be created for diagnosis in the presence of faulty crossbars or cells. For example, rings 3901 and 3903 created respectively from source cells 3902 and 3904 respectively can be used to create a particular delay between the test vector generator and the test vector receiver to reveal delay faults, etc. Rings can be of any form, and special irregular rings such as 3906 can be used to test and diagnosis interconnect faults in the presence of faulty cell 3907, as shown on the same figure.

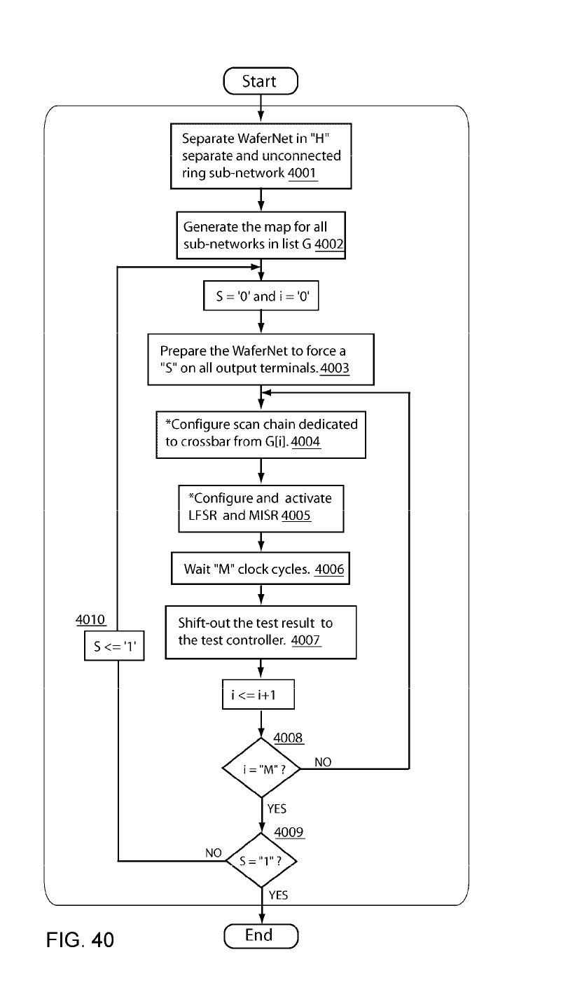

A general and fast algorithm to locate shorts, crosstalk, delay faults as rapidly as possible is depicted as a flowchart on the FIG. 40. The first step 4001 is to define a list of rings that must be applied to the network. Depending on the defect map generated from the fault tolerant diagnosis, some cells can be diagnosed to be entirely faulty. Therefore, an appropriate test list “G” each having a unique network configuration must be generated (step 4002). The size of the test list must be as short as possible; therefore a maximum number of rings must be included in each test. Then, the first test can be applied (i=0) and the RRN must be prepared for test (step 4003) by forcing a “!S” (“Not S”, or the complement of the constant logical value) to all observation registers on each crossbar output terminal. Next, the network is ready to receive the test configuration (step 4004) and then the TPG/ORA can activate (step 4005). Returning briefly to FIG. 10, the TPG was simply a LFSR (for the preferred embodiment) and the ORA an MIRS (for the preferred embodiment). During “M” cycles, all source cells generate their test vectors set (step 4006), and at the end of the count, the result from the ORA is ready to be shifted-out to the test controller (step 4007). The same process (steps 4003-4007) is repeated “N” times (step 4008) for each element of the list “G”.

The same process is repeated again (step 4009), but with a new value (step 4010) to force onto the observation register of each crossbar. In this second test phase the same test list “G” is applied sequentially to the network under test, but every TPG must generate a new test vector set to reveal new faults. An easy way to create a new test vector set is to change the number of cycles from M to M′. A second condition must be respected in order to reach 100% test coverage for short faults: the last test vector generated by the TPG must be composed of “1” if S=1 and composed of “0” if S=0. The last value generated by the TPG is very important to diagnose passive faults. This is why the same process is repeated again to reveal all the bridge fault types (wired-and fault, wired-or, A dominate B fault, etc.).

The Ring test list applied to the network creates a list of test results composed of test vectors captured from observation registers in the network. From this result, interconnect faults can be detected and located. Passive faults (e.g., 3808) can be easily located for shorts. Active faults (3809), i.e., faults detected from the ring receivers, must be located using inference rules.

Coverage can rapidly degenerate by applying too many rings at the same time. It is important to create plenty of space between ring sources in order to create a perimeter for un-activated cells. Each un-activated cell (shown in white in FIG. 38) can potentially detect shorts in the network.

The concurrent BIST diagnosis can be done from one test controller outside of the device under test of from a test controller embedded in the DUT. The device can be accessed through a JTAG port where the multiple scan chains can be selected and shifted through the standard instruction register from the IEEE 1449.1. The device can be accessed and diagnosed from a direct access to the multiple scan chain, with the TAP controller outside of the test controller.

As with each diagnosis system disclosed in this document, the concurrent BIST is dedicated to a RRN. The preferred embodiment for concurrent BIST is depicted in FIG. 41. It comprises an array of crossbar cores 4103. Each crossbar is part of a “cell” and the device is in fact a sea of regular reconfigurable cells. Each cell contains test and diagnosis means. Because of the regularity of the circuit, each cell 4106 is identical. The preferred embodiment consists of three scan chains (A_{reg}, B_{reg} and I_{reg}) from a multiple scan chain system. The function of A_{reg} is to configure the BIST counter 4106 that generates the test vector pattern known as “walking-one” or “walking-zero”. The width of the A_{reg} is “k+1” and is connected to the counter.

The walking sequence is generated from a NOR gate or an OR gate. If it is a “k” bit counter, the walking sequence can be 2^{k} bits long. A_{reg} is partitioned in two distinct parts. The first part is composed of “k” bits that define the number of register associated to the counter. The second part is composed of a single bit to determine if the NOR gate or the OR gate is activated to generate a walking one or zero sequence.

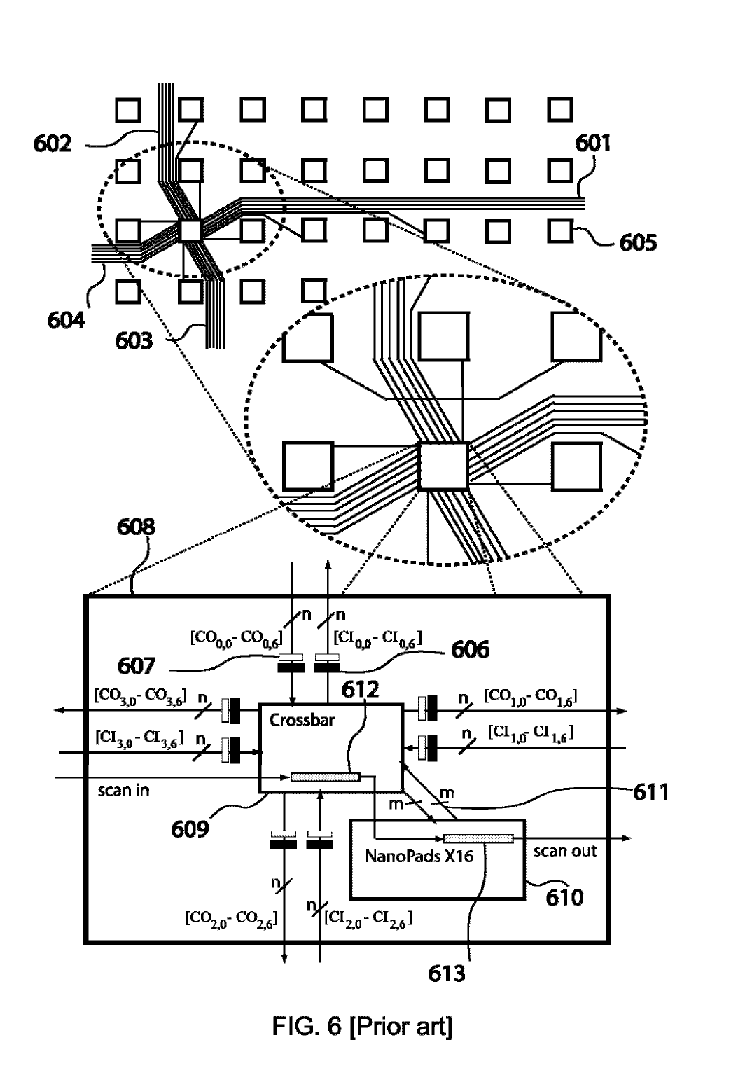

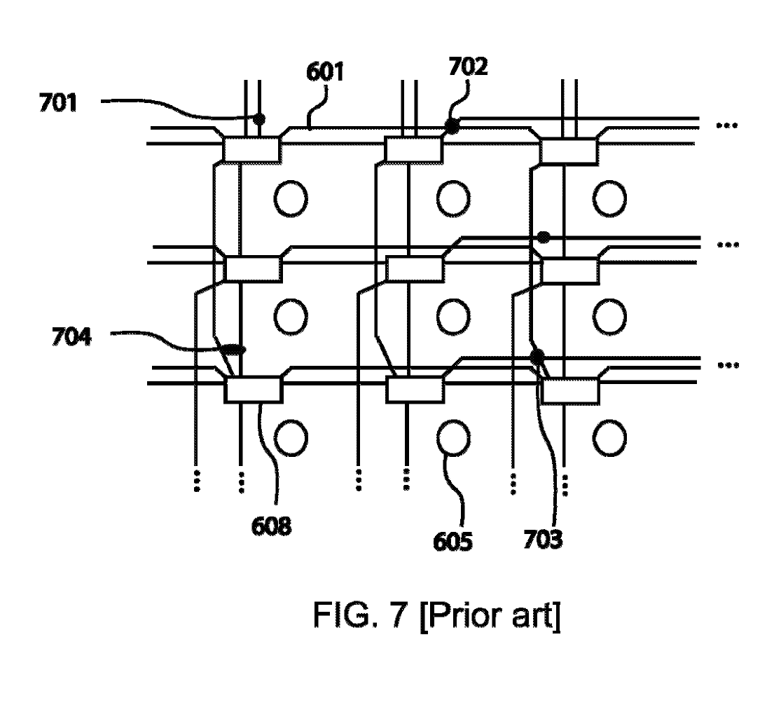

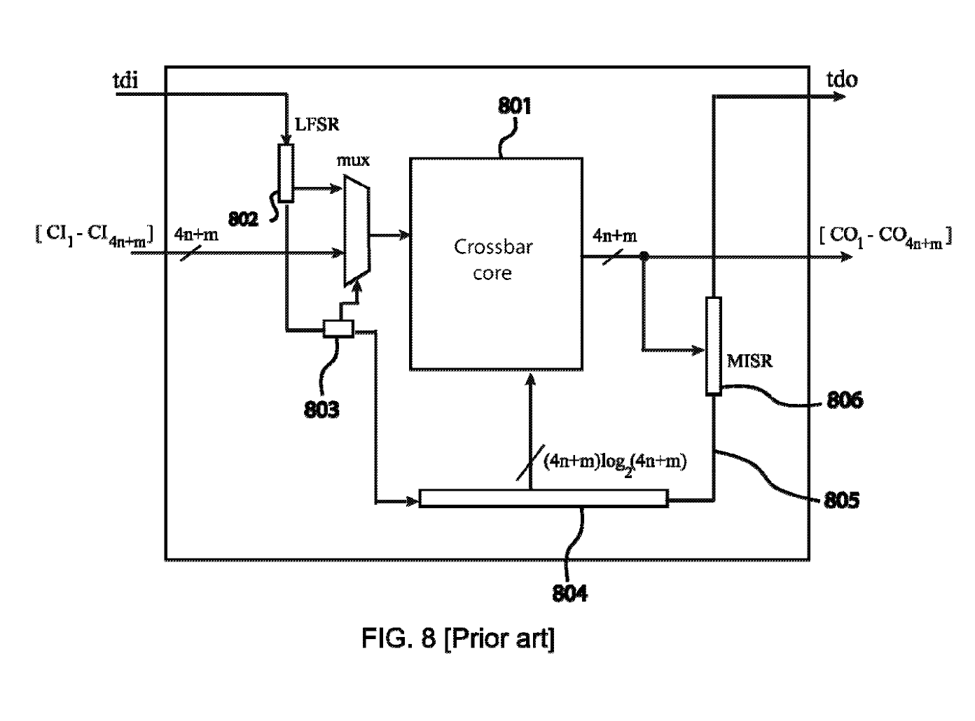

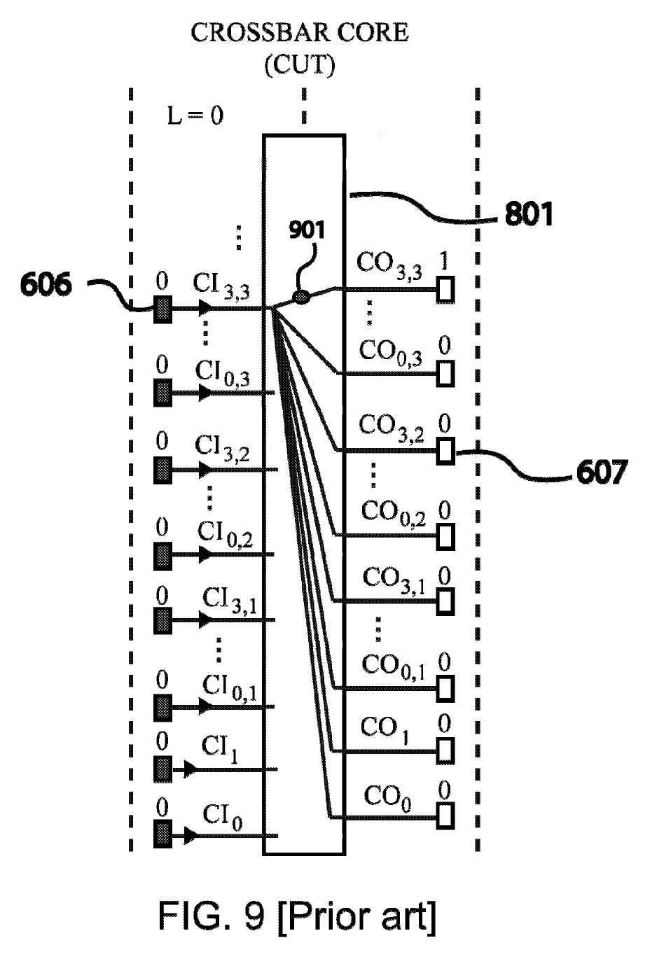

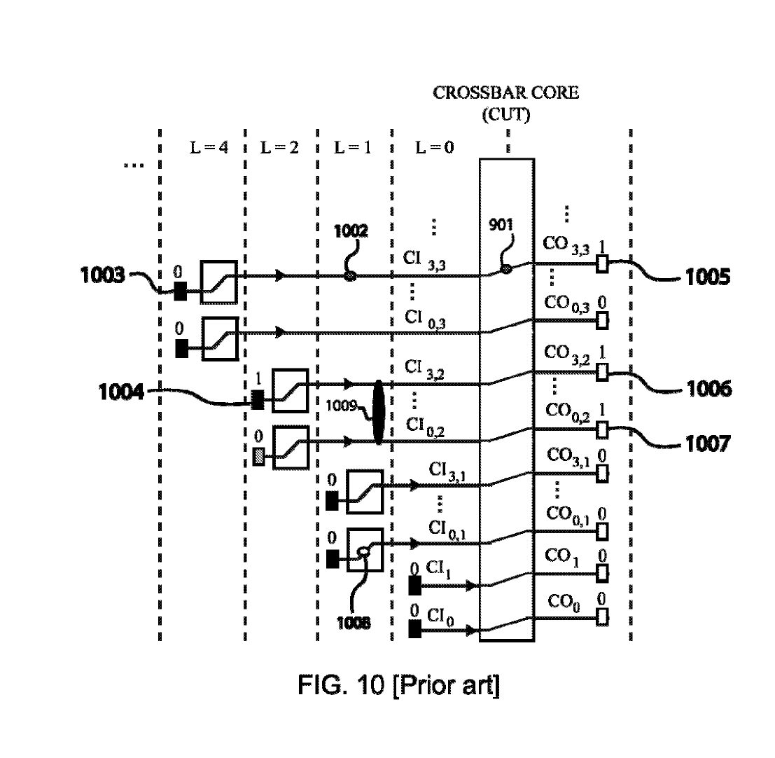

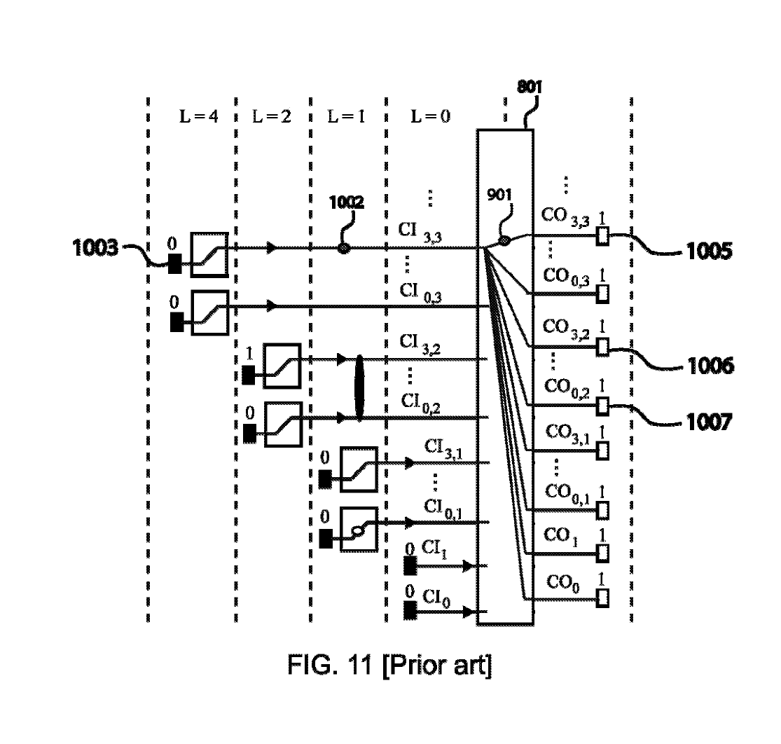

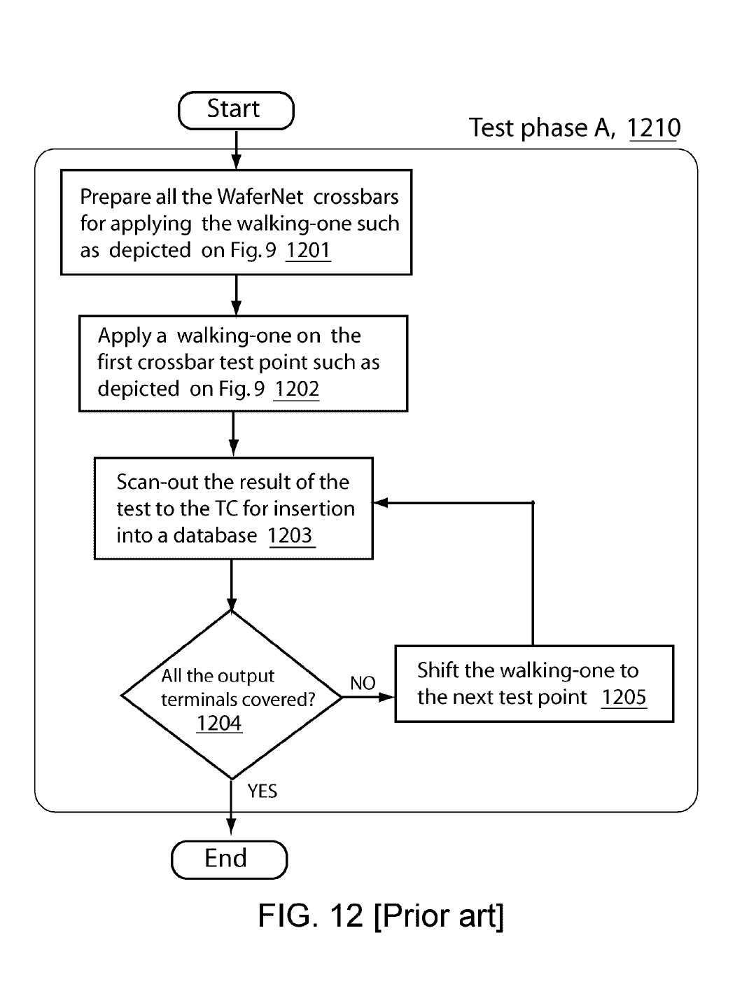

The crossbar contains 4*n+m input port (4107). Each crossbar input must be controlled with a scannable control register 4104 in contact with the output of the NOR gate (for walking one) or OR gate (for walking zero). The test mode is triggered from the test mode signal coming from the counter module 4106. The variable “n” is the number of interconnects in each direction coming out from the crossbar and is m the number of supported signal redirections from CMPIOs (see section prior art, FIG. 6). Therefore the counter minimal size is k=log₂ (4n+m).

The crossbar output 4108 must be observed with a capture register included in the walking 1/0 interpreter module 4105. The capture registers are connected 4103 to the crossbar output (4108) and they can be shifted-out directly and entirely to the test controller to locate the faulty interconnect. To make the diagnosis faster, it is possible to use the “walking-1/0 interpreter module” 4105. The function of this module is to compress the data coming from the capture register to make the diagnosis faster. The compressed data is transferred to the I_{reg} to be shifted-out to the test controller. Normally, in the presence of a fault-free network, all interconnects of the network must give an equal constant logical value (same value on all crossbar output). An exception occurs in only two cases: first, if the interconnect under test that is associated to the walking sequence (the interconnect under test) works properly, that interconnect will differ from the other; and second, if the number of ‘1’ is larger or equal to two, then it is the proof that a fault is present in the interconnect under test included in the cell. Therefore, a decoder detects the occurrence. Therefore, if a logical value is found in the I_{reg}, then, it is either a faulty interconnect or it is the normal output of the walking sequence on the observation register. Because the order of appearance of each cell is known in the scan chain, it is possible to locate faults.

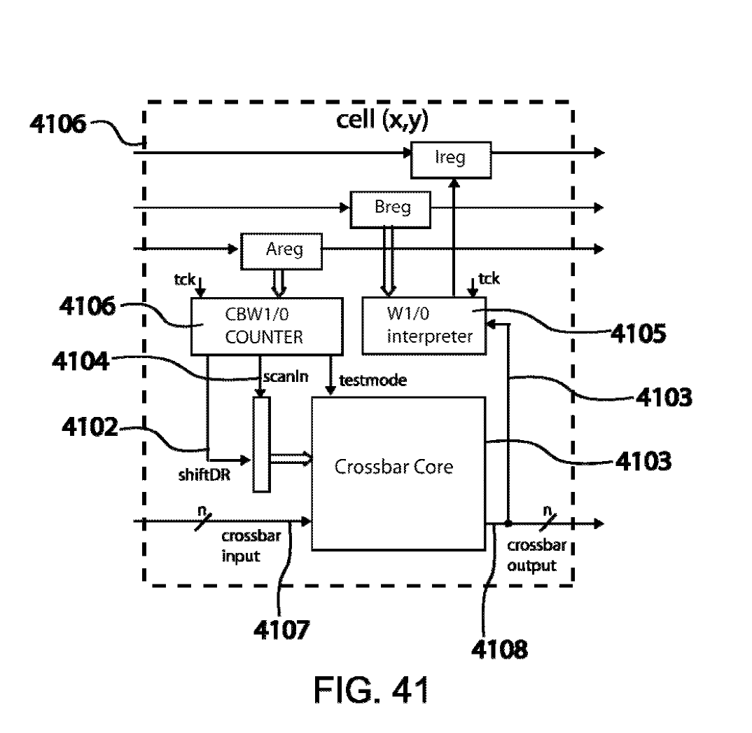

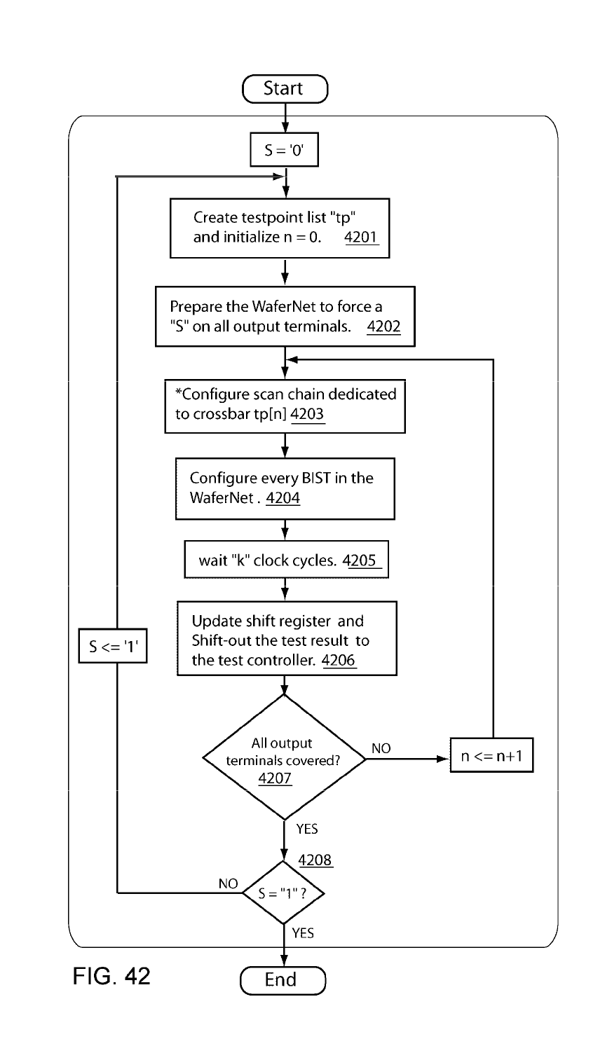

The hardware architecture described above is designed to apply multiple concurrent walking-one sequences on the same network with the same scan chain. The flowchart depicted in the FIG. 42 describe the minimal step to complete in order to create a concurrent walking one sequence with only three scan chains. The first step 4201 is to create a test point list “tp” that includes all interconnects under test of the network. Then the network must be prepared for the diagnosis (step 4202) by forcing a “!S” value on each interconnect of the network under test. For example, if “S”=1, then the forced value on each interconnect is “0”. At this stage, every crossbar (step 4203) and BIST (step 4204) are ready to be configured for the specific walking sequence. BIST are configured through all the A_{reg} part of the daisy chained scan chain. Then, every counter from every cell is ready to be activated. To be sure that the whole walking sequence is applied to all cells, ones must wait k=log₂ (4n+m) (step 4205). After the count, the test controller can collect test result data from the walking-1/0 interpreter module included in each cell (step 4206). The same process is repeated (step 4207) until reaching the end of the “tp” list. Then, the whole process is repeated again, but with a complementary value of “S” (step 4208).

Second Family of Preferred Embodiments: Contact Detection Methodology by Locating Short Between CMPIO.

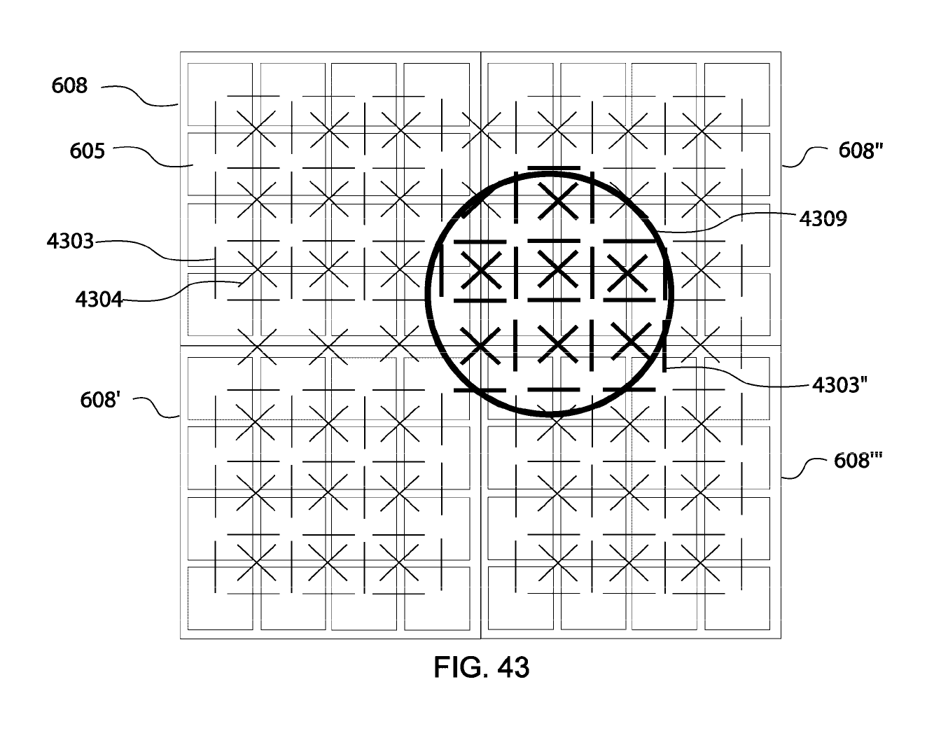

By default, no shorts should be present between CMPIO. If a short exists, it must be located with a proper algorithm. FIG. 43 depicts the basic mechanism underlying short detection between CMPIO. In addition to shorts between CMPIO caused by defects being found, the same test procedure can be used afterward to detect shorts between CMPIO caused by uIC pins pressed against the CMPIO, thus serving for contact detection between uIC pins and the CMPIO array. FIG. 43 shows a portion (4 cells: 608, 608′, 608″, 608′″) of the WaferIC each having an array of 4×4 CMPIO 605. A uIC's pin 4309 is shown on the same figure to illustrate its effect on short circuits between CMPIO. Each line 4303 and each line 4304 between CMPIO has potential shorts to diagnose. Lines that are shorted by the uIC's pin 4309 are shown in bold, such as line 4303′.

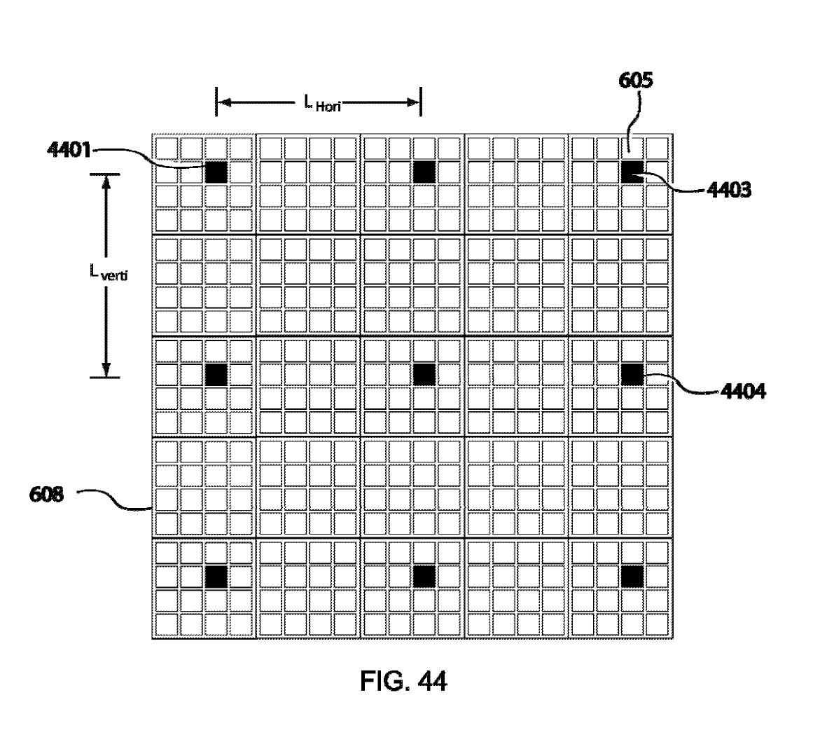

To diagnose short locations in the sea of cells (WaferIC), diagnosis algorithms are disclosed in this section: (1) the walking one algorithm. FIG. 44 depicts a typical walking one configuration on a portion (4×4 cells 608). All the CMPIO of that portion of the WaferIC are represented by small squares 605. To make the walking sequence more time efficient, it is possible to include more than one walking sequence at the same time in the circuit. For example, the FIG. 44 includes 9 walking sequences each represented with a dark square 4403. The distant walking sequences can all be separated by the same gap (Lᵥₑᵣₜᵢ or Lₕₒᵣᵢ) or can be separated by an irregular pattern. The minimum gap must be greater than the smallest uIC pin that is supported by the WaferIC in order to locate shorts efficiently. The same process must be applied with the complementary walking sequence i.e. ones must apply a walking one sequence and then a walking zero sequence.

Third Family of Preferred Embodiments: Configurable Interposer for Three Dimensional Large Area Integrated Circuits

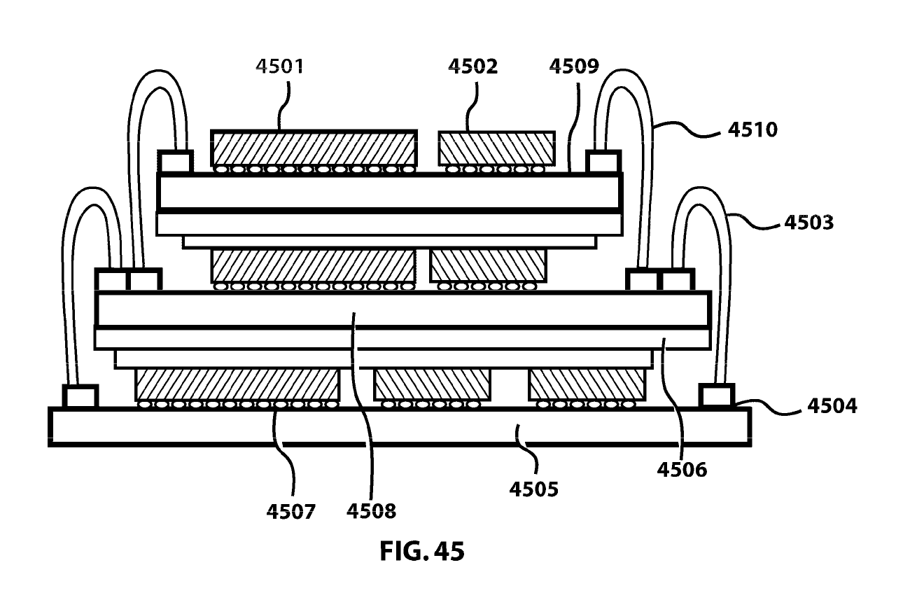

FIG. 45 depicts a preferred embodiment of the reconfigurable interposer for System in Package (SiP). This figure depicts an example of usage of the configurable interposers (4505, 4508, and 4509) for production or for rapid prototyping of digital circuits. Each level of the 3D IC is defined by one layer of configurable interposer and one layer of a functional chip (for example 4501, 4502). On the same figure, 3 layers are shown where a configurable interposer (such as 4505, 4508, or 4509) is placed between each layer of the SiP chips. The wire bonding (4510, 4503) is used as a mean to interconnect the adjacent level of the system in package.

The configurable interposer is in fact an active substrate containing active digital and analog circuit. The first usage of the configurable interposer considered is as a configurable NoC to receive or transmit data on each pin of each IC die of the system. Any set of conventional chips or ICs placed anywhere on configurable interposer can be connected to any other chips or ICs placed on another system layer in 3D stacked chip. Moreover, the configurable interposer embeds an array of tiny “CMPIO” to enable electrical contact between uIC pins and provide power to the user's ICs. The uICs can be any CPU, microcontroller, FPGA or any IC whose pinout or ball-grid is compatible with the configurable interposer CMPIO array. The use of a sea of tiny CMPIO supports compatibility with a wide range of pin and ball types, spacings and patterns.

The configurable interposer comprises a regular array of unit cells, with each cell comprising at least a configurable crossbar, an array (preferably 4×4 or more) of CMPIO, a configurable assertion checker, a configurable logic cell, and a microcontroller. The configuration to a particular state for each cell's crossbar creates a unique interconnection network mirroring the desired topology of the system composed of multiple layers of interconnected uICs.

Because the tiny CMPIO array is deployed on the entire active surface of the configurable interposer, the wire bonding (4503) that connect multiple layers together are in contact with the CMPIO arrays, for example at 4504. This electrical contact can become a real digital connection by properly configuring the configurable interposer's crossbar to create the desired connection between elements of different system level. For example, uICs 4501 and 4502 can be connected to uIC 4507 through wires 4510 and 4503 and through the configurable interposers 4509 and 4505. A layer of power blocks (4506) is used in each level to provide power to the configurable interposers.

The power is delivered to the ICs by the means of the configurable interposer. Each CMPIO can be configured as a VDD, GND or as an I/O. All power rails of the system can supply current or drain the current outside of the SiP.

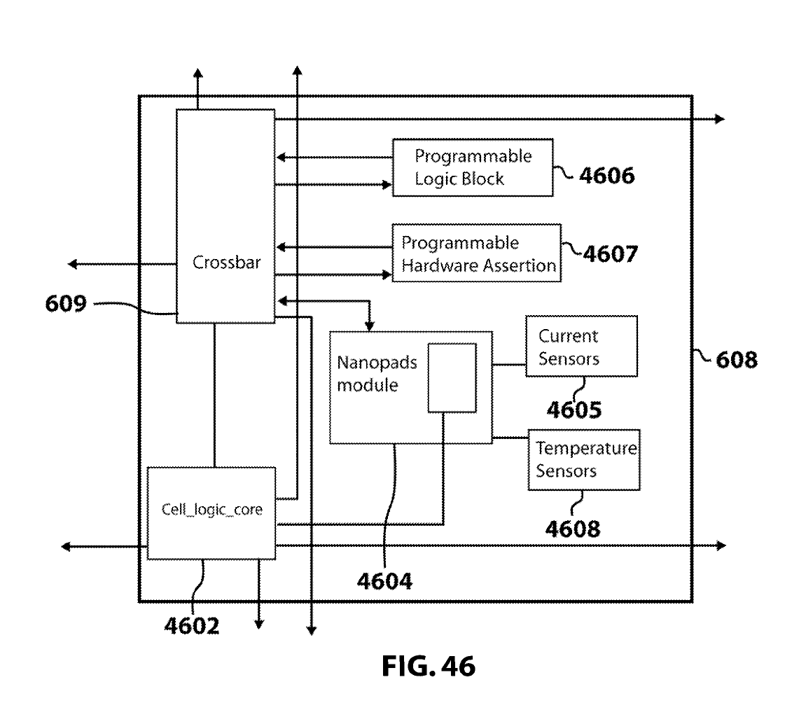

FIG. 46 depicts a logic block diagram of a cell 4601 of the regular array of cells for a preferred embodiment of the present invention. The first logic block is (4602) which corresponds to the cell logic core where the majority of the logic for the configurable system is concentrated. The configurable crossbar is depicted in 4603. The CMPIO (4604) are contained in a logical module (each CMPIO also contains special analog circuitry depicted elsewhere in the present application. Module 4606 contains the configurable logical assertion checkers and module 4607 contains the configurable cell logic block. The usage and the precise functionalities of each of these blocks will be described later in the present application.

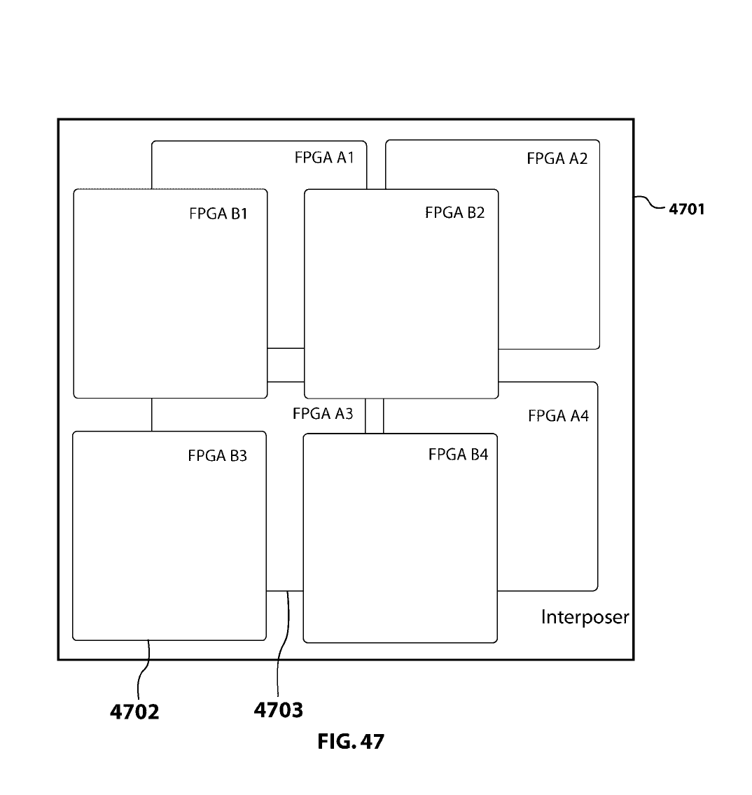

FIG. 47 depicts an example application where a configurable interposer 4701 is used to implement a fully expendable array of high performance FPGAs 4702. The geometrical expansion of this array is possible in the Z axis by stacking an arbitrary number of levels of circuits. The geometrical extension of the array of FPGA is possible in the XY plane too. Therefore, it is possible to create system comprising a massive number of FPGA where all interconnections between FPGA pins remain configurable, and can be dynamically customized to fit a given application. Moreover, the FPGAs can be used without their packages (with bare FPGA dies), enabling the array of FPGA to be energy efficient and very densely integrated in a 3D structure. Several variations of this concept are possible if the system assembled from ICs and interposer combines FPGAs, memories of and processors of different kinds coming from possibly more than one vendor and manufactured with different microfabrication technologies. This would enable building a wide range of defect and fault tolerant system, or energy and power efficient systems and of configurable/reconfigurable architectures not possible with a single IC manufactured with a single technology.

Rather than using FPGAs 4702, the interposer 4701 could be populated with advanced reconfigurable GPUs each having the possibility to interconnect with other adjacent GPUs to optimize that array of GPUs for a given processing application (e.g. bioinformatics, interpretation of seismic data, etc.) because the interposer is configurable.

FIG. 48 depicts an example of a system level 3D stacked IC. The uICs are indicated by the numbers 4808 and 4809. The configurable interposers (4801, 4803, and 4807) are filling the space between uICs. Two power block layers (4804 and 4805) are supplying current and decoupling capacitance to the whole system. The power and the GND are connected to the power blocks by the mean of TSVs (Through Silicon Vias) (4806 and 4810). If the uICs used for the design of the 3D IC system are not filling the whole surface of the configurable interposers, then a special material such as SiO₂ or epoxy is used to fill the space between layers (4802, 4811).

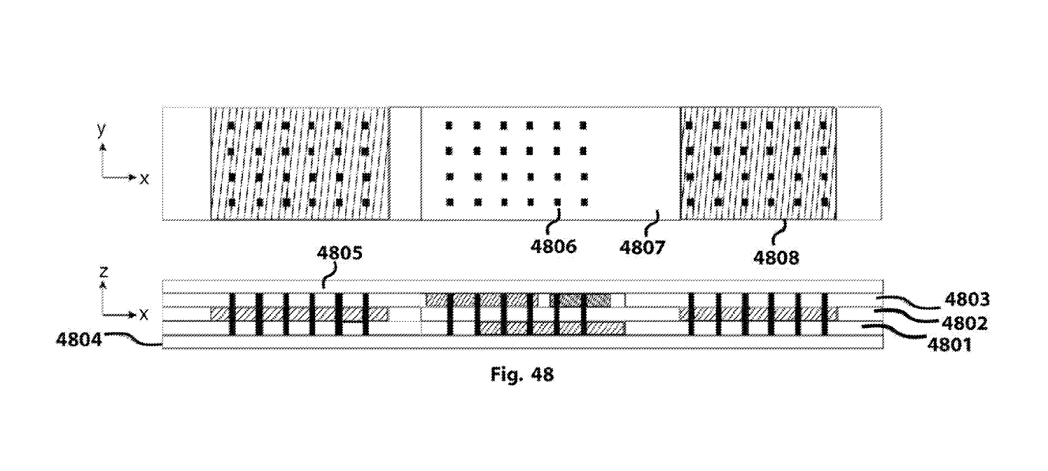

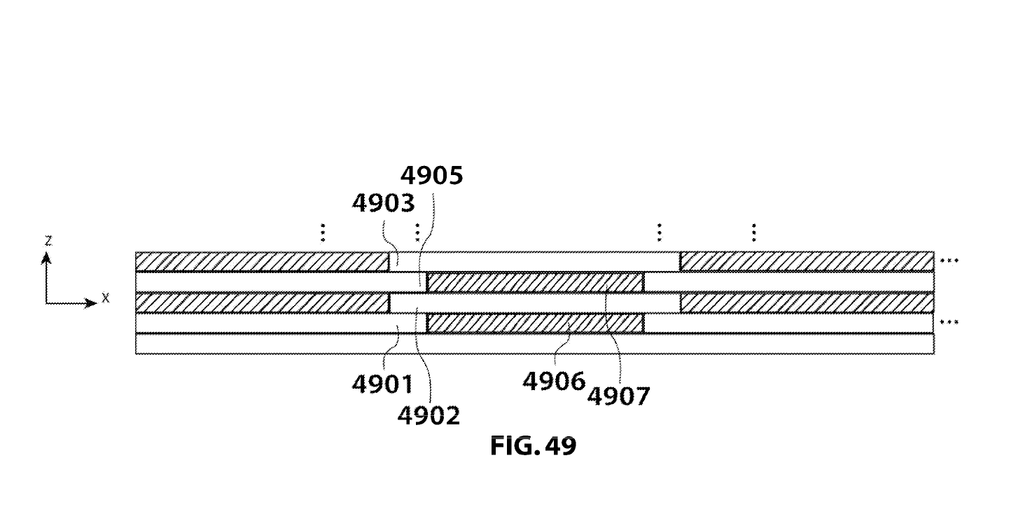

The uIC and configurable interposer arrangement can be expanded in axis Z (in number of layers) and in the XY plane as shown on the FIG. 49. The hashed regions in FIG. 49 inserted for readability indicate successive layers in a stack. Interposers of different size could be used and each layer dedicated to ICs could comprise one or more IC with gap between ICs optionally filled with a suitable filler material contributing to thermo-mechanical stability of the assembly. As said previously, configurable interposers (4901, 4902, 4903 and 4905) fill the voids in the stack of dies (4906, 4907). Once soldered together, they support the structure. Dies and interposers are intertwined so that the whole structure is extensible in the XY plane. This particular pattern enables densely connected complex systems with spans much larger than the limit imposed by reticle size, and even larger than a whole wafer.

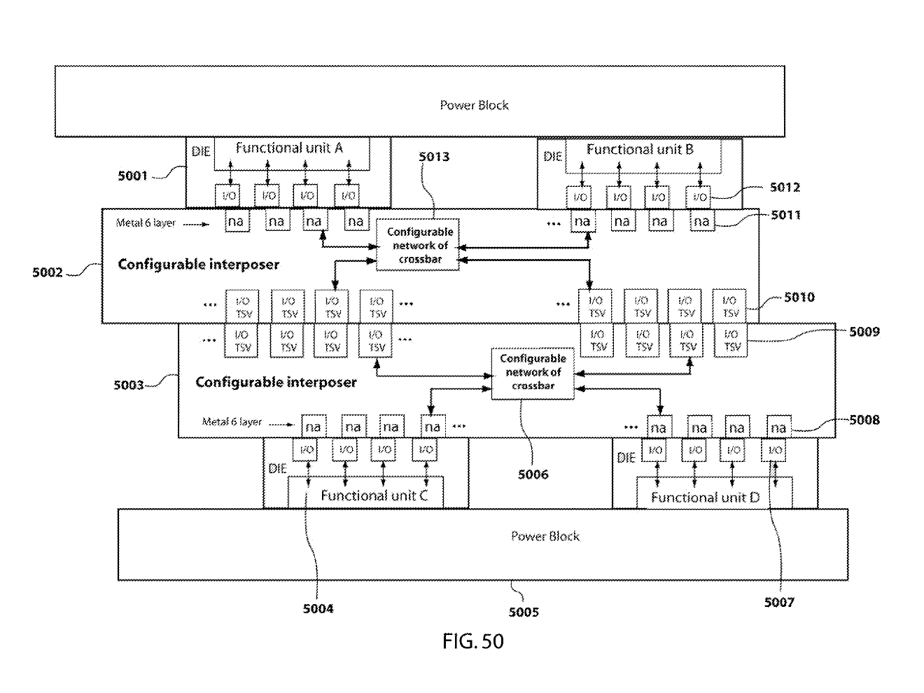

The internal architecture of the configurable interposer is shown in FIG. 50. The configurable interposer is in fact two integrated circuits (5002 and 5003) placed back-to-back. Electrical connections exist between the two integrated circuits because the TSVs (5010) of each side are aligned together. On the front side, there is an array of CMPIO (5011, 5008) for alignment insensitive placement of dies on the interposer. FIG. 50 shows four dies (for example 5001) each containing a particular function implemented by the inner functional unit (A, B, C or D).

The configurable network of crossbars (5006 and 5013) enables the configuration of any kind of netlist between dies' pins. Signals travel between layers 5002 and 5003 by passing through the TSV I/O (5010 and 5009). The configurable network of crossbars is connected not only on the CMPIO, but also on the TSV I/O. It means that the designer can activate a particular interconnection between the two configurable interposer layers.

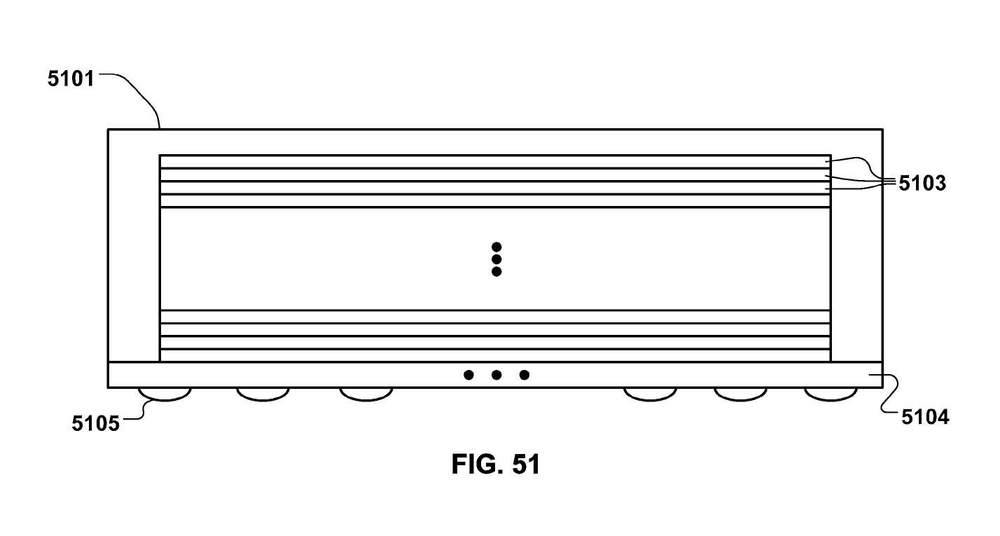

In another preferred version of the structure proposed in FIG. 45, the structure of FIG. 51 is enclosed in a conventional IC package 5101. This package encloses a 3D stack 5102 composed of multiple layers 5103. These layers can be an interposer that may or may not be programmable, an integrated circuit layer or a film of compliant materials such as existing Z-axis films. An advantage of using a compliant film is that chips of slightly different thickness could be used without causing excessive thermo-mechanical stress in the assembly, and without requiring separate shims to compensate for different component thicknesses. Methods for thinning integrated circuits have been developed by the semiconductor industry. The chip or silicon interposer layers could then be as thin as 10 microns and could approach 1 mm thickness. Considering the expected evolution of manufacturing technologies, a 3D stack of the type proposed here could have in excess of 100 layers with a total thickness slightly larger than 1 mm. Thicker stack could also be assembled if needed.

In a preferred arrangement, the stack would alternate the layer types as necessary. For example, a stack could alternate layers as follows: interposer-chip-interposer-chip-interposer . . . , or interposer-chip-Z_axis_film-interposer-chip-Z_axis_film . . . . As many useful variations are possible, the disclosed combinations are only exemplary and it should be understood that 3D stacks combining such layers differently are possible and can be useful. The disclosed structure assumes that interposers and chip layers provide a sufficient number of vias to propagate signals, ground and power supplies needed by the assembly. As the assembly could include ICs from various vendors in die or in packaged form, such ICs may not have been designed to be specifically embedded in the disclosed 3D assembly, such devices with desired functionality may not provide any vias supporting vertical connections.

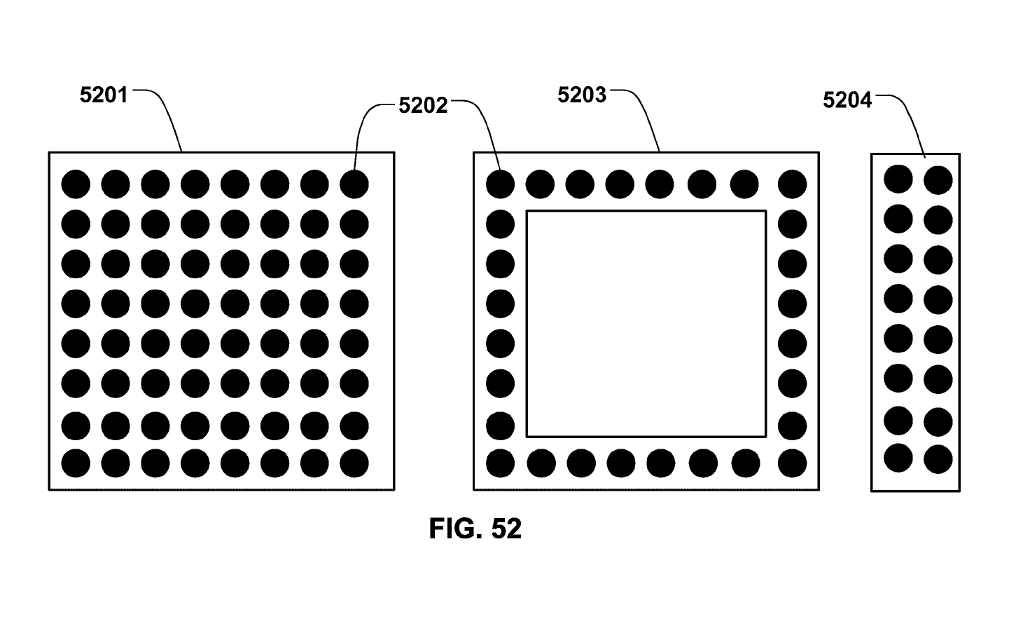

To ensure that suitable numbers of vertical connections are available, special dummy dies of the kind disclosed in FIG. 52 could be manufactured. In a preferred exemplary embodiment of the dummy dies 5201, a piece of silicon that can be thinned to the desired thickness to match that of other dies on a target die layer and that is separated in die form and is covered of a regular array of TSVs. It should be understood that the die can have any suitable rectangular shape and that other TSV 5202 patterns could be devised. TSVs as small as a few microns in size and approximately 10 microns in pitch are known. Other technologies are limited to TSVs of more than 100 microns in diameter with a pitch of more than 250 microns. Such a large pitch would yield dies with 16 TSVs per mm² or 1600 TSVs per cm². This should suffice for most applications and the feasible via density is expected to grow significantly over time. It should also be understood that other dummy die organizations as shown in 5203 and 5204 could be useful.

As disclosed dummy dies can be simple pieces of silicon with TSVs, generic dummy dies could be reused for multiple applications and thus manufactured in very high volumes for very low cost. They could also be thinned on demand to fit a particular use, and/or be available in a variety of standard thicknesses.

The disclosed 3D stack could be based on interposers supporting alignment insensitive contacts. This would be useful for assembling very dense 3D stacks in low volume, possibly using Z-axis films. Alternately, interposers or dies and dummy dies could receive balls as in the ball grid array (BGA) technology. Pick and place machines with an accuracy sufficiently better than the size of large 100 micron TSVs could be used to assemble 3D stacks composed of interposers, dies and dummy dies without Z-axis film and alignment insensitive contacts. These elements could be reflowed together in a compact low cost 3D assembly.

The preferred embodiment in FIG. 51 has a base layer 5104 that could be ceramic or any other suitable material found in IC packages. The 3D stack 5102 can be assembled to the base layer either using a compliant Z-axis film combined with a pressure applicator or using balls that allow reflowing the stack in place. At least one side of the integrated package 5101 would have external connections 5105. Less conventional packages with external connections on more than one side are possible. In the basic form shown in FIG. 51, the whole assembly could be treated as a conventional BGA chip.

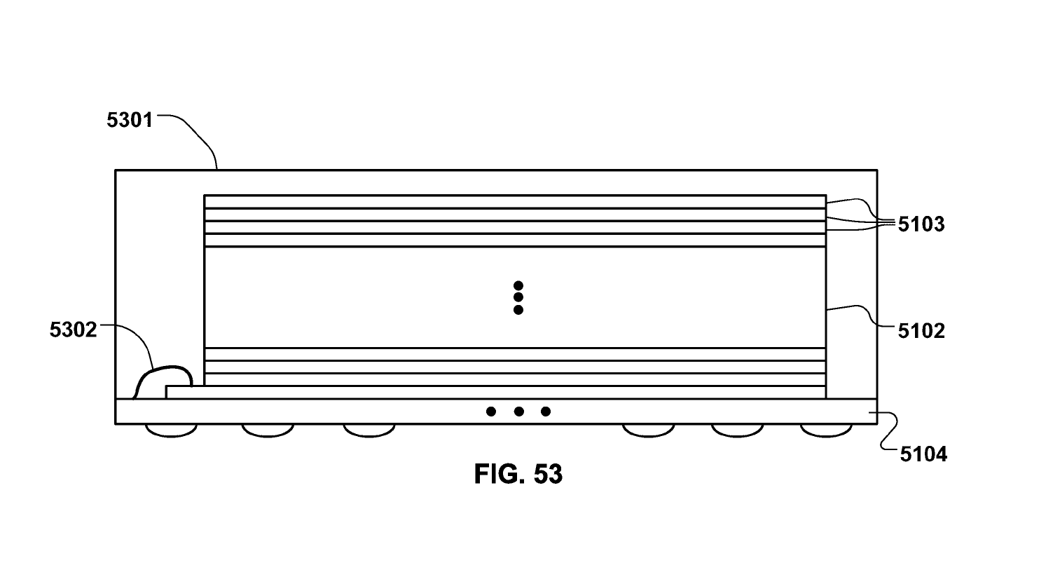

In a variation shown in FIG. 53, it is shown that the 3D stack may be composed of interposers larger that the other layer. In an heterogeneous 3D stack layers 5103 of different sizes could be combined. For example the first n layers could be large and the last m-n layers of a m layer stack a smaller area. FIG. 53 also shows that connections between the substrate and one of the layers in the stack could be made using wirebond 5302. The assembly could then combine wire-bound, reflowed balls and Z-axis films with a pressure applicator as necessary. It should be understood that many useful variations of the heterogeneous 3D stack exist and that FIG. 53 is only exemplary.

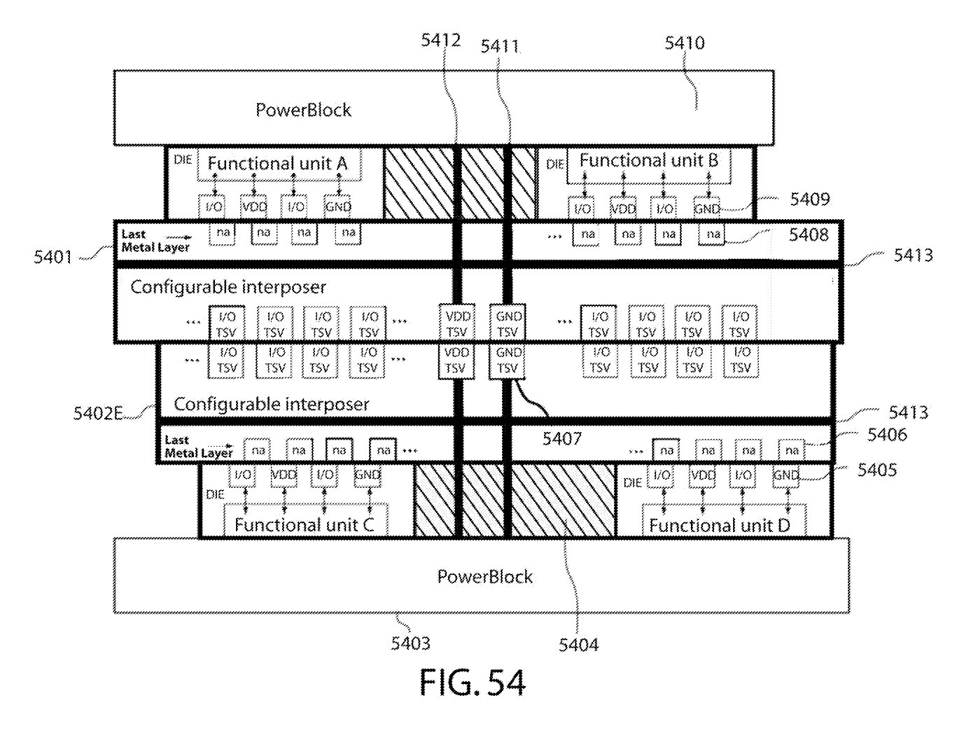

Stacking multiple dies as shown on the example of FIGS. 45, 49, 50, 51 and 53 could result in severe power integrity problems if the dies draw large and rapidly varying amounts of power. As shown in FIG. 54, a preferred embodiment of the present invention can minimize these problems by using a set of broad through silicon via (TSVs) 5411 and 5412 to supply the interposers (5401, 5402). All the decoupling capacitor insertions and most of the voltage regulation are done in the power block (5403, 5410). In this divulgation, the proposed solution to minimize power integrity problem is the following: the ground vias (5411) coming from the power block are directed to the configurable interposer ground plane (5413) and uIC ground plane (not shown on this figure) is connected to a set of CMPIO (5405, 5406) configured to the ground state. The same principle is applied to VDD vias (5412). The power block supplies the nominal voltage level to the configurable interposer (5412) and then to the uICs (5408 and 5409) by the configurable CMPIO located in the configurable interposer. The grounds vias from both configurable interposers are soldered back to back and therefore connected together (5407) to improve the power integrity. The same hold true for the VDD vias.

A key challenge of 3D integration relates to test and control in general. Test and control relates to determining the presence or absence of faults and defects. Once the presence of a fault is known, its location can be determined precisely, a process called diagnosis. Setting up alternate path around faults/defect to obtain a desired functionality in spite of them leads to fault tolerance. This process can be called configuration. Configuration is a process that is also useful beyond fault tolerance as it may allow enabling modes and desired functionality at will. It may allow programming a clock speed, changing the operating voltage produced by an internal regulator or gate ON/OFF some modules or put them in standby or sleep modes to save power. Supporting these functionalities at the system level is useful. This can be done using the general objective or testing known as controllability and observability of internal nodes or states stored in memory elements.

Several test methods exist. Some are based on conventional scan often implemented using the IEEE1149.1 standard [53]. Other standards such as IEEE1149.6 [54], IEEE1149.7 [55], and P1500 [56] exist. Other known methods such as random access scan are known but never evolved into widely accepted industry standards. A key idea of many, if not all, such test methods is the ability to control and observe many internal points and state bits through a limited of access points using some suitable protocol generally supported a controller or wrapper or some sort. A wrapper as the name suggests wraps some circuitry using an interface. The p1500 standard is particularly open to support a wide range of previously known test standards using a bus interface. This facilitates design, test and verification and provides a useful means of partitioning a system across large design teams. Using the concept of interface based design and design contract, modules designed by teams that have minimal and possibly no interaction can work together. That is particularly useful when some programmable interposer is designed to accept virtually all available chips from diverse sources where the group developing the interposer has limited knowledge of what is in a chip that may have been designed by a team that has been dissolved of be part of a future design project.

The methods disclosed earlier to implement test and fault tolerance of the interconnect structure of a LAIC programmable interconnect device apply directly to a system composed of a 3D stack comprising a plurality of programmable interposer and IC layers. The need to test and configure 3D stacks is equally important and such stack may be composed of a wide range of ICs found on the market. An interposer that can flexibly support such ICs possibly requiring heterogeneous test method is useful. As proposed earlier, a programmable interconnect fabrics embedding test controllers or a modern variant based of test wrapper such as the P1500 is directly applicable and could be used not only to test the programmable interconnect device but also various ICs embedded in a 3D stack.

The need to ensure power integrity through distributed regulators, to support analog signals, to measure various parameters that relate to thermo-mechanical integrity, to supply current, to supply voltages, and their respective integrity are all useful in a 3D stack.

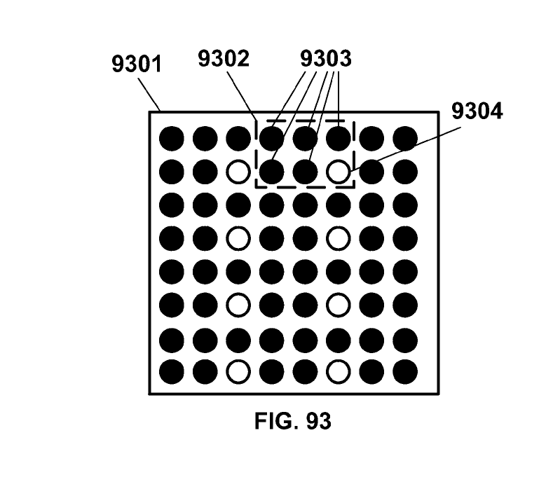

FIG. 93 shows a 3D stack component 9301 through which an array of TSVs is repeated as a TSV pattern 9302. The 3D stack component could equally be a programmable interconnect device or a dummy IC. It could be a LAIC, a full wafer scale device, a chip size programmable interposer or a simple dummy IC. A regular pattern of N by M TSVs could be repeated over a part or the complete surface of these respective devices. A useful arrangement is when the TSV pattern covers one or more than one edge of an interposer and the core of the interposer is reserved for nanopads. In this specific example, a 2 by 3 TSV pattern is composed of 5 real TSVs 9303 with the 6th one being a dummy TSV.

In a preferred embodiment, the 5 real TSVs propagate VSS, VDD1, VDD2, ANi, Tj. Here VSS is the ground, VDD1 and VDD2 are two different power supply tied to respective metallic power distribution grids, ANi would propagate some signal vertically in an analog way through a metallic stack and Tj would distribute to all layers one of the test signals of one of the IEEE1149 or P1500 standards. A digital signal can be propagated through an analog ohmic connection. Other TSV patterns and arrangements can be useful. For instance, more than two VDDs could be provided. A larger number of test or analog interconnect signal in each TVS pattern. By combining compatible interposers and ICs or dummy ICs, the proposed arrangement allows building low-impedance metallic connections through a 3D stack particularly useful to connect ground and supplies and to bring analog signals as well as test signals inside a 3D stack. The preferred purpose of Dummy vias is to systematically insert infrastructure circuits needed to support test and management of analog signals.

A dummy via in the regular fabric of an interconnect device is a zone where instead of having a regular TSV, some circuits needed to complete an electronic system would be available and could be connected to suitable parts of the system. Some support circuits that are useful in electronic systems include pull-up devices, pull-down devices, a voltage reference, a programmable voltage reference, a typical RC power-on reset circuit, analog to digital and digital to analog converter as well as some analog switch. This list of possible analog support circuits is not exhaustive or restrictive.

In the preferred embodiment, the programmable interconnect device has more than one metallic grid to distribute power and one of these grids can be used to connect analog support circuits to analog pins of user ICs as needed. Alternately, a metallic grid dedicated to the distribution of analog signals could be embedded in the programmable interconnect device. Also, more than on type of dummy via could be designed if the desired circuitry does not fit in the area of a single one. Various forms of regular interlaced distribution pattern of such plurality of dummy vias are useful. This is not restrictive and other uses of the dummy via zone could be useful.

Fourth Family of Preferred Embodiments: Distributed Hardware and Software Strategy for Rapid Prototyping of Reliable and Energy Efficient Three Dimensional Large Area Integrated Circuit System

The present invention aims not only to aid design of energy efficient electronic systems, but also to form a whole new family of integrated circuits. The methodology disclosed herein can be applied to 3D stacked ICs with one or several configurable interposers. A configurable interposer could be used as a tool to implement adaptable power management policies, or dynamical thermal management (DTM).

Just as FPGAs allow dramatically reducing development time and cost as compared to ASICs by allowing easy changes and architecture exploration, the use of one or more programmable interposer can reduce the development time of effective DPM or DTM policies.

Furthermore, as FPGA are considered for production for high complexity applications, the proposed programmable interposer solution is an attractive solution for production of highly complex systems that need to be energy efficient.

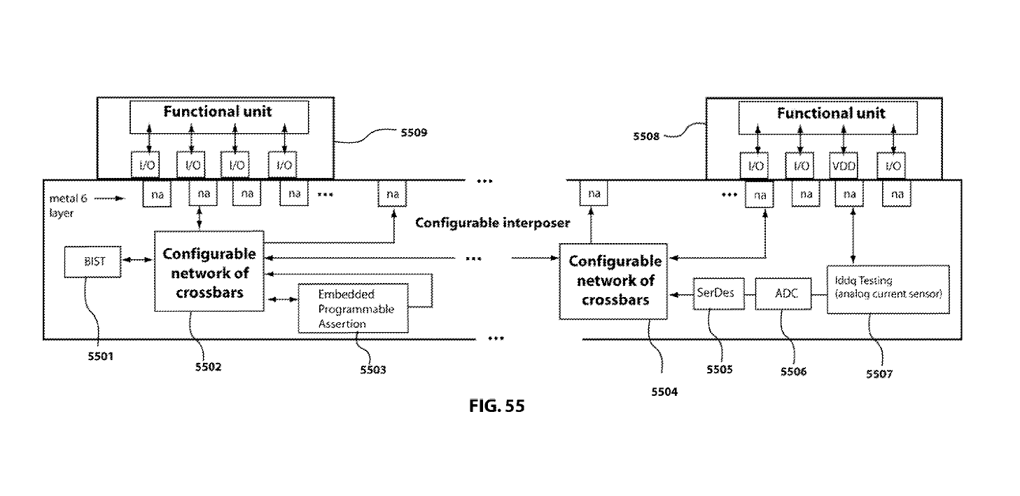

The configurable interposer includes design for testability features to improve the quality and the efficiency of the test and diagnosis of complex 3D stack chips or complex SoW. FIG. 55 shows the logical block of the design for testability devices. The configurable interposer contains a BIST module (5501) able to generate signals to the RRN (5502) and interprets signals from the RRN.

Embedded programmable assertion (5502) allows checking for complex patterns of signals coming from the uIC under test. Assertion checkers can detect logical faults based on the observation of the traffic on specifiable sets of interconnects in the 3D chips. The hardware implemented assertions are obtained by programming special logical cells embedded in the LAIC. Interconnecting sub-group of logical cells allows the creation of the desired behavior. Such hardware implemented embedded assertion checkers facilitate diagnosis the location in space and time of the root cause of observed undesired system behaviors. This embedded programmable assertion can be used for a large number of applications, not just for diagnosis and testability. By definition, assertion models check the expected logical and temporal behavior of the device under test (or diagnosis). Assertions are expressed by high level language, such as PSL, and a subset of this language is synthesizable in the hardware assertion integrated in the configurable interposer. Normally, simulation or emulation is done on the design to validate the behavior. The assertion can verify if an expected behavior occurs in the circuit, and it is able to detect potential or confirmed problems during uIC operation. The innovation integrates assertion in the configurable interposer to make advanced, at-speed diagnosis of complex 3D stack LAIC systems.

In order to create, validate and test energy efficient electronic systems, the designer needs to have extensive observability of the key system parameters that determine power and energy consumption. Data obtained from sensor can be analyzed to find patterns and correlations, with as much accuracy as possible, that determine power and energy consumption from which shut down events for each component can be planned. The system can control each PMC (Power Managed Component), according to a wide range of architectures or DPM methodology that can be tested effectively and for which the energy consumption can be directly measured.

The configurable interposer Iddq testing device is shown as 5507. A current sensor is associated with every CMPIO and a dedicated ADC 5506 converts the current sensor's analog output to N digital bits and then converts this to a serial signal with a Serdes (5505). The serial signal is connected to the NoC; therefore the signal can be redirected to any uIC chip integrated in the 3D structure or outside of the system to software analyzer. Iddq testing is used for diagnosis and efficient testing of ICs. In the present invention, the current sensor can also be used for evaluating the energy efficiency of the device under test.

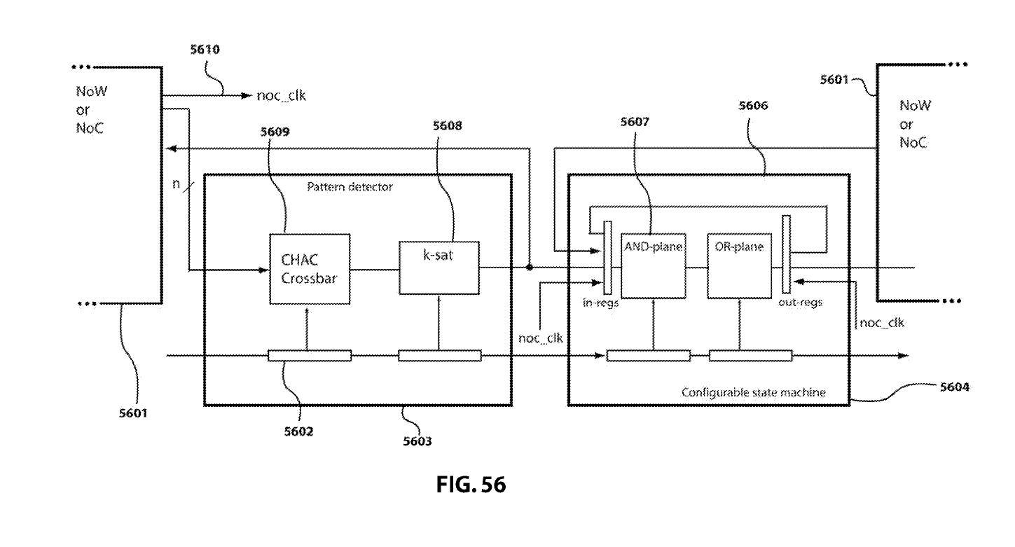

A preferred embodiment of the internal architecture of the configurable assertion integrated in the configurable interposer is shown in FIG. 56. Assertions are used to increase test efficiency, testability and diagnosability, and can also used for the dynamical power management and the dynamical thermal management. An assertion usually comprises a sequential logic (a finite state machine) and pattern detector (combinatorial logic). The hardware is dedicated specifically to allow a large subset of all possible assertions to be synthesized in the hardware with as few logical gates as possible. The configurable hardware assertion module contains a pattern detector (5603) directly in contact with the network on chip (5601). The number of wire connections between the pattern detector and the NoC is determined by the designer and is set to a generic number “n1”. The Boolean result from the pattern detector is routed back to the network on chip or the network on wafer depending if the technology is used in a chip or in a wafer scale integrated circuit.

The pattern detector contains a small local crossbar (5609) named CHAC crossbar that interconnects any input port to any sets of hardware emulation (5608) of the Boolean behavior of a k-sat. The k-sat is a very well known formulation of the prepositional satisfiability problem. The local crossbar 5609 and the k-sat module 5608 are software configurable by the means of the serial scan chain 5602.

The Boolean result from the configurable pattern detector can be received by a configurable state machine (5606). The configurable state machine is configured with a serial scan chain (5602) and the specific configuration bitstream is generated by the embedded software or external software controlling the system. To create a large span of emulated behavior, the state of the configurable state machine and a set of signals are connected back to the RRN to give an observability access to every external device in connection with the system.

The RRN provides a system clock. It means that the system clock can potentially come from anywhere or anything that is in contact with the network. The same principle holds for logical signals dedicated to control the state of the AND-OR plane (5607) or the pattern detector. This is the key to aggregate multiple hardware assertions checker together to increase arbitrarily the complexity of the assertion checker.

Referring back to FIG. 46 shows that the Configurable Hardware Assertion Checker (CHAC) which is a type of programmable logic block 4606, is in contact with the RRN for all the cells included in the system via Crossbar 4603. The CHAC 4606 are also all in contact with their cell's logic core 4602 via the crossbar 4603.

The configurable hardware assertion checker is fully fault tolerant for multiple reasons. First, the configuration system that provide the configuration bitstream to the logical AND-OR plane and pattern detector is fully fault tolerant. Secondly, the system contains as many CHAC 4602 as the number of cells in the circuit. Because the number of cells is high and many of the cells won't be used, if a cell contains a failed CHAC this specific cell will not be used. In order to be able to avoid the use of a faulty CHAC, one must be able to diagnose the fault. As shown in FIG. 56, the CHAC includes scannable registers. Furthermore, observability and controllability are possible on every signal that comes from or goes to the RRN. Therefore, test and diagnosis is possible to achieve on the CHAC.

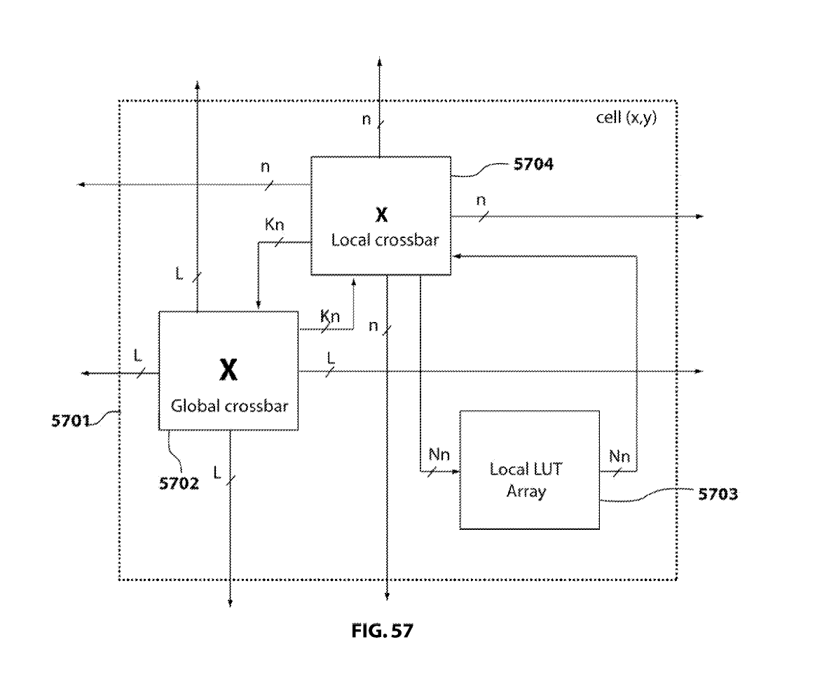

All the cells of the configurable interposer contain the same architecture. FIG. 46 shows the logic block of a configurable interposer's cell. As depicted in FIG. 46 and in more detail in FIG. 57, every cell has an array of programmable logic cell block 5703. This array is in connection with the other cells by the means of the central and global crossbar (4603 or 5702), but the local array of programmable logic blocks is directly in contact with the neighbor cells as shown on the FIG. 57. The local crossbars 5704 of every cell are in contact exclusively with the adjacent cells. The local array of programmable LUTs has N bus of n signals (N bus of width n). Each bus is in connection with one LUT and each LUT has “n” entry signals and “n” output signals. This configurable interconnection network enables the aggregation of a large number of local arrays of LUTs to synthesize complex behavior such as LFSR, MISR, BILBO, counter, or any other kind of BIST system.

Each BIST is composed of a vector generator (LFSR) and a signature analyzer (MISR). The signal generated by the LFSR can be redirected to desired chip pins in a LAIC or in a 3D structure. The LAIC or the configurable interposer MISR can observe any signal in the system with the use of the configurable network. The complexity of the LFSR or the MISR can be enhanced arbitrarily by combining together a large number of programmable cells. BIST for diagnosis such as a walking one sequence can be generated and results interpreted to perform a precise diagnosis by the programmable logical cell embedded in the LAIC or in the configurable interposer.

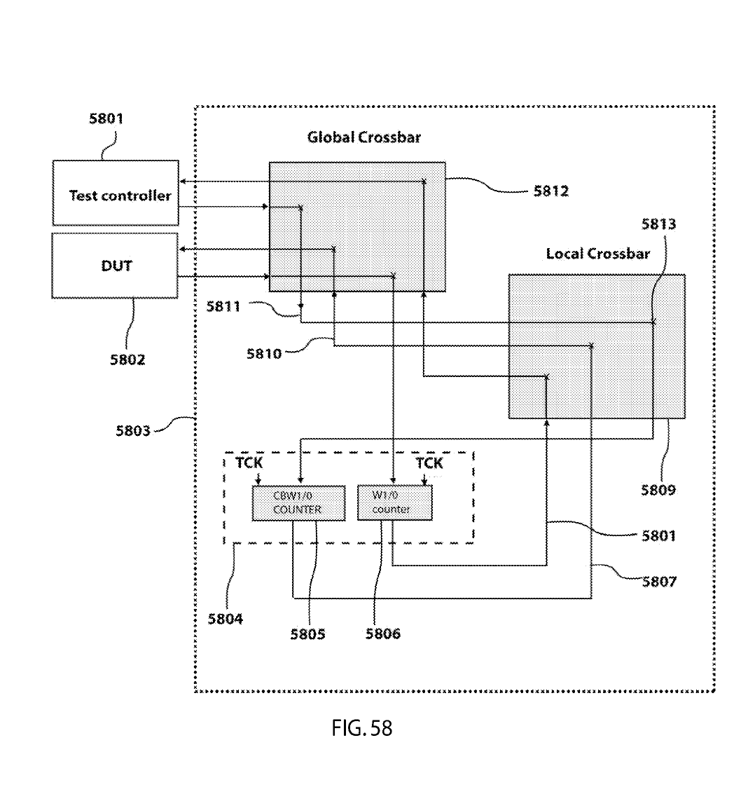

FIG. 58 depicts a particular configuration applied to the configurable array of crossbars included in the configurable interposer. The configurable interposer has the ability to observe signals coming from any pins in contact with the configurable interposer's CMPIO. Likewise all the control signals of any DUT 5802 is accessible from the configurable interposer. The interposer is able to create a communication links between DUT 5802 and test controller 5801. The BIST is represented by the inner dotted rectangle (5804). In this example, the BIST is triggered by the test controller to accelerate the test phase by creating a local walking-one vector generator (5805) using the local array of LUTs as synthesizable logic blocks. The walking one sequence is generated on a trace (5807) that travels through the cell to reach the local crossbar (5809). The local crossbar output (5810) is in connection with the global crossbar (5812); therefore the signal can reach other distant cells. The global crossbar is the crossbar that is associated with the main network of the system known as the WaferNet in the WaferIC technology. The main network has rapid (direct) connection with not only the adjacent cells, but with very distant cells as shown previously on FIG. 6. The regular array of global crossbars can be configured to reach the JTAG test port of the DUT to apply the signals on the DUT. In response to the received walking-one, the results from the tests are being interpreted not by the test controller, but by the BIST which include a 0/1 counter (5806) to detect faults. The BIST receive the results signals from the routed paths between the DUT and the BIST. The global result from a series of test vectors applied to the DUT is then sent out by the BIST to the test controller.

Some conditions must apply in order to be able to save energy with the DPM design methodology. The first condition is to have components that consume variables power during system operation. The second condition is to predict the future workload of the most power hungry components of the system. The third condition is to be able to achieve such prediction with negligible power consumption. These conditions can be satisfied by observing signals that trigger shut-down or power-up event. Furthermore, it is required to use a Power Manager (PM) implementing the control of shut down and power-up of components. Such components are called power managed components (PMCs). The set of all control command for power managed components is called a policy. The PM can be distributed on the whole configurable interposer or the WaferIC. Instead of having a central PM as the prior art, the logical behaviors of the PM are inserted in the configurable logic included in the configurable interposer or the WaferIC. This is achievable because the external software is in connection with a configurable interposer or a LAIC that have an access to all VDD power supply pins of the system. Knowing the correct location of every VDD pins of the system and having the possibility to force a particular voltage level (between 1V to 3.3V) on the CMPIO is the key to find the minimal applicable VDD voltage level on every ICs of the system.

A preferred embodiment of the configurable interposer integrates hardware assertion embedded in the configurable interposer to enhance thermal management. Furthermore, the configurable interposer uses the extensive observability on every signal of the system to prototype, validate and fully implement software based thermal management policy.

Preferably multiple features are included in the same configurable interposer, including: (1) integration of hardware assertion embedded in the configurable interposer to enhance thermal management; (2) the configurable interposer using the extensive observability on every signal of the system to prototype, validate and fully implement software based thermal management policy.

The interposer comprises a current, voltage and power monitoring of every VDD pin of every uIC deposited on the active surface of the configurable interposer. The current and the voltage are directly measured and the measurements are redirected to an embedded or an external software module. The role of the software module is to analyze the crude voltage and current data and compute power consumed by every uIC, from which energy efficiency statistics can be gathered in a database and shown to the user.

A preferred method to automate the search for the optimal DPM policy is to mix the massive data gathering capacity on power consumption of the electronic system with the possibility to control every PMC of the system. The data gathered on the power consumption fluctuation is stored in the database.

Then the data is analyzed by the software to create a predictive model of future shut down events and future power-on events. The data gathered is not only power data coming from the current consumption, but signal data coming from every observation pin of the system. The massive quantity of data is analyzed by software running on a high-performance external computer during the design phase. Once the best possible predictive model is found with the computer, the model is expressed in term of assertions and then synthesized into the configurable assertion checker. The predictive model can be based on statistical analysis of the power data and the digital signal data coming from I/O pins. The innovative aspect consists in implementing the predictive model by the means of the massively distributed configurable assertions embedded in the configurable interposer or in the WaferIC.

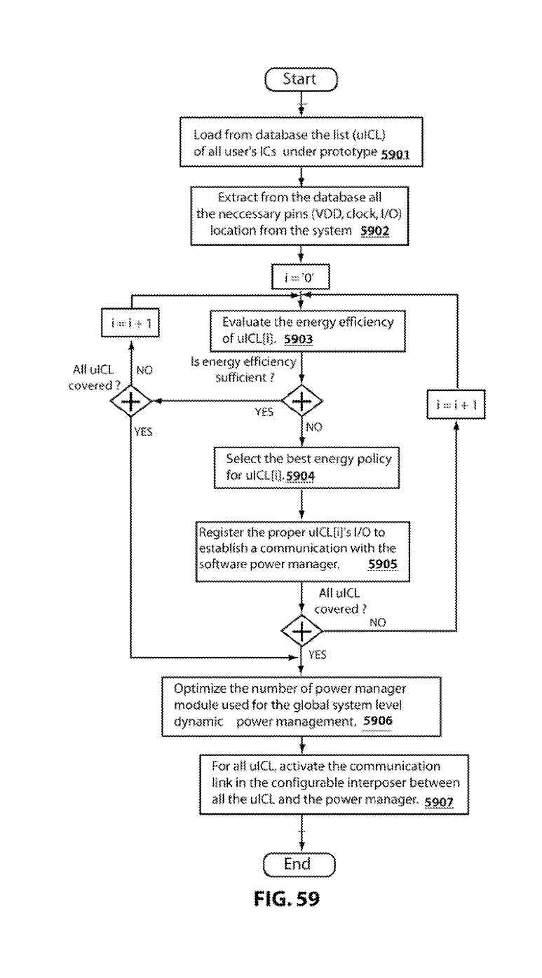

FIG. 59 is a flowchart depicting the general strategy and algorithm applied to the hardware and the software to automatically generate a DPM policy. The first step (step 5901) of the algorithm consists of create a database containing the list of all the ICs used in the current design, and then extract all the necessary information for the algorithm such as I/O, VDD and GND pin locations of the design in a second step (step 5902). The location of the pins on the active surface of the configurable interposer or the WaferIC is determined by the contact detection algorithm discussed previously in the present application. The subset of pins that drive the control signals of the power state machine of every PMC is a very important subset of I/O pin to locate on the active surface. The location of those pins can also be specified by the designer in addition to or instead of being found automatically by software in step 5902.

The next step (step 5903) consists of evaluating the energy efficiency of every chip or die placed on the active surface of the system. This stage is crucial to pinpoint the most important places in time (when) and location (where, on which chips or die) to search for power management policies. Because the search is very time consuming, a heuristic is added to the Predictive Model Search (PMS) algorithm. The search criteria are based on the energy efficiency of every die or uIC deposed on the system. The most logical choice is to search for a predictive model only on the least-energy-efficient component of the system.

The energy efficiency of the component is estimated by evaluating the power consumption multiplied by a metric called the “ExIn” index (for Exchange Intensity index). The ExIn index is computed from the number of data exchanged inward or outward for a component over a small time interval, and the index thus changes over time. The time precision depends on the sampling rate of the signal data captured in the system. The ExIn index can be mixed with the power consumption to get a relatively accurate estimation of the energy efficiency of the component over time. A preferred method to mix power and ExIn data is to create another metric called the EE index, defined by the ExIn index divided by the current power consumption (EE(t)=ExIn(t)/P(t)). If the later EE index is high, this means that the energy efficiency of the component is high. The EE index varies over time and if the EE index is relatively low compared to other components or compared to previous time interval, then the space-time interval can be chosen and place in a list of data to search for power management policies. Therefore, this stage finds when and where to apply DPM policy to improve the inefficient part of the system.

Selecting the best DPM policy is the next step (step 5904). This selection can be made by the user which select in a library of DPM policy. Each DPM policy is then tested with the reconfigurable logic cell and the reconfigurable network to force to signals on the PMC and to observe the system signal to trigger the PMC to shut down or to wake up (step 5905).

The power manager must able to implement the policies without significant degradation of the system power consumption. In other words, the power consumption required for the power manager to implement the DPM policy must be small enough to be negligible. In order to do that, the number of power managers to implement and synthesize in the configurable interposer or in the WaferIC must be optimized (step 5906).

The last step (step 5907) consists of activating the configurable links between the configurable interposer or the WaferIC and the power manageable components. All the links can be configured by software with a fault tolerant serial communication link such as the previously discussed (CICU or CICB).

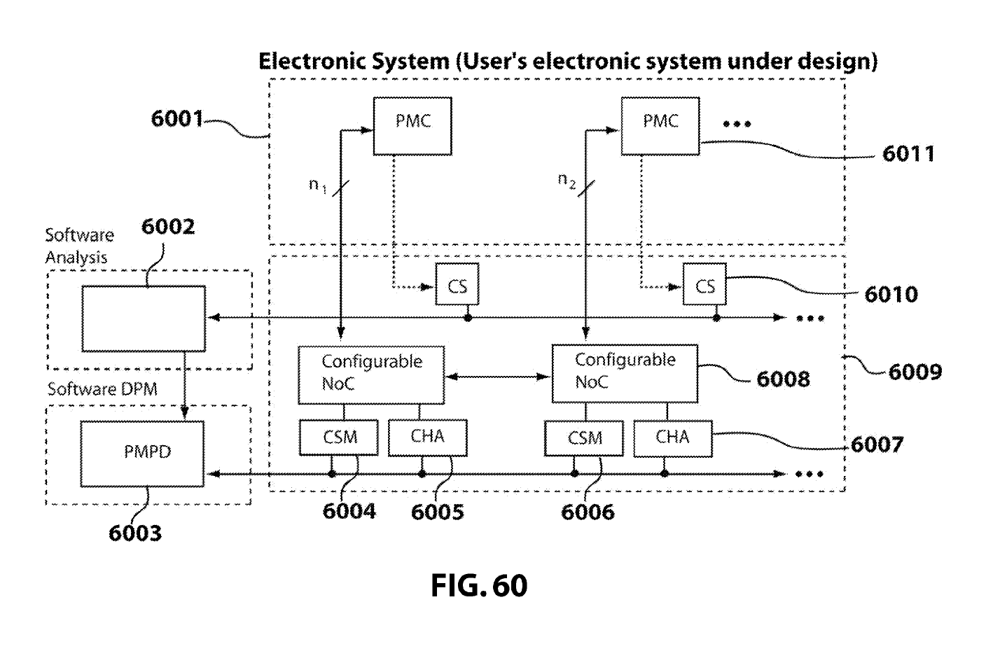

The main benefit of using an array of CMPIO and a configurable network on chip is to gain an observability of every I/O of the system. This is the foundation for generating assertion-based management policies. As shown in FIG. 60, and as previously discussed, the configurable interposer or the WaferIC contains an array of configurable logic specialized for synthesized assertions (6005). Each configurable hardware assertion (CHA) is linked to a configurable state machine (CSM) (6004, 6006). The CSM is the control interface between the PMCs (6011) and the CHA.

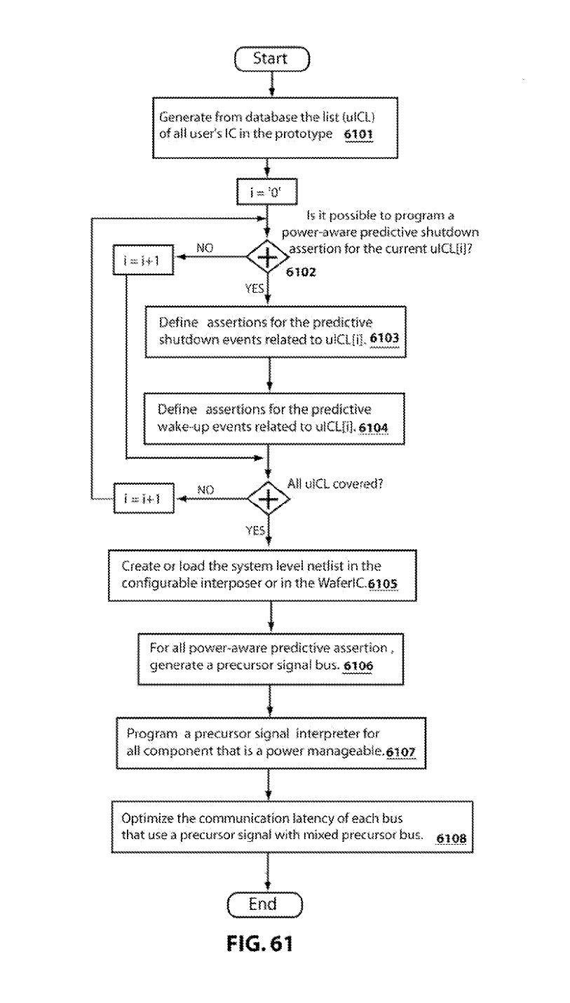

FIG. 61 depicts an example of a “Power Aware Design flow” that it is possible to implement with the configurable interposer. First, the methodology consists of getting the knowledge of all I/O pins of all components of the systems (step 6101). The Design flow consists of applying DPM policies only on power manageable components (such as 6011 of FIG. 60) (step 6102), and to define assertions specialized to detect future shut-down event of all the PMC (step 6103).

In order to find those assertions, embedded or external software (shown as 6002 in FIG. 60) is able to analyze all the observable data and generate the proper shut-down assertions. The same principle is applied to generate the configurable assertion detecting the wake-up events (6104). For each shut down assertion there is a wake-up assertion.

The shut-down and wake-up events must be automatically generated from the observed data. While many methods to accomplish this are possible, the preferred method is to use regression analysis. The workload is defined as the total computing done in a small interval of time. The workload of the whole system can fluctuate around an average value with more or less time variation. The workload can be defined for a single component. In that case, the workload can drop down to zero during a non-negligible time interval. During such events a shut down applied to this component can be forced without compromising the system functionality. To detect this kind of event, a correlation must exist between the exchanged signals between components and a particular time interval with zero workload. In other words, a series of precursor signal must be detected before sending a shut down takes place. Therefore, the algorithm consists of finding such correlations. The same principle holds in finding correlations between a series of precursor signal and a wake-up event (step 6104) as stated in FIG. 61. Once the assertions are found, they can be automatically synthesized and instantiated in the configurable interposer or in the WaferIC (step 6105).

This methodology can be fully automated and installed in the OS of the whole system (configurable interposer and 3D stack chip). Therefore, this design flow is the basis to create an adaptive DPM policy. The assertions can be changed “on the fly” to reflect a new workloads patterns observed by the software installed in the OS of the system.

The configurable interposer or the WaferIC can force a specific voltage level on every uIC pin dedicated to power. This is possible through the regular array of CMPIO.

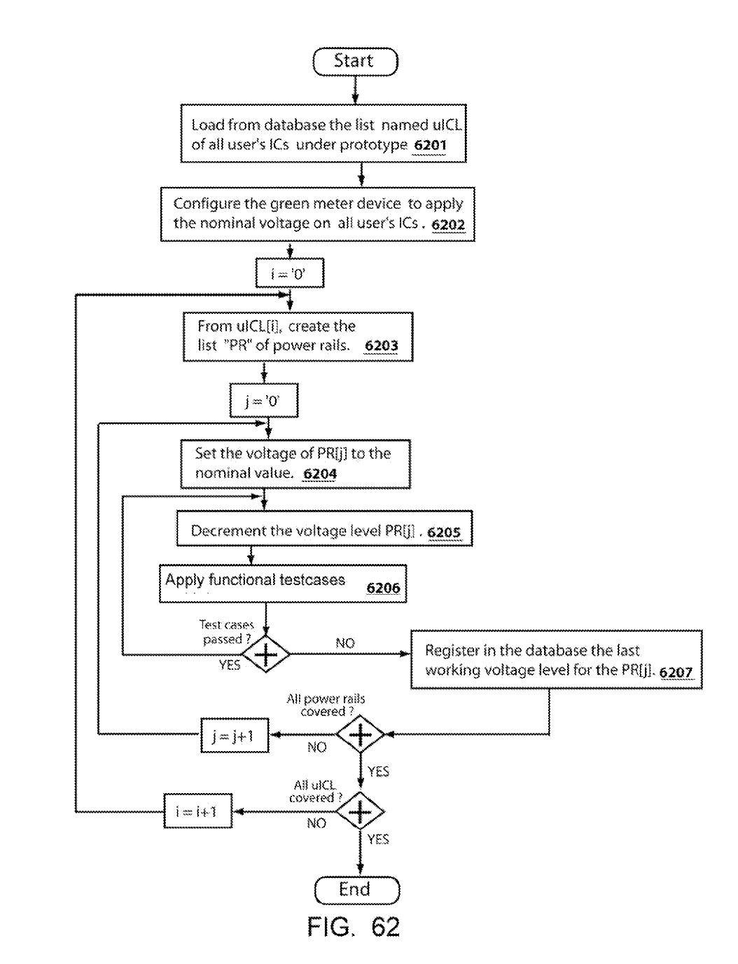

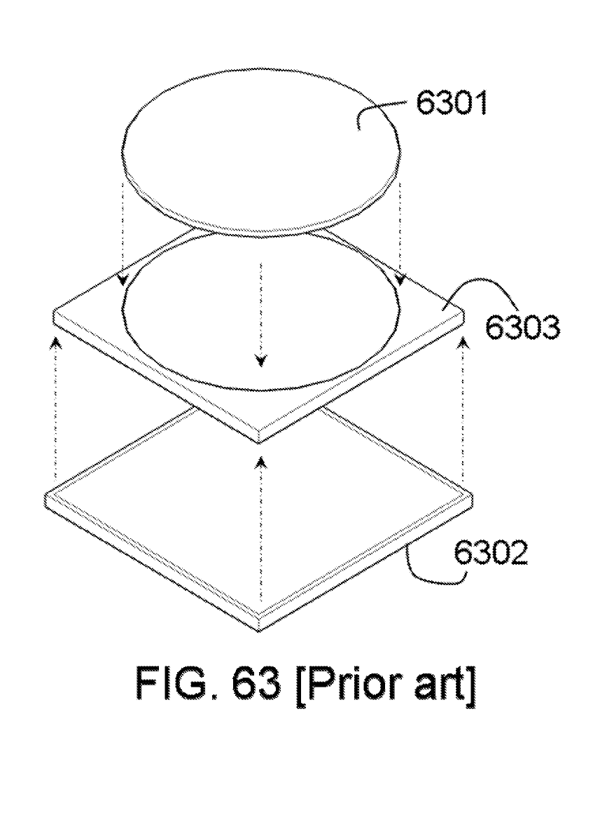

The ability to force voltage to supply current to any VDD pin is the key to automatically adjusting the appropriate voltage according to the uIC's specifications. It is possible to gain a non-negligible amount of energy saving in the whole system by minimizing the applied voltage level on every VDD of the system. FIG. 62 is a flowchart that shows how it is possible to improve the power consumption of the whole system using the configurable interposer or the WaferIC to automate the search for the minimal VDD applicable on every power rail.

The algorithm disclosed in FIG. 62 has two requirements: (1) every uIC pin location is known and the system is known to work with the voltage level recommended by all users' IC manufacturer; (2) a set of previously specified testcases running successfully at a given VDD level means that that voltage level is sufficient.

The first step (step 6201) is to create from a database a list of all the power rails of every IC under prototyping. The second step (step 6202) is to configure the interposer or WaferIC find the minimum VDD for each component. The following convention is used: the list of all ICs in the system is uICL and the list of all power rails of the actual uICL[i] is PR, which is created in step 6203. The next step (step 6204) is to initialize the VDD voltage level to the nominal value as stated by the specification documents. The voltage is then slightly decremented (step 6205). Then, the whole system is tested with automated and auto-validating testcases (step 6206). The VDD of the current power rails under minimization is slightly decremented. If the test case does not pass, the minimal voltage level applied on the power rail is found and corresponds to the i-1 search iteration previously applied on the whole system (6207). The same process is repeated on each power rail of the system. In consequence, this algorithm is able to automate the search of the minimal voltage on every power rail of the system and as a matter of fact, accelerates the whole design flow.

To limit peak temperature in a 3D chip stack dynamic thermal management can be integrated in the system. Such techniques can be implemented in 2D chip with dynamic frequency and voltage scaling. The same sets of techniques can be implemented in 3D. Because there is a strong correlation between chips and stacked chips, a configurable interposer can assume the role of dynamical thermal manager.

An array of temperature sensors are embedded in the configurable interposer. Data obtained from these sensors can then be gathered for software based quantitative evaluations of the effectiveness of the implemented DTM policy. The configurable and interconnected logic cells can be the base from which the thermal management policy is executed and controlled. On the other hand as depicted in FIGS. 49, 50, 54 and 55 VDD voltage is applied on every IC by the means of the configurable interposer in a 3D chip stack. Furthermore, frequency is controlled by a clock signal dispatched to the whole system by the configurable interposer. Therefore, it is possible to implement the dynamical thermal management in the configurable interposer instead of using the computational area of each IC to do it.

A current sensor, a voltage sensor and/or a power sensor is associated with every surface contact support circuitry 9501 and a dedicated analog-to-digital circuit converts the sensor's analog output to digital signal as stated in the previously preferred embodiments. The digital signal can be redirected to any internal memory, internal controller or external controller for analysis. The sensor(s) can also be used for evaluating the energy efficiency of the integrated circuit component or the signal integrity at the surface contact.

Fifth Family of Preferred Embodiments: Mosaic of Miniature Printed Circuit Board for Mechanical Support and Power of Large Area Integrated Circuits

An aspect of the present invention is stacking of different mechanical and electrical layers to support a LAMS device. This stacking architecture acts firstly as a flat and stable mechanical support for very fragile LAMS devices. Secondly it supplies powers and signals to LAMS devices using only one side of the LAMS device. A layered arrangement of different layers allows supporting sub-micrometer devices with existing improved millimeter systems and technologies. The invention is a hierarchical layered system from mechanical and electrical points of view. The invention structure is described as follows and illustrated in FIG. 60: a support frame 6002, the interface structure 6003 and the LAMS device 6001 itself.

The main structure of the invention supports any mechanical and electrical devices needed for the LAMS application. The support frame 6002 is the first level of the hierarchical structure. It acts as the LAMS device mechanical support and supplies electrical power and signals to LAMS devices. The power circuitry of the support frame is similar to a power supply unit in an electronic system. It is designed to provide stable voltage(s) and high current to LAMS devices. Typical LAMS power ranges are from 300 W to 1000 W, depending on the current capability needed by the LAMS application. The support frame can be a multi-layer printed circuit board or any multi-layer thin or thick film technologies with or without common electronic components (ICs, passive devices, connectors, etc.).

The multilevel structure is made of different materials with their own properties, specifically different coefficients of thermal expansion (CTE). They could induce thermal stresses, distortion, and warping that could cause problems if not managed properly. The power used in any layer will generate heat and the LAMS device could fail prematurely due to mechanical thermal expansion. LAMS devices are effectively very sensitive to mechanical stresses (such as bending or pressure) or thermo-mechanical stresses.

Some pre-processing and post-processing technologies that can be used to interconnect LAMS devices (6001) to the support substrate (6002), such as through-wafer-via or through-silicon-via, could significantly increase the sensitivity to mechanical stresses.

The support substrate (6003) is designed in order to get a surface as flat as possible under the LAMS device (6001) to minimize mechanical stresses. The support substrate (6003) is also made as thin as possible to maximize heat transfer between LAMS devices (6001) and the large and robust main mechanical support (6002).

The TCE of each layer in the multi-layer structure is made as close as the TCE of the LAMS devices.

But even if perfectly TCE-matched materials are used for each layer, it is impossible to avoid temperature difference between layers. It is therefore impossible to avoid thermo-mechanical stresses if the two layers are rigidly attached together.

In the present invention, mechanical stress are reduced by ensuring that one layer attached to another be made as an array of mechanically independent devices. The size of these devices in this array must be made small enough to reduce the stress to a tolerable level in X and Y directions.

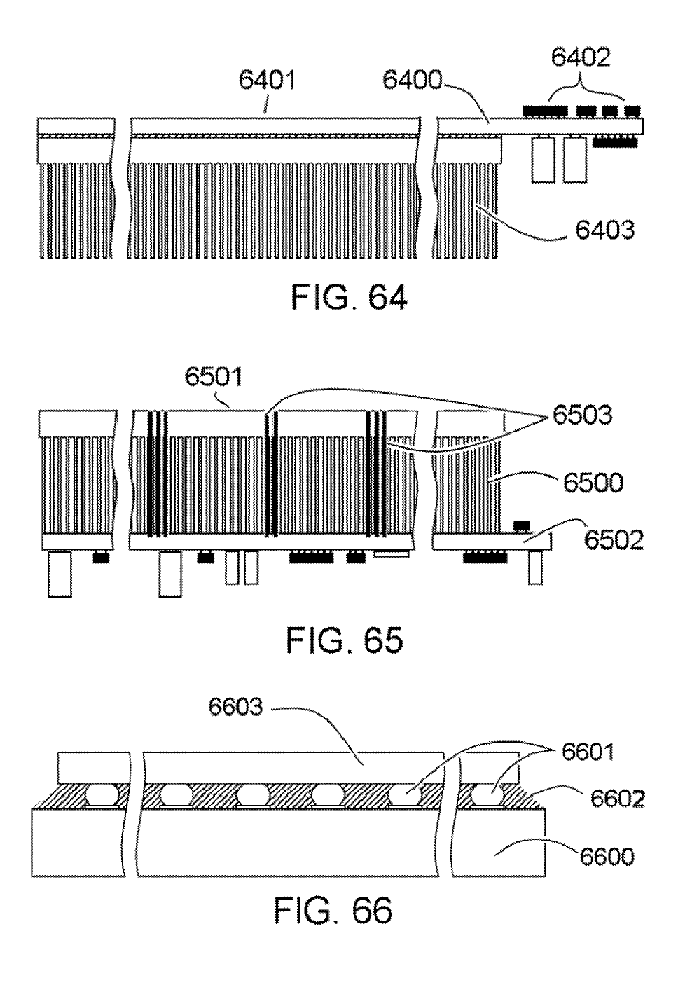

Preferred methods for the main support structure are illustrated in FIG. 64 and FIG. 65. In both methods, a large metallic heat sink is used as the main mechanical support. It provides good thermal characteristics and a better mechanical rigidity to the whole system.

In the first method, as shown in FIG. 64, a main printed circuit board can be added to the LAMS system (6401) and can lay on the heat sink (6403), with some thermal grease spread between them for thermal considerations. Interfaces (6401) under the LAMS device have to be as flat as possible to minimize mechanical stresses. Most or all electrical and mechanical components should be placed in a dedicated area (6402) beside the LAMS device area to minimize thermo-mechanical stresses and electrical noises in the LAMS device.

The second method, FIG. 65, comprises placing the main printed circuit board (6502) under the heat sink (6500). Heat sink face 6501 is made as flat as possible to support LAMS devices laid on it. Connectors and interconnections (6503) can reach the LAMS devices through well placed holes drilled in the heat sink. Mechanical and electronic components are place on the free backside of the main printed circuit board (6502).

The interfaces between the support substrate (FIG. 64-65) and the LAMS device is a key point of the invention. This interface substrate is designed to meet some physical constraints required by semiconductor and circuit board technologies.

The interface substrate must be able to compensate TCE mismatch between the main mechanical support and the LAMS devices but also has to ensure a maximum mechanical stability to the whole system.

The connections between the interface substrate and the LAMS device can be made with solder balls to hold it and make electrical connections to it as shown in FIG. 66. This approach is similar to flip-chip packaging technologies. Empty spaces between solder balls (6601) are filled with a thermal epoxy (6602) (under-fill). As reference, typical minimum drawing width/spacing of the latest printed circuit board technologies is one hundred micrometers whereas the minimum size of the latest semiconductor technologies is around few tens of nanometers. Specific patterns are designed to correctly interconnect the support substrate (6600) with the LAMS device (6603) and compensate the size and spacing differences between the both layers.

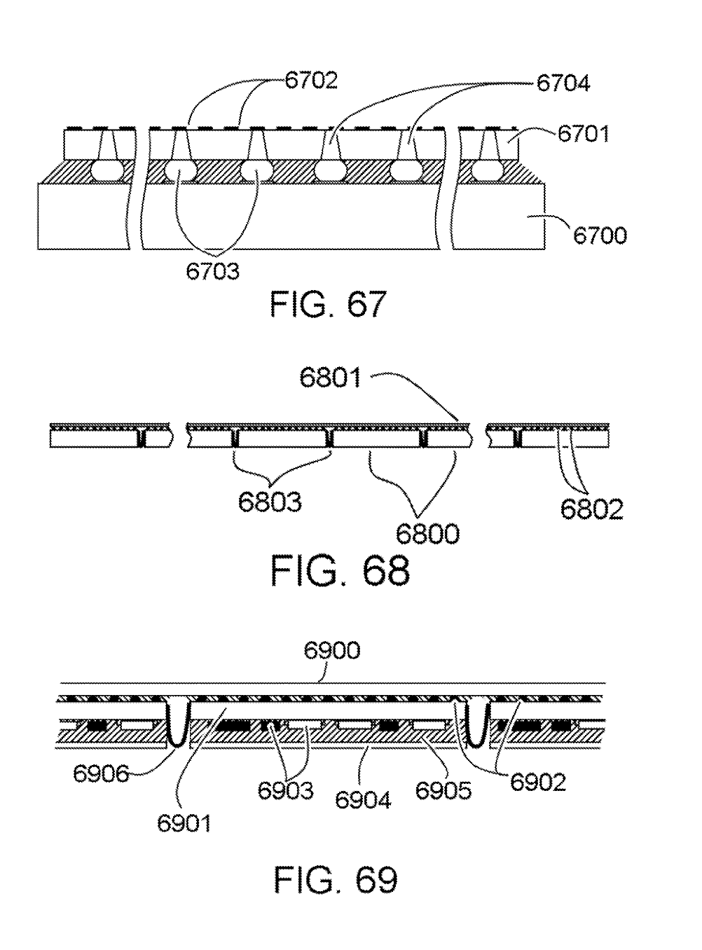

Another method for the LAMS interface is preferred when the active side of the LAMS device must be freed up for the application, such as described in U.S. Ser. No. 11/611,263. FIG. 67 illustrates this case. The active side (6702) of the LAMS device (6701) has to be clean of any mechanical or electronic structure. In such a particular case, the LAMS device (6701) has to be supported and supplied power from its backside. The connections to active element at the LAMS (6701) active surface (6702) are done through well placed and sized Through LAMS Vias (TLV) (6704). Solder balls (6703) are used to connect and permanently solder the LAMS device on its electrical and mechanical support substrate (6700). The solder balls can be placed elsewhere than under the TLVs, and electrical signals are then redistributed by using post-processed LAMS backside redistribution metal layers.

One of the most important reliability issues of LAMS scale packaging is the thermo-mechanical stress that is caused by the mismatch of the coefficients of thermal expansion (TCE) between the LAMS device and the main support substrate. This thermo-mechanical stress can be reduced either by using an interface substrate material whose TCE matches that of the LAMS device (AlN, Si or GaAs) or able to compensate the TCE difference. Thermo-mechanical stress in LAMS application can lead to the break of the LAMS device.

The interface substrate can be made with a material that has a TCE equal or nearly equal to that of the LAMS device. For instance, silicon has a TCE of 2.6×10⁻⁶ K⁻¹, silicon or alumina silicate glasses (TCE of 2.9×10⁻⁶ K⁻¹) or Aluminum Nitride (TCE 4.5×10⁻⁶ K⁻¹) can be used as substrate for the interfacing substrate but such substrates are extremely expensive and not suitable for high volume products. Notice that even perfectly TCE-matched layers will develop mechanical stress if their respective temperatures are different.

An alternative method to minimize both the cost and the thermal stress on the LAMS device during its operation is to split its support substrate into a mosaic of cheaper micro-substrates as shown on FIG. 68. Each micro-substrate (6800) of the mosaic can be connected or not to its neighbor with flexible cables or flexible PCB (6803). Both sides of the ‘micro-substrate’ have to be as regular as possible in order to get a large mosaic substrate as flat as possible for mechanical considerations.

A more detailed illustration is given on FIG. 69. Specific components (6903) can be embedded in each micro-substrate. All embedded components (6903) can be encapsulated with filling material (6905) and a backside plane (6904) to ensure good thermal conductivity. The micro-substrates are fixed and connected with solder balls (6902) to the LAMS device. The size of the micro-substrate size is calculated depending on the thermal expansion of each parts and an acceptable induced thermo-mechanical stress of LAMS devices.

The set interface substrate fixed and connected to the LAMS device can be defined as the packaged LAMS. The package LAMS has to be placed on the main system support 6302.

The packaged LAMS can be fixed and connected to the main support but can also be only deposited on the main support substrate in order to slide on this surface to compensate X and Y TCE mismatches as described in [000486].

If the packaged LAMS is fixed on the main substrate support, connections and fixations are ensured by classic PCB or packaging soldering techniques solder balls and metal lines.

If the packaged LAMS is only deposited and must slide on the main substrate support as 6801, the electrical connections are ensured by face to face metal rails on packaged LAMS backside and main substrate support topside.

FIG. 70 illustrates a packaged LAMS deposited or fixed on a main substrate support. A robust and efficient heat-sink (7003) supports the main PCB (7001) of the application with its dedicated components (7004) away from the flat surfaces that support the LAMS. The packaged LAMS (micro-substrate array (7002) with LAMS device (7000) is placed or fixed on the PCB.

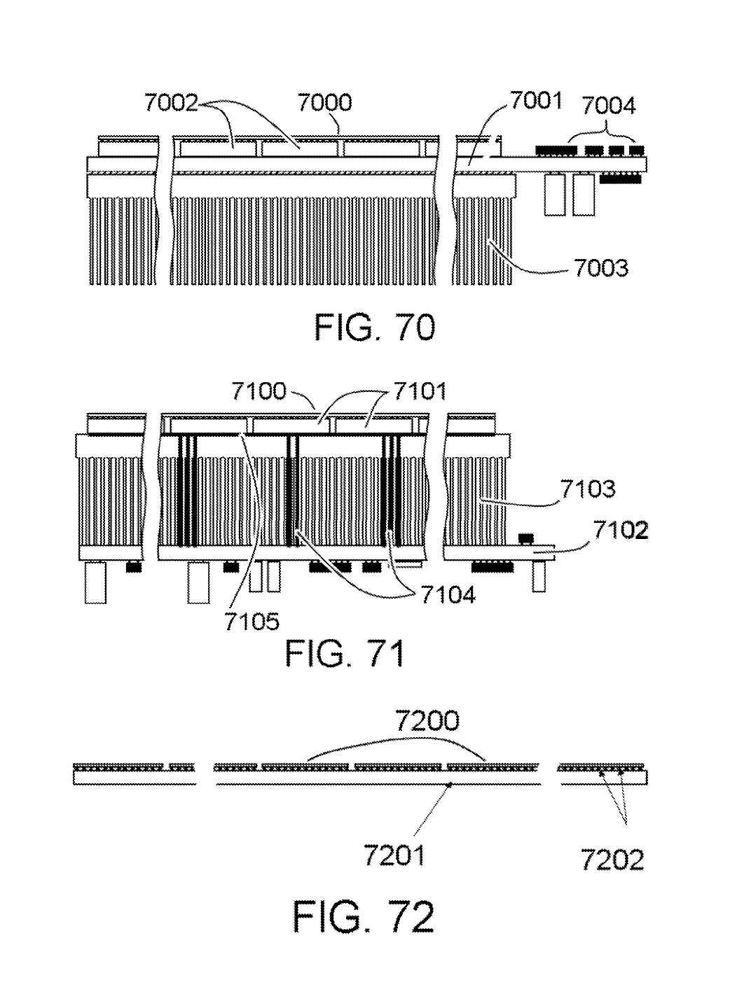

FIG. 71 illustrates a packaged LAMS deposited or fixed on a main substrate support as 6502. A robust and efficient heat-sink (7103) has the main PCB (7102) fixed on its backside. The packaged LAMS (micro-substrate array (7101) with LAMS device (7100)) lies on the heatsink topside. Electrical connections between the packages LAMS and the main PCB (7102) are ensure with flexible PCB or cables (7104) that goes through the heatsink (7103) through dedicated drilled holes.

To ensure more mechanical and thermo-mechanical stability during mounting steps to the set of substrates, an interposer layer (7105) between micro-substrate array (7101) and the heatsink (7103) can also be added.

If the LAMS device can be split into several parts (typically identical) that interact only electrically, another alternative of the whole system assembly is preferred. The LAMS device can be diced into an array of identical cells or other parts. This array is placed and/or fixed on a substrate support as depicted in FIG. 72. This solution is the reverse of the structure described in FIG. 68. The LAMS array (7200) is placed on a substrate (7201) with solder balls (7202).

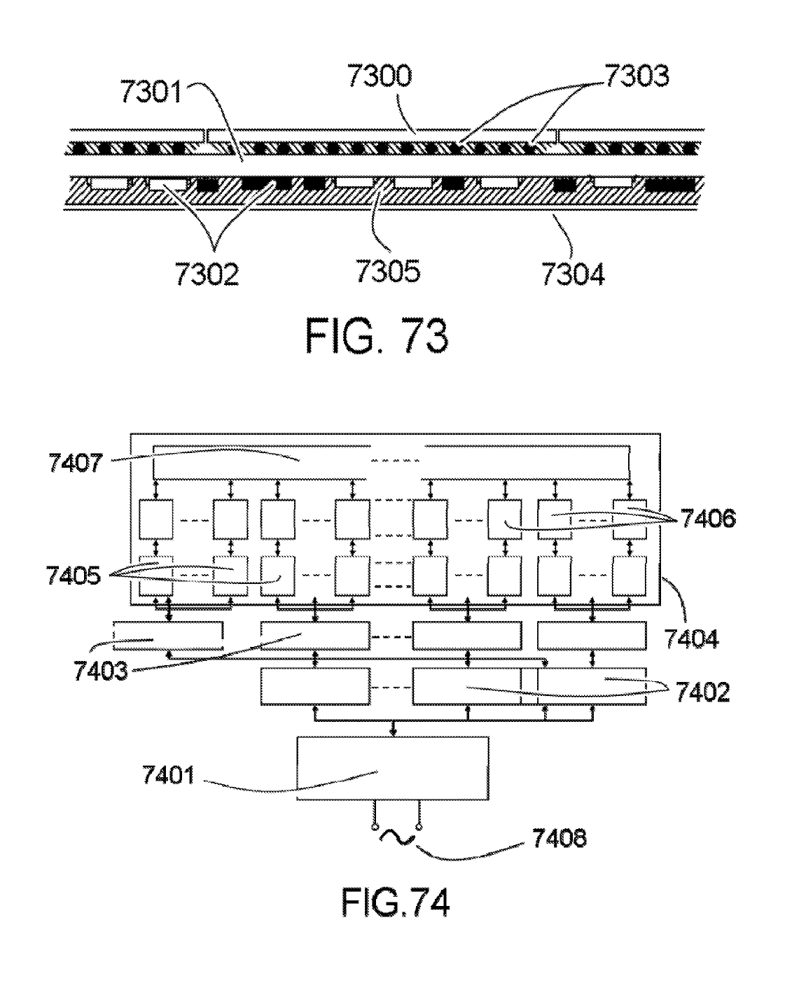

A more details view is given in FIG. 73: the piece of LAMS (7300) is soldered (7303) on a main support substrate (7301) with the possibility of including specific components (7302) on its backside.

Sixth Family of Preferred Embodiments: Distributed and Fault Tolerant Power Supply for Large Area Integrated Circuits

Another aspect of the present invention is able to power any LAMS device. A hierarchical and distributed architecture of a programmable power supply voltage regulator is proposed to satisfy LAMS device power requirements. The global architecture of the power supply system is depicted on FIG. 74.

The hierarchical architecture is well suit to efficiently distribute power to the whole LAMS area. Depending on the LAMS application, the large area of the system imposes a need to design a power supply distribution strategy as robust as possible to provide voltage sources as stable, homogenous and fast-response as possible. The first level of hierarchy (1) feeds a second distributed one (3) through dedicated interconnections (2). The second level (3) feeds a third more distributed hierarchy level (6) also through dedicated interconnections (5) and then reach the entire LAMS area (7). This power supply tree architecture is generic and can be used in all systems where voltage/currents sources have to be spatially/temporally homogenous distributed (in area or volume).

A preferred implementation of this hierarchical and distributed power supply system is given in the following parts.

The first and main stage (1) of the power supply architecture is similar to a computer power supply unit. It is designed to convert 100-120 V (North America and Japan) or 220-240 V (Europe, Africa, Asia and Australia) AC power from the mains to usable low-voltage DC power for the LAMS application. Typical power ranges are from 300 W to 1000 W, depending on the voltage and the current capability needed by the wafer-scale system. All circuitry lays on the backside or main PCB shown in FIGS. 64 and 65.

Most of AC-DC and DC-DC converters have decoupling capacitors and inductors to enhance their dynamic performances. Those capacitors have to be as close as possible to the application to avoid long power lines and the related electromagnetic issues. Large decoupling capacitances are placed directly on the PCB-wafer interface depending on the adopted wafer supporting strategies.

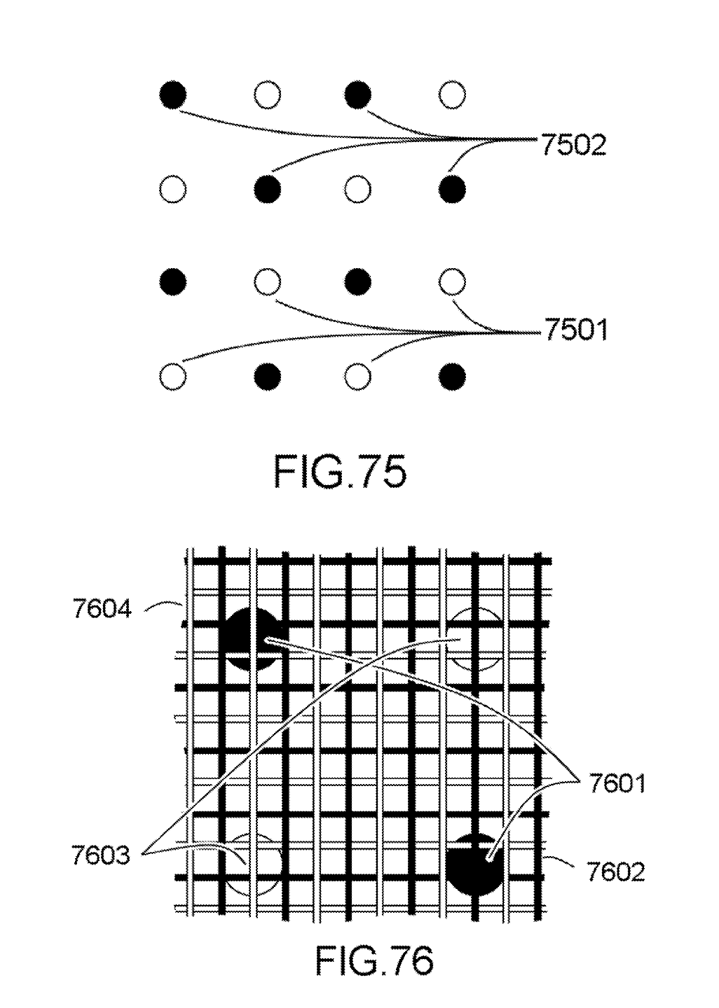

Power and ground connections with the LAMS device are made with solder balls. The distribution of those power and ground solder balls is important to minimize electromagnetic effects between them and to enhance the power supply performances. The power (7501) and ground (7502) balls are equally distributed as depicted on FIG. 75. Several power and ground domains can be defined depending on the supported LAMS application.

In the particular case where the active side of the wafer-scale device is useful, through LAMS vias (TLV) are distributed on the whole surface of the LAMS device, by respecting the same distribution described in previous paragraph.

To distribute the power to the whole LAMS device area, classical techniques for integrated circuits are used. Typically, power distribution within an integrated circuit is done from the top-level metal layer, which is connected to the package, down through inter-layer vias and finally to the active devices, as illustrated in FIG. 76. Power (7604) and ground (7602) stripes are interleaved and form complementary metal grids. Those grids are connected to the power (7603) and ground (7601) solder balls or TLV that provide power supply from the support substrate. Several power and ground domains can be defined by respecting the described physical implementation (interleaved metal grids and access points) depending on the supported LAMS application.

To power wafer-scale application that needs large currents and to avoid electro-migration issues, the power and ground grids can be strengthened with post-processed metal layers, deposited on the topside or the backside of the LAMS device by using standard Wafer Level Packaging processes (WLP) or redistribution layers.

If very robust and stable power supply voltages are needed by the LAMS application, other levels of hierarchy (5-6) can be embedded in the LAMS device (4) in schematic given in FIG. 12. Different possibilities are given in the next sections. Those possibilities can be used alone or combined each other.

A first possibility to improve the power supply system capabilities is to embed local and fast power supply regulators in the LAMS application to provide stable strong currents very close to the final application.

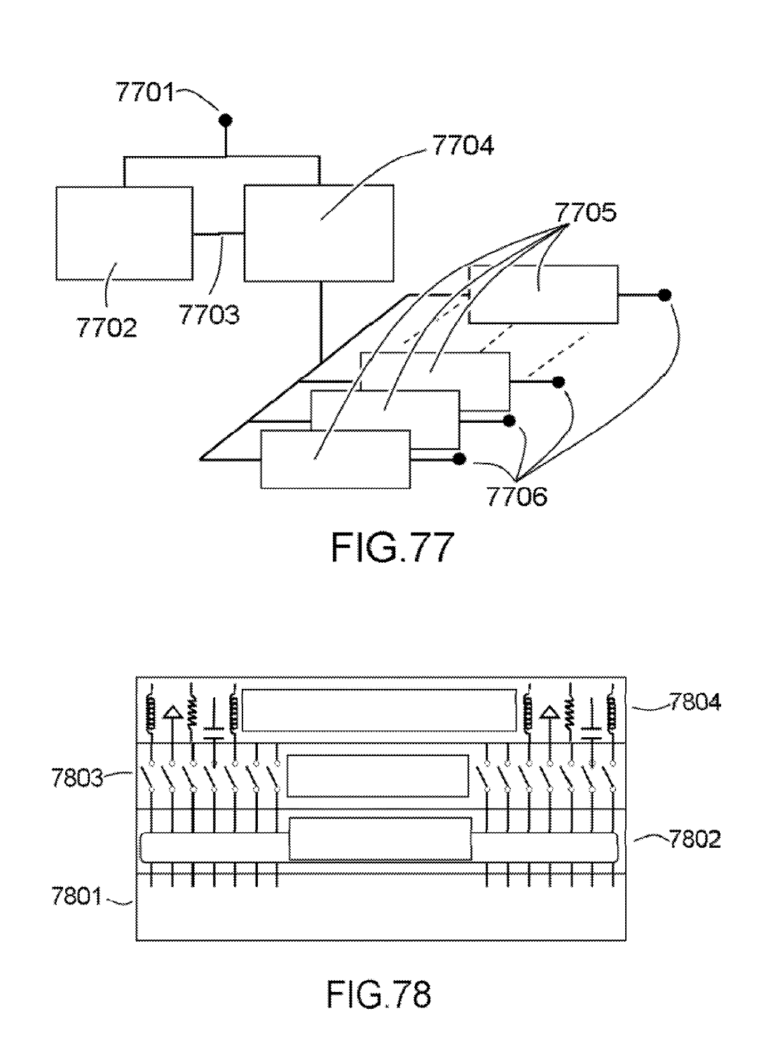

The architecture of the embedded voltage regulators is also a hierarchical architecture and is depicted in FIG. 77. This active circuit can be repeated any times needed and distributed on the LAMS device surface in order to get a power supply voltage as stable and homogenous as possible. A programmable voltage reference (7701) block provides the reference voltage to each regulator. A master regulator stage (7701-7704) can command many slave stages (7705). The number of slave stages is adjusted to adequately respond to the LAMS application power requirements.

Each master stage can contain an accurate voltage sensor. The measured voltage is converted in digital data and then sent to the global system control stage. An accurate and real time power supply voltage map of the wafer-scale device can be elaborated from the data provided by the voltage sensor network.

The real time LAMS surface voltage sensing is useful to control adequately each block of the LAMS power supply chain in order to get the best electrical response of the system to any power supply requirements and/or constraints.

The programmable voltage reference has to provide stable and programmable voltage depending on the LAMS requirements. Different microelectronic (LMOS, CMOS, biCMOS, bipolar) circuitries can be designed to respect those requirements.

Another way to stabilize the power supply voltage on the LAMS surface is to add a level of integrated passive devices.

Decoupling capacitors can be placed on the surface of the LAMS device. Wafer Level Packaging and Integrated Passive Device post processing steps allow to deposit passive devices, as capacitors, on a semiconductor surface. Those capacitors can be connected or not to the LAMS device power lines to enhance its power capability by using post-process MEMS switches.

A large ground plane can be deposited on the LAMS surface (WLP technology) to enhance the electromagnetic behavior of the whole system. Distributed MEMS switches on the LAMS surface allow connecting any LAMS point to a clean ground. This configurable Kelvin ground point networks is useful for electromagnetic sensitive systems or for high power systems.

The present invention provides a configurable network of passive devices. With this network, any contact of the LAMS device can be connected to passive devices such as resistor, capacitor, inductor or ground point. This interesting possibility can be used to strengthen the power supply capability of the LAMS application. It is also useful to adapt the impedance of certain kind of electric signal paths. This networks can be also used to clamp any electrical signal of the LAMS device to a fixed voltage (ground or power voltage for instance). This networks is externally programmable and can be configured ‘on the fly’ during the operation of the LAMS application.

This configurable passive device network is implemented with a superposition of post-processing layers and micro/nano scale technologies deposited on the LAMS application itself. A collection of Integrated Passive Devices is distributed on the LAMS surface. Any device can be connected to neighbor LAMS application dedicated nodes with programmable MEMS switches as depicted on FIG. 16.

The distributed network of MEMS switches (3) allows ensuring low resistive electrical paths between the passive devices and some dedicated LAMS device nodes (2).

The passive device network is obtained by using classical post-processed integrated passive device technologies (IPD).

The three principal classes of integrated passive component technologies that are available today include thin-film technology, low-temperature co-fired ceramic (LTCC) technology, and technologies based on extensions of high-density interconnection (HDI) and other printed circuit board (PCB) technologies. The HDI and PCB technologies are most commonly employed in digital applications, where distributed capacitance and medium precision pull-up resistor functions can be realized at reasonable yield and cost. Of the technologies suited for RF integration, the thin-film integrated passive technologies generally provide the level of precision, range of component values, and functional density to allow a more integrated, smaller, and lighter implementation of a given RF function.

A collection of metal and/or polysilicon resistors with different resistance values is distributed on the whole wafer surface.

A collection of metal capacitors with different capacitance values is distributed on the whole wafer surface.

A collection of metal inductors with different inductance values is distributed on the whole wafer surface.

A low impedance ground grid is implemented with WLP processes on topside or backside of the application. Some distributed and configurable MEMS switches can connect any node of the wafer-scale application to the clean ground plane. This configurable ground network allows enhancing power and EMI characteristics of the system.

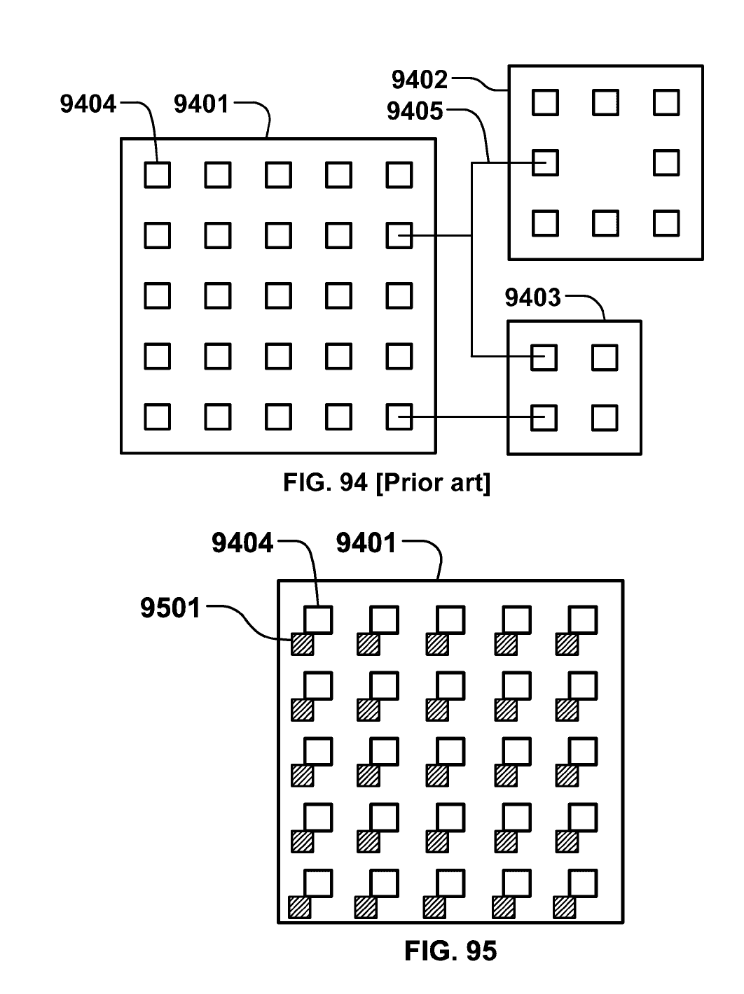

An integrated circuit component is typically connected to other components through its surface contacts, as shown in FIG. 94. FIG. 95 shows support circuitry 9501 for one or several surface contacts 9404. This support circuitry can include at least one of the following functionalities: voltage regulator circuitry, differential signaling support circuitry, signal measurement circuitry, analog-to-digital (ADC) or digital-to-analog (DAC) circuits. Such support circuitries are able to realize many functions that may be integrated into smart Configurable Multi-Purpose IOs (CMPIOs).

The CMPIOs have their own programmable analog and digital circuitries that allow powering many different electrical devices. The output power supply voltage can be externally controlled and is also regulated.

Distributed voltage regulator support circuitry can be activated to feed power to any integrated circuit components connected to its surface contact. This distributed voltage regulator support circuitry has a hierarchical structure similar to that in FIG. 77. This active circuit can be repeated as many times as needed and distributed on the integrated circuit component surface in order to get a power supply voltage as stable and homogenous as possible. A programmable voltage reference (7701) block provides the reference voltage to each regulator. A master regulator stage (7701-7704) can control many slave stages (7705). The number of slave stages is adjusted to adequately respond to the power requirements of the integrated circuit component electrically connected to the surface contact. A plurality of surface contacts of an integrated circuit component can be electrically connected to a power pad of another integrated circuit component 9402 to increase its power capability.

Each master stage can contain an accurate voltage sensor. The measured voltage is converted into digital data and then sent to the global system control stage. An accurate and real-time power supply voltage map of the integrated circuit component can be elaborated from the data provided by the voltage sensor network.

The real time voltage sensing of one or more integrated circuit surface contacts is useful to control adequately each block of the power supply chain of integrated circuit components in order to get the best electrical response to any power supply requirements and/or constraints.

The programmable voltage reference has to provide stable and programmable voltage depending on the integrated circuit requirements. Different microelectronic (LMOS, CMOS, biCMOS, bipolar) circuitries can be designed to respect those requirements.

Seventh Family of Preferred Embodiments: Thermo-Mechanical Stability in LAIC (Large Area Integrated Circuit) Systems

One of the main aims of the invention is to limit as much as possible thermal and pressure stresses on the supported LAMS device. Those thermal effects can have disastrous consequences on LAMS application. An object of the invention is a hierarchical and distributed thermal regulation system.

Thermal and pressure sensors are embedded and distributed on the whole LAMS surface. Those thermal and pressure sensors can be made by using different technologies, depending on the LAMS application technology used. The measured temperatures and pressures are converted in digital data and then sent to the global system control stage. An accurate and real time thermal and pressure maps of the LAMS device can be elaborated from the data provided by the thermal and pressure sensor network.

Programmable thermal heater and coolers are embedded and distributed on the whole LAMS surface. Those heaters and coolers can be made by using different technologies, depending on the LAMS application technology used.

The LAMS distributed thermal sensor and generator networks are directly linked to the system control that can be local or global. Thermal and pressure mechanisms are very slow physical phenomenon and can be regulated and controlled with a real-time software approach. Dangerous temperatures and pressures are detected and their potential consequences are avoided by controlling the thermal generator networks adequately to reduce the differential temperature or in a worst case, by switching off the LAMS device and its components.

Eighth Family of Preferred Embodiments: Differential Electrical Signal Propagation in Integrated Circuit Networks with Configurable Pair Location

An object of the invention is a smart CMOS module that is useful to support all described functionalities. This CMOS circuit is a Configurable Multi-Purposes IO (CMPIO). The output stage of the described module is fully configurable and is able to realize many functions with the same device. The use of the same output stage for different functions allows minimizing the silicon area needed for this smart Configurable Multi-Purposes IO. The output stage is a combination of PMOS and NMOS transistors.

The CMPIOs common functionalities are given below. CMPIOs have their own programmable analog and digital circuitries that allow supporting many single ended digital Input/Output standards (CMOS, TTL). The output or input voltage, the output and input impedances can be externally controlled.

CMPIOs have their own programmable analog and digital circuitries that allow supporting many differential digital single ended Input/Output standards. The output or input voltages, currents, the output and input impedances can be externally controlled.

The CMPIOs also include original features. They have their own programmable analog and digital circuitries that allow powering many different electrical devices. The output power supply voltage can be externally controlled and is also regulated.

A fault tolerant RRN allows propagating single ended digital signals on the wafer-scale application surface (referenced to WaferNet™)

CMPIOs are able to support differential signaling with the particularity that the complementary pair of differential nodes can be placed anywhere on the LAMS application surface. To support this spatial uncertainty, a dedicated configurable differential signaling structure is described below.

CMPIOs can drive and can be driven by configurable input/output balanced H-tree networks called WaferDiffNet™.

WaferDiffNet is a hierarchical configurable input/output H-tree network that propagates balanced differential signals from CMPIOs to RRN or from RRN to CMPIOs. It can be considered as a differential signal ‘window’ on the wafer surface, that can be resized or moved depending on the differential signal ball locations.

A cell-based hierarchical approach is used to simplify the physical implementation of such complex balanced configurable H-tree networks on a wafer-scale application. The size of a unit square cell tiled through the full wafer-scale active surface is noted L_{cell}.

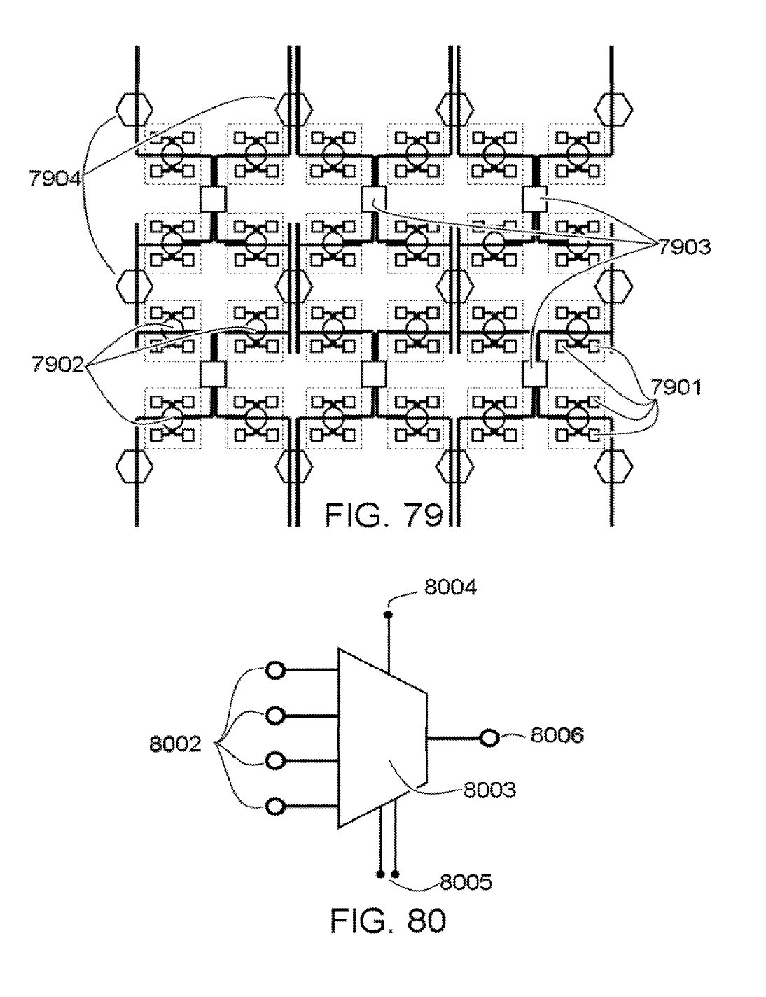

A four hierarchical level WaferDiffNet logical structure is depicted on FIG. 79. This structure allows propagating balanced input/output differential signal on the wafer-scale application through the WaferNet™.

The 4 level WaferDiffNet can support differential IOs distant from a minimal length of √2.L_{cell} to a maximum length of 4.√2.L_{cell} depending on the differential IO placements and orientations.

Each stage of the output WaferDiffNet™ is configurable and can propagate or not a single ended digital signal to the 4 connected following stages as a digital de-multiplexer. Classical three-state buffers or inverters can be used to implement fast digital de-multiplexers for each stage of the output WaferDiffNet.

Metal interconnections between each stage are regular and are implemented using top level metal layers of the CMOS technology used for delay dispersion and jitter considerations.

The three-state buffers used in each stage are well sized and balanced considering their loads especially the metal line interconnection lengths and capacitances in order to be able to propagated high-speed digital signals.

Each stage if the input WaferDiffNet is configurable and can propagate or not analog signals. Analog multiplexers coupled with differential to singled ended signal converters are used in each stage of the input WaferDiffNet.

Each stage of the input WaferDiffNet can be set in a low-power mode by an external configuration in order to minimize the whole structure power consumption.

Considering the 4 level WaferDiffNet depicted on FIG. 79, the first stage (7901) logic of this hierarchical structure is detailed on FIG. 80.

The first stage of the 4 level WaferDiffNet is only a 4-to-1 analog multiplexer (8003) that propagates or not analog signal from CMPIOs at its inputs (8002) to the second stage input (8006) depending on the external configuration (8004-8005).

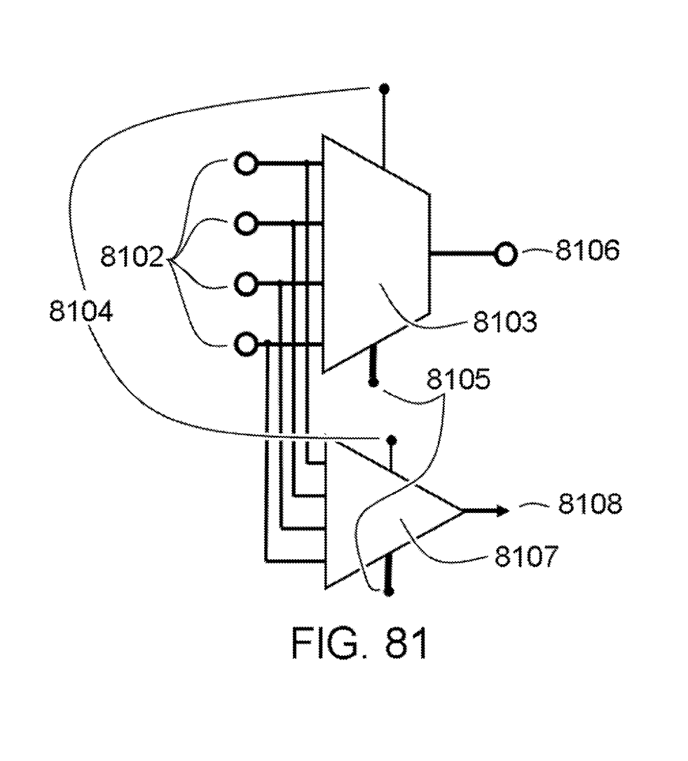

Considering the 4 level WaferDiffNet depicted on FIG. 79, the second stage (7902) logic of this hierarchical structure is detailed on FIG. 81.

The second stage of the 4 level WaferDiffNet is a 4-to-1 analog multiplexer (8103) that propagates or not analog signals coupled with a configurable differential to single ended converter (8107).

The 4-to-1 analog multiplexer (8103) of the second stage allows propagating or not analog signals from the outputs of the first stages (8102) to the third stage input (8106) depending on the external configuration (8104-8105).

The configurable differential to single ended converter (8107) of the second stage can select a pair of differential signals provided by the previous stages (8102) between 4 pair possibilities and then transform them into a single ended digital signal that is directly sent to the global WaferNet™ (8108).

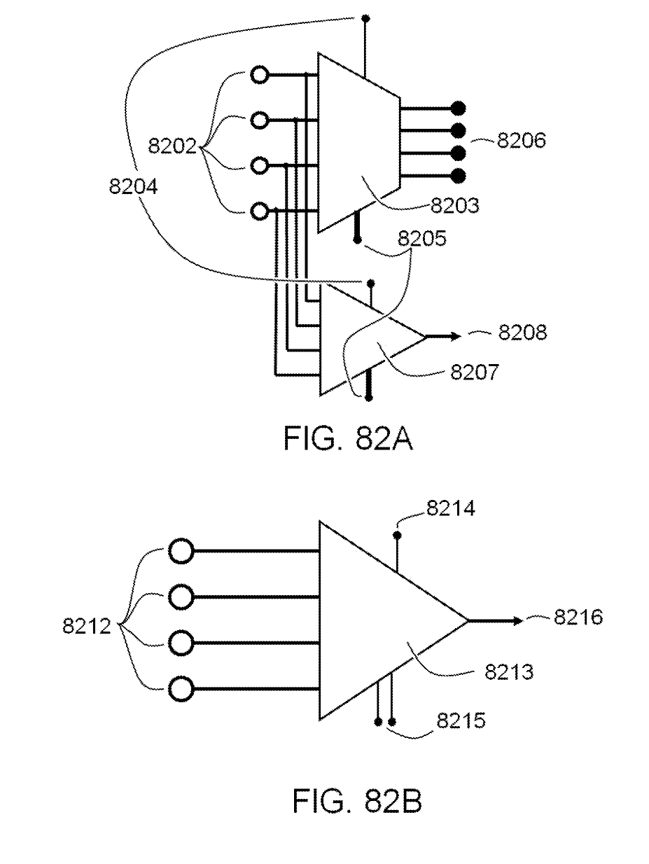

The third stage of the 4-level WaferDiffNet can also be depicted on FIG. 82a. It is a 4-to-4 analog multiplexer (8203) that propagates or not analog signals coupled with a configurable differential to single ended converter (8207).

The 4-to-4 analog multiplexer (8203) of the third stage allows propagating or not analog signal from the outputs (8202) of the second stages to inputs (8206) of the fourth stages depending on the external configuration (8204-8205). The possibility to address 4 different fourth stages around a third one allows the configurable network to cover the whole wafer area and to support all differential signal ball pitches. The differential configurable network ‘window’ can slide with a step of a half ‘window’.

The configurable differential to single ended converter (8207) of the third stage can select a pair of differential signals (8202) provided by the previous stages between 12 pair possibilities and then transform them into a single ended digital signal that is directly sent to the global WaferNet™(8208).

The fourth stage of the 4 level WaferDiffNet is a configurable differential to single ended converter and is depicted on FIG. 82b.

The configurable differential to single ended converter (8213) of the fourth stage can select a pair of differential signals provided by the previous stages (8212) between 12 pair possibilities depending on the configuration (8214-8215) and then transform them into a single ended digital signal that is directly sent to the global WaferNet™ (8216).

CMPIOs are also able to support differential signaling with the particularity that the complementary pair of differential nodes can be placed to any surface contact of the integrated circuit component.

CMPIOs can drive and can be driven by configurable input/output balanced H-tree networks called DiffNet.

A digital network (DN) inside the integrated circuit component allows propagating single ended digital signals on the integrated circuit application surface. The integrated circuit can have any size up to a full wafer.

DiffNet is a hierarchical configurable input/output H-tree network that propagates balanced differential signals from CMPIOs to DN or from DN to CMPIOs. It can be considered as a differential signal ‘window’ on the integrated circuit surface that can be resized or moved depending on the differential signal surface contact locations.

A cell-based hierarchical approach is used to simplify the physical implementation of such complex balanced configurable H-tree networks on the integrated circuit component. The edge length of a unit square cell tiled through the integrated circuit surface is noted L_{cell}.

In a preferred embodiment, a four hierarchical level DiffNet logical structure is depicted in FIG. 79. This structure allows propagating one or more balanced input/output differential signals on the integrated circuit component through the DN.

The 4 level DiffNet can support differential IOs (differential surface contacts) distant from a minimal length of √2.L_{cell} to a maximum length of 4.√2.L_{cell} depending on the differential IO placement and orientation.

Each stage of the output DiffNet is configurable and can propagate or not a single ended digital signal to the 4 connected following stages as a digital de-multiplexer. Classical three-state buffers or inverters can be used to implement fast digital de-multiplexers for each stage of the output DiffNet.

In the proposed configuration, metal interconnections between each stage are regular and can be implemented using top level metal layers of the CMOS technology used for delay dispersion and jitter considerations.

The three-state buffers used in each stage are well sized and balanced considering their loads, especially the metal line interconnection lengths and capacitances in order to be able to propagated high-speed digital signals.

Each input stage of DiffNet is configurable and can propagate or not analog signals. Analog multiplexers coupled with differential to singled ended signal converters are used in each stage of the input DiffNet.

Each stage of the input DiffNet can be set in a low-power mode by an external configuration in order to minimize the power consumption of the whole structure.

Considering the 4 level DiffNet depicted on FIG. 79, the first stage (7901) logic of this hierarchical structure is detailed in FIG. 80.

The first stage of the 4 level DiffNet is only a 4-to-1 analog multiplexer (8003) that propagates or not an analog signal from CMPIOs at its inputs (8002) to the second stage input (8006) depending on the external configuration (8004-8005).

Considering the 4 level DiffNet depicted in FIG. 79, the second stage (7902) logic of this hierarchical structure is detailed in FIG. 81.

The second stage of the 4 level WaferDiffNet is a 4-to-1 analog multiplexer (8103) that propagates or not analog signals coupled with a configurable differential to single ended converter (8107).

The 4-to-1 analog multiplexer (8103) of the second stage allows propagating or not analog signals from the outputs of the first stages (8102) to the third stage input (8106) depending on the external configuration (8104-8105).

The configurable differential to single ended converter (8107) of the second stage can select a pair of differential signals provided by the previous stages (8102) between 4 pair possibilities and then transforms them into a single ended digital signal that is directly sent to the global DN (8108).

A preferred structure for the third stage of the 4-level DiffNet is also depicted in FIG. 82a. It is a 4-to-4 analog multiplexer (8203) that propagates or not analog signals coupled with a configurable differential to single-ended converter (8207).

The 4-to-4 analog multiplexers (8203) of the third stage allow propagating or not analog signals from the outputs (8202) of the second stages to inputs (8206) of the fourth stages depending on the external configuration (8204-8205). The possibility to select 4 different fourth stages around a third one allows the configurable network to cover the whole wafer area and to support all differential signal ball pitches. The differential configurable network ‘window’ can slide with a step of a half ‘window’.

The configurable differential to single ended converter (8207) of the third stage can select a pair of differential signals (8202) provided by the previous stages between 12 pair possibilities and then transform them into a single ended digital signal that is directly sent to the global DN (8208).

The fourth stage of the 4 level DiffNet is a configurable differential to single ended converter depicted in FIG. 82b.

The Configurable Differential to Single Ended Converter (8213) of the Fourth Stage can Select a Pair of Differential Signals Provided by the Previous Stages (8212) Between 12 Pair Possibilities Depending on the Configuration (8214-8215) and then Transform them into a Single Ended Digital Signal that is Directly Sent to the Global DN (8216). Ninth Family of Preferred Embodiments: Propagation of Analog Signals on a Digital Interconnect Network and Support for Analog Signals

To fulfill the need for reprogrammable circuits carrying analog signals, the present invention discloses converting one or more analog signals to one or more digital signals or quantities that can reliably be propagated though a reprogrammable digital network, and then converting the signal back to analog at the destination. Any known conversion technique can be implemented. In a preferred embodiment of the invention, an analog signal is converted to a digital signal or quantities that can reliably be propagated though embedded digital interconnects, and then converted to an analog signal at the destination.

Any conversion technique can be implemented. One way to obtain that functionality is to embed Analog-to-Digital or Digital-to-Analog converters to convert the signals from analog to digital and vice versa.

Another technique is to use of a voltage controlled oscillator (VCO) [37-39] to convert the analog signal into a digital stream or a signal whose frequency varies with the magnitude of the analog input signal. A frequency to analog conversion is then done at the destination.

The same conversion principle can be applied with delta-sigma modulation [37-39].

Another invention is to propagate analog signal between to I/O with one or several metal grids (typically used for power) coupled with large transmission gates.

Once Analog-to-Digital or Digital-to-Analog converters are introduced in a programmable or configurable fabric such as the one proposed in this invention, in addition to propagating analog quantities for one I/O to another, it becomes possible to convert an analog quantity that originates from an integrated system or to drive some internal node using an analog quantity using a suitable converter. Thus information detected by an internal sensor in analog form can be propagated over a digital switch fabric, and used elsewhere inside or outside of the integrated system. It should be understood that I/O here could be any of a CMPIO, a port of the test controller or some TSV propagating some electrical signal in a 3D assembly. This allows measuring the voltage drop in a TSV used as a shunt, the drop (peak or average) in power distribution path, the temperature or mechanical stress at some internal point. It also allows distributing and controlling an internal node meant to receive an analog reference or any form of analog quantity as in any regular analog feedback path, except that part of that path would in fact be propagated as a form or digital signal over one or more than one connection in a substantially serial or substantially parallel way. The invention also covers the digital path used to propagate information in the form of a modulation in frequency or pulse width of a substantially digital signal.

Another use of the concept of propagating a digital signal to drive a substantially analog quantity would allow trimming an analog function using a digital correction that could be stored in a register, in some form of non volatile memory such as fuses, zener-zapped devices or floating-gate devices or in devices whose parametric value may be altered by the application of a current or of an external stimuli such as one or more laser pulse. In the case of floating-gate devices, they may also store an analog quantity. The support circuitry could thus be any circuitry required to support known trimming of an analog function. A known benefit of such trimming is to adjust for process or environment variation to correct the accuracy of the analog function. That could be applied for instance to voltage references, current sensors, voltage sensors, embedded amplifier, voltage regulator. This list is not restrictive. It should be understood that temperature gradient or voltage drops in power distribution networks are prone to induce environment parametric variations. Other sources of parametric variations could also be managed in the same way.

Tenth Family of Preferred Embodiments: Smart Thermo-Mechanical Prediction Unit and Monitoring Methods to Sustain Transient Thermo-Mechanical Stress Peaks Reliability in Large Area Integrated Circuit Systems

The effects of mechanical stress on VLSI devices behavior are of significance to modern integrated circuit manufacturers since large values of stress can be induced by various steps during fabrication and by a variety of packaging processes, including die attachment and encapsulation. One of the major concerns in designing such packages is the reliability of solder joints, die, and the various material interfaces present in the package.

Smart thermo-mechanical prediction unit and monitoring methods to sustain thermo-mechanical stress peaks reliability in embedded high density VLSI system according to a first family of preferred embodiments of the present invention overcomes these drawbacks of the prior art by providing a useful prediction unit and monitoring methods to detect and therefore avoid critical stress by monitoring the whole active LAIC surface.

Preferred embodiments of the present invention therefore use a method that is more efficient by using embedded pressure and thermal array sensors network. While many such networks are known in the art, two that are considered exemplary for their simplicity, efficiency, flexibility and robustness are discussed herein, with flexibility for grouping and interconnection needs of the present invention.

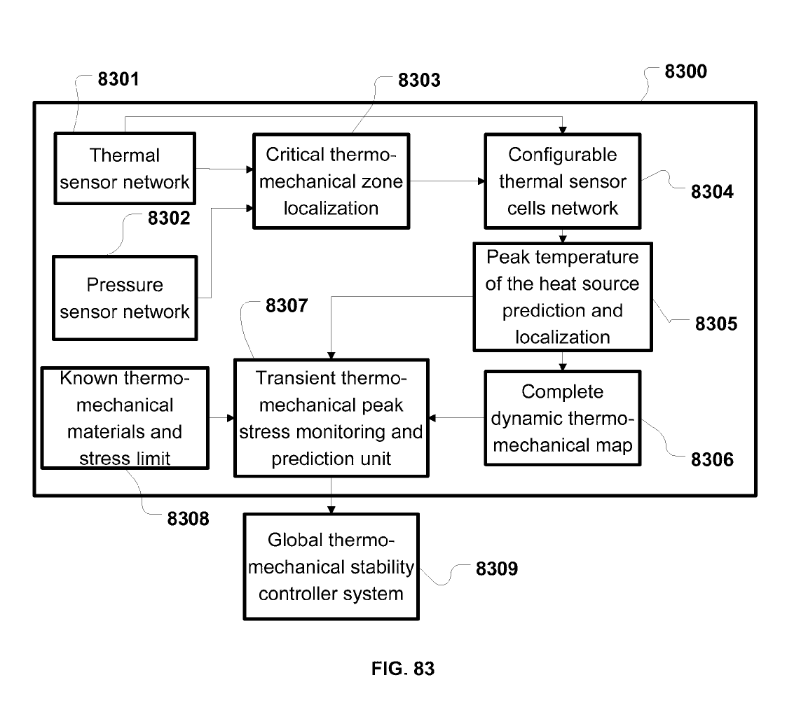

FIG. 83 is a conceptual block diagram depicting a whole smart thermo-mechanical prediction unit to sustain transient thermo-mechanical stress peaks reliability in LAIC (Large Area Integrated Circuit) systems; First, the combination of the temperature sensors network (8301) and the pressure sensor network (8302) gives preliminary measurements that allows a critical thermo-mechanical zone localization (8303) then the appropriate configurable thermal sensor cells network (8304) established and used to predict and localize the peak temperature of the heat source (8305); second the transient thermo-mechanical peaks stress monitoring and prediction (8307) will be achieved by processing data from localization and peak temperature of the heat source prediction (8305), complete dynamic thermo-mechanical map (8306) and known thermo-mechanical materials and stress limit (8308); finally for critical situation the emergency signal will be sent to the global thermo-mechanical stability controller system (8309).

Smart thermo-mechanical prediction unit and monitoring methods to sustain thermo-mechanical stress peaks reliability in SoC according to a second family of preferred embodiments of the present invention can help designer of the future high density SoC by controlling critical hot spot and associated stress level during operation and hence avoiding these drawbacks of the prior art by providing a useful prediction unit and monitoring methods to detect and therefore avoid critical stress by monitoring the whole active SoC surface.

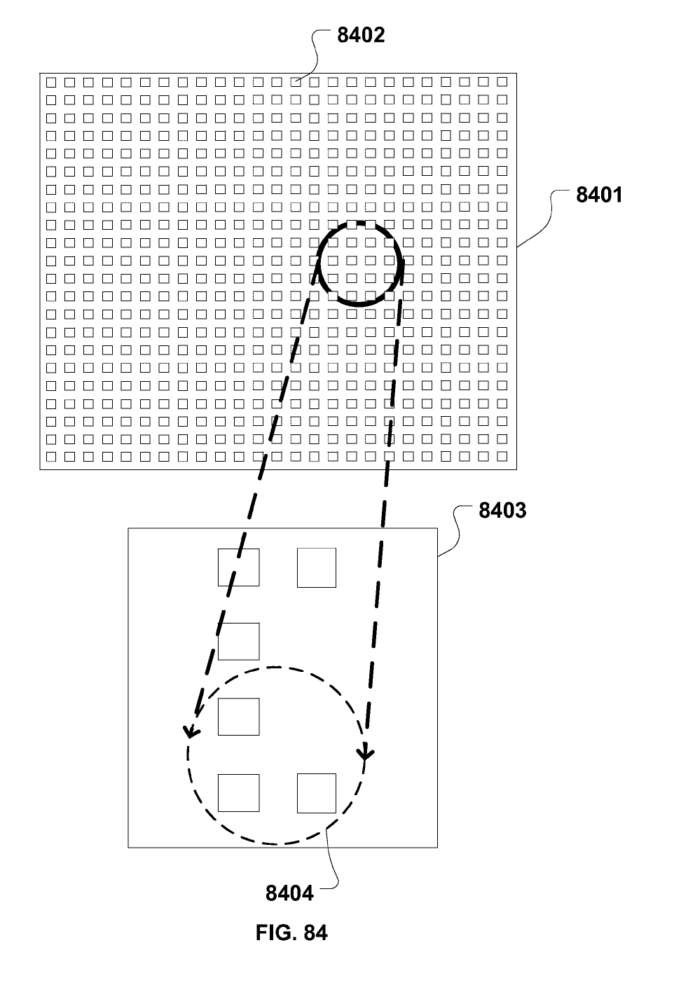

FIG. 84 includes an embedded thermal or pressure sensor network (8401) (or both) on LAIC systems in which a fine-pitched (sensor to sensor) allows substantially all of the surface temperature or pressure to be measured by using an embedded thermal or pressure sensor (8402) on LAIC systems to allows coarse localized temperature or pressure to be measured;

A possible configurable thermal sensor cell couple (8403) is selected from thermal sensor network (8401) embedded on LAIC systems by grouping three individual thermal sensors (8402) to build thermal sensor cell (8404) to allows the surface temperature peak value measured and position to be localized;

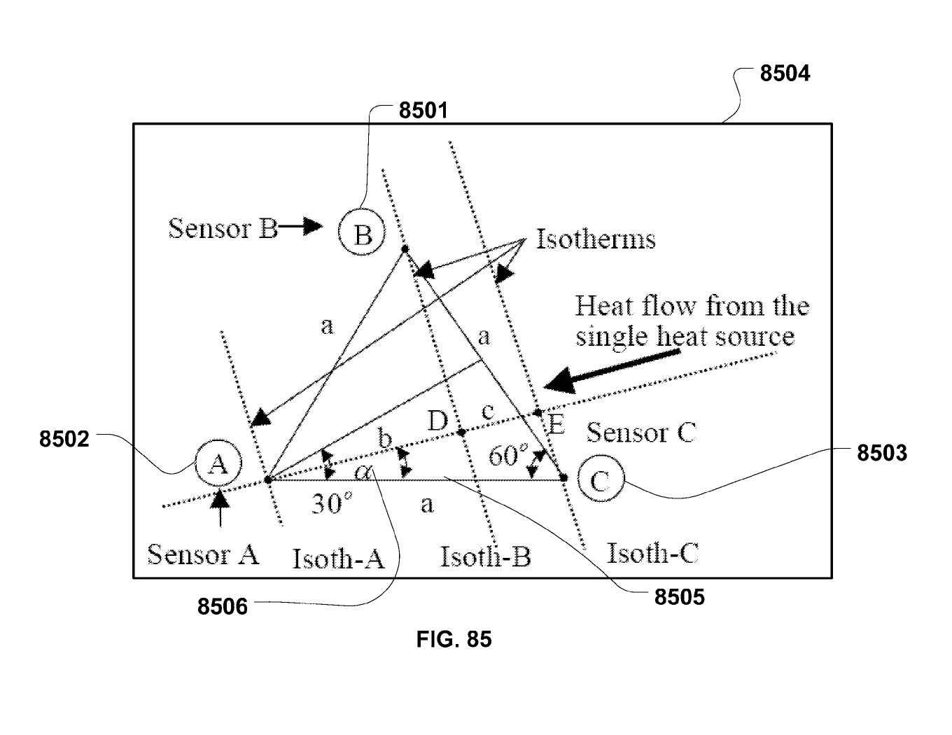

One sensor unit cell (8504) depicted in FIG. 85 is configured by grouping three sensors (8501, 8502 and 8503) from (8401) in equilateral triangle as thermal sensor cell (8504) to be coupled with another unit cell sensors triplet selected also from (8401) to form a configurable thermal sensor cells couple (8503) on LAIC systems to allows the surface temperature peak value measured and position to be localized;

For two sensors A (8502) and C (8503) placed in the distance a on line AC (8505), the difference between their output voltages or frequency in the case of using RO (Ring Oscillators) is proportional to the changes of the temperature value along the line 8505. This is true only when the heat source is directly on the line AC 8505 for any other cases the values of the angle α 8506 has to be taken into account for the proper calculation of ΔT.

Using one sensor unit cell (8504), the information on the temperature distribution and partly on the position of the heat source is obtained. In order to obtain the temperature value of a single punctual heat source, the distance between the sensor and the heat source is calculated.

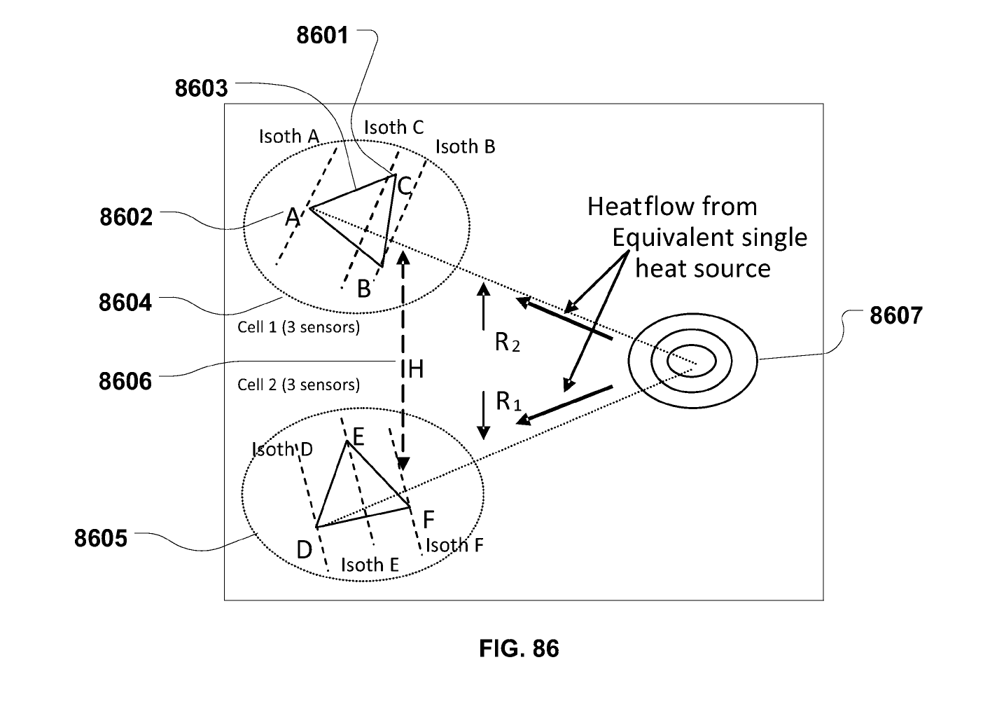

The information on the temperature distribution and partly on the position of the heat source is obtained by using multiple sensor couple, as shown on FIG. 86. selected from (8401) on LAIC systems to allows the surface temperature peak value measured and position to be localized.

In the preferred embodiment, two sensor unit cells 8604 and 8605 are required for this purpose. The cells are placed in a given distance H (8606) and each of them gives information about the angle α (α1 and α2) in the direction of the heat source 8607.

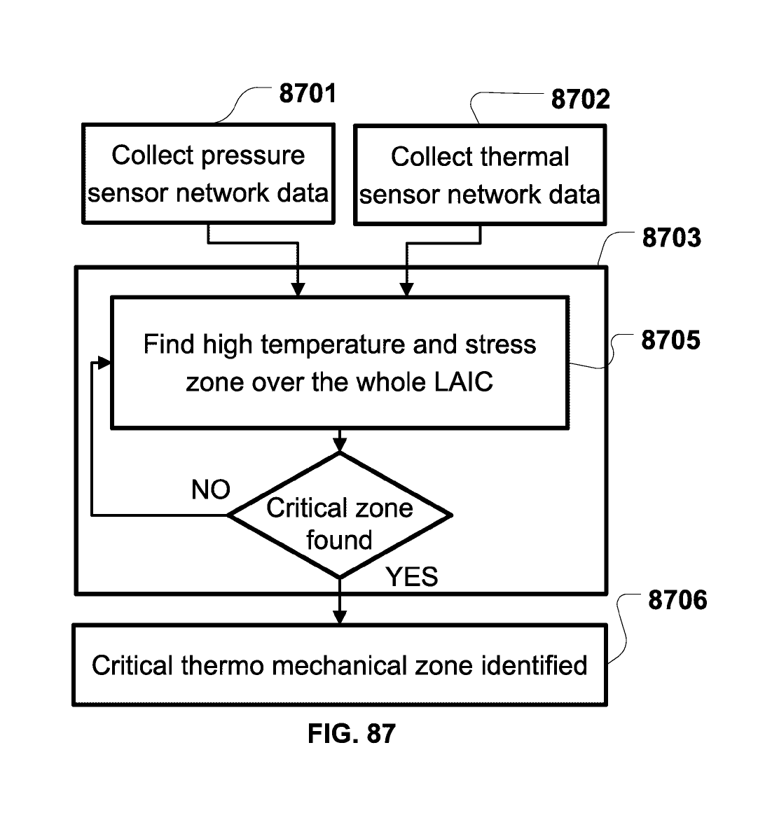

The conceptual block diagram on FIG. 87 depicts a critical thermo-mechanical zone localization based on first measurement of temperature sensors network; (8702) and pressure sensors network (8701); the scan over the whole LAIC (8705) is done to find high temperature and stress zone for identifying the critical thermo mechanical zone (8706);

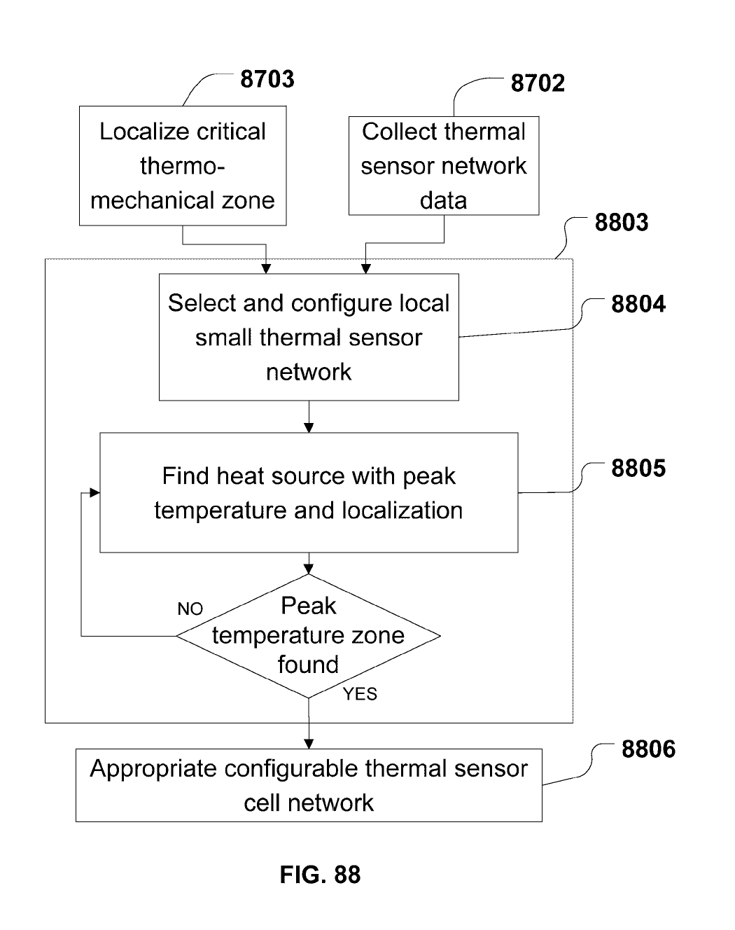

A preferred embodiment for finding heat source with peak temperature and the corresponding localization is described in the conceptual block diagram of FIG. 88, with a final module to confirm the appropriate configurable thermal sensor cell network (8806). Selection and configuration of local small thermal sensor network (8803) is based on the critical thermo-mechanical zone localization (8801) and thermal sensor network measurements (8802); the scan over the whole LAIC is done to find heat source with peak temperature and the corresponding localization (8805).

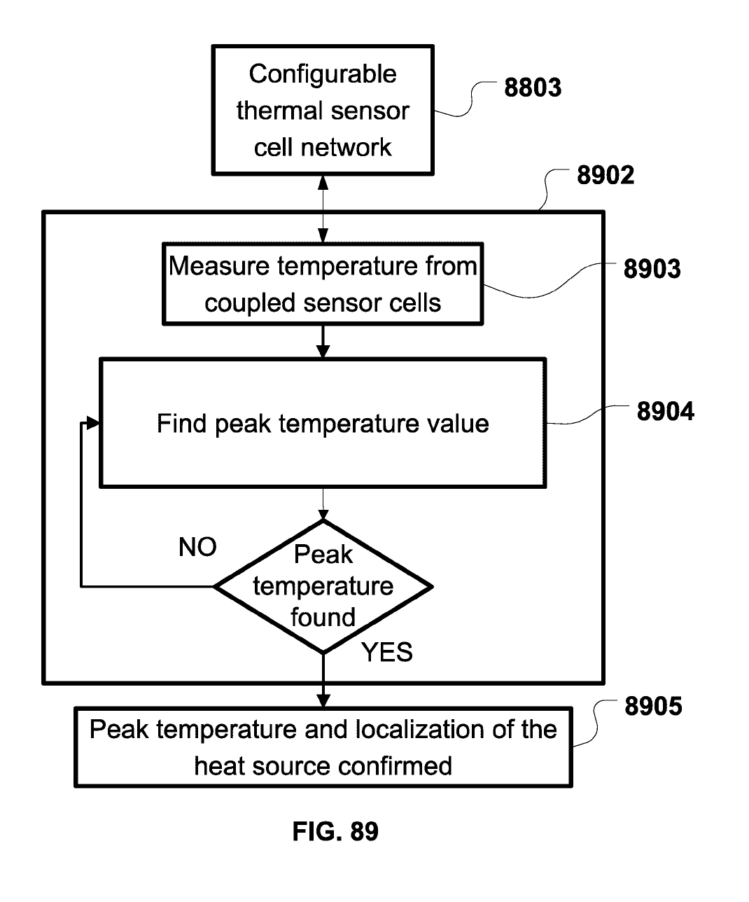

A preferred embodiment for confirmation of peak temperature and localization of the heat source (8905) is depicted in conceptual block diagram off FIG. 89. Finding peak temperature value (8904) is based on the temperature measurement from coupled sensor cells (8903) and configurable thermal sensor cells network (8901); local scan over the six sensors selected is done to confirm the peak temperature and localization of the heat source (8905);

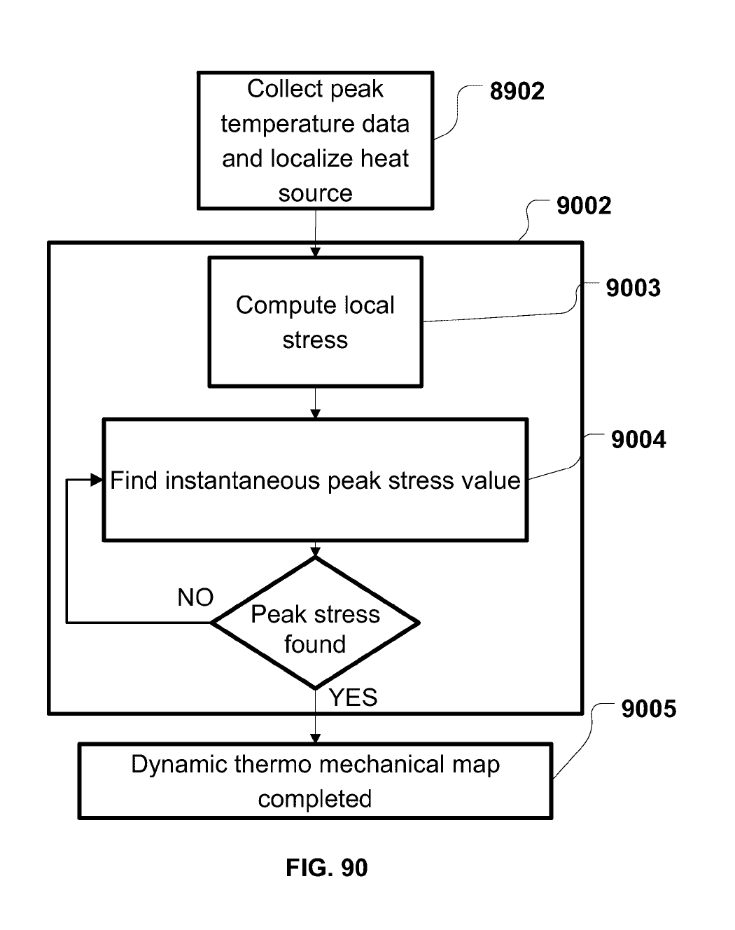

A preferred embodiment to extract a dynamic thermo mechanical map of the state of thermo mechanical stress (9005) is described in the conceptual block diagram of FIG. 90. A scan to find instantaneous peak stress value (9004) is based on the local stress computation (9003) and peak temperature of the heat source prediction and localization (9001);

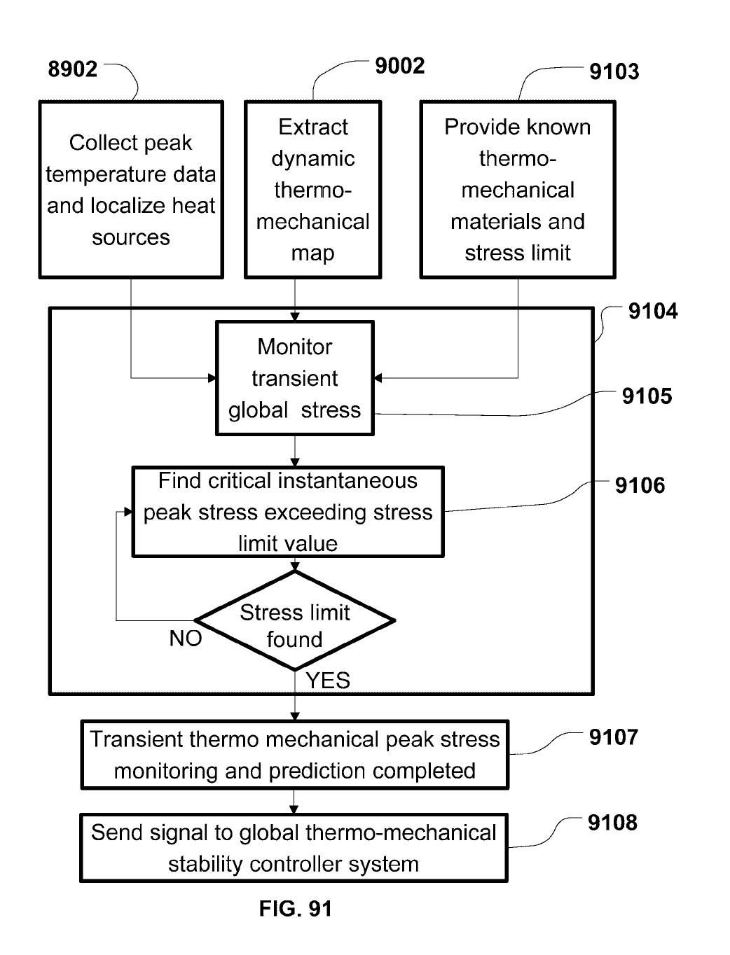

A preferred embodiment shown on FIG. 91 is a conceptual block diagram depicting a transient thermo mechanical peaks stress monitoring and prediction unit (9104) based on peak temperature of the heat source prediction and localization (9101), on a complete dynamic thermo-mechanical map computations (9102) and on the known thermo-mechanical materials characteristics and stress limit (9103) of the LAIC system; the scan over the whole LAIC is done to achieve transient global stress monitoring (9105) to find a critical instantaneous peak stress (9107) exceeding stress limit value; if it is the case alerting signal will be sent to a global thermo-mechanical stability controller system (9108);

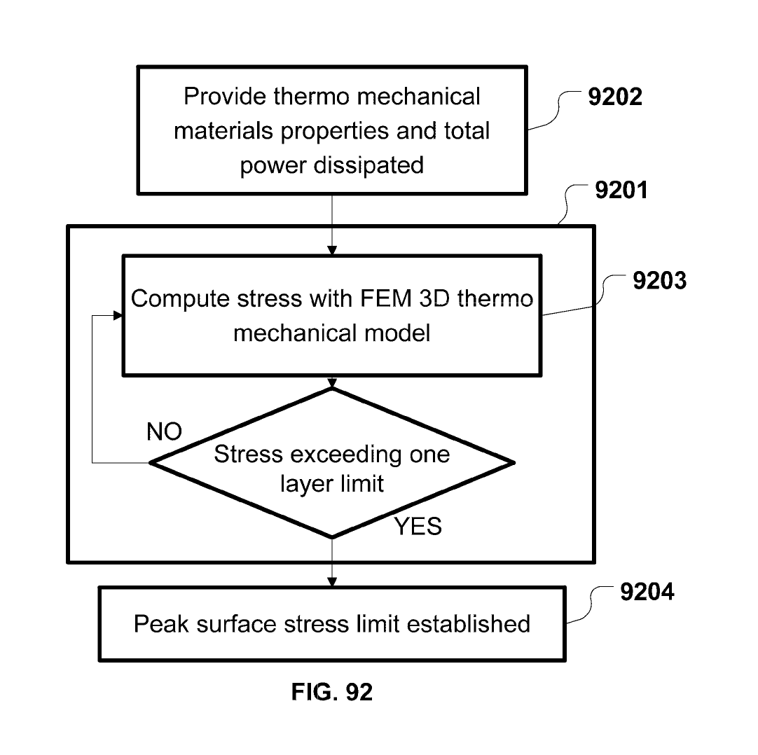

A preferred embodiment shown on FIG. 92 as a conceptual block diagram is the peak surface stress limit characterization (9201) based on thermo mechanical materials proprieties (9202) and FEM (Finite Element Method) 3D thermo-mechanical model stress computation (9203), the scan over the whole LAIC is done to verify if instantaneous local stress exceeding one layer limit from data provided by FEM 3D model thermo-mechanical stress computation.

### REFERENCES

[1] R. Norman, “Reprogrammable Circuit Board with Alignment-Insensitive Support for Multiple Component Contact Types,” U.S. Patent, Application 20080143379, 2008.
[2] Y. Savaria and M. Lu, “Fault tolerant scan chain for a parallel processing system,” U.S. Pat. No. 6,928,606, 2005.
[3] R. Kermouche and Y. Savaria, “Defect and fault tolerant scan chains,” in Defect and Fault Tolerance in VLSI Systems, 1994. Proceedings., The IEEE International Workshop on, 1994, pp. 185-193.

[4] H. Chun-Lung and C. Ting-Hsuan, “Built-in Self-Test Design for Fault Detection and Fault Diagnosis in SRAM-Based FPGA,” Instrumentation and Measurement, IEEE Transactions on, vol. 58, pp. 2300-2315, 2009.

[5] Y. L. Peng, et al., “BIST-based diagnosis scheme for field programmable gate array interconnect delay faults,” Computers & Digital Techniques, IET, vol. 1, pp. 716-723, 2007.
[6] M. Abramovici, et al., “Online BIST and BIST-based diagnosis of FPGA logic blocks,” Very Large Scale Integration (VLSI) Systems, IEEE Transactions on, vol. 12, pp. 1284-1294, 2004.
[7] A. Doumar and H. Ito, “Detecting, diagnosing, and tolerating faults in SRAM-based field programmable gate arrays: a survey,” Very Large Scale Integration (VLSI) Systems, IEEE Transactions on, vol. 11, pp. 386-405, 2003.
[8] T. S. J. Payakapan, CA, US), Chung, Lee Ni (San Jose, Calif., US), Toutounchi, Shahin (Pleasanton, Calif., US), “Built-in self test (BIST) technology for testing field programmable gate arrays (FPGAs) using partial reconfiguration,” U.S. Pat. No. 7,302,625, 2007.
[9] M. B. H. Abramovici, NJ, US), Stroud, Charles E. (Charlotte, N.C., US), “Identifying faulty programmable interconnect resources of field programmable gate arrays,” U.S. Pat. No. 6,966,020, 2005.
[10] Y. Basile-Bellavance, et al., “Faults diagnosis methodology for the WaferNet interconnection network,” in Circuits and Systems and TAISA Conference, 2009. NEWCAS-TAISA '09. Joint IEEE North-East Workshop on, 2009, pp. 1-4.
[11] K. Ohsawa, et al., “3-D assembly interposer technology for next-generation integrated systems,” in Solid-State Circuits Conference, 2001. Digest of Technical Papers. ISSCC. 2001 IEEE International, 2001, pp. 272-273.
[12] S. S. Wong and A. El Gamal, “The prospect of 3D-IC,” in Custom Integrated Circuits Conference, 2009. CICC '09. IEEE, 2009, pp. 445-448.
[13] M. Kawano, et al., “Three-Dimensional Packaging Technology for Stacked DRAM With 3-Gb/s Data Transfer,” Electron Devices, IEEE Transactions on, vol. 55, pp. 1614-1620, 2008.
[14] S. E. a. M. I. (SEMI), “3D Integration: A Progress Report,” Semiconductor Equipment and Materials International (SEMI). 2009.
[15] B. N. D. Eldridge, Calif., US), Reynolds, Carl V. (Pleasanton, Calif., US), “Wafer level interposer,” U.S. Pat. No. 7,649,368, 2010.
[16] T. L. C. C. Sterrett, AZ, US), Natekar, Devendra (Chandler, Ariz., US), “Etched Interposer for Integrated Circuit Devices,” U.S. Patent, Application 20080265391, 2008.
[17] M. Boule, et al., “Assertion Checkers in Verification, Silicon Debug and In-Field Diagnosis,” in Quality Electronic Design, 2007. ISQED '07. 8th International Symposium on, 2007, pp. 613-620.
[18] L. Benini, et al., “A survey of design techniques for system-level dynamic power management,” Very Large Scale Integration (VLSI) Systems, IEEE Transactions on, vol. 8, pp. 299-316, 2000.
[19] V. Raghunathan, et al., “A survey of techniques for energy efficient on-chip communication,” in Design Automation Conference, 2003. Proceedings, 2003, pp. 900-905.
[20] L. Benini, et al., “Monitoring system activity for OS-directed dynamic power management,” in Low Power Electronics and Design, 1998. Proceedings. 1998 International Symposium on, 1998, pp. 185-190.
[21] S. Zhang, et al., “Implementation of standard IEC 61970 in EMS systems,” in Power System Technology, 2004. PowerCon 2004. 2004 International Conference on, 2004, pp. 114-118 Vol. 1.
[22] F. Douglis, et al., “Adaptive Disk Spin-down Policies for Mobile Computers,” presented at the Proceedings of the 2nd Symposium on Mobile and Location-Independent Computing, 1995.
[23] H. Chi-Hong and A. C. H. Wu, “A predictive system shutdown method for energy saving of event-driven computation,” in Computer-Aided Design, 1997. Digest of Technical Papers., 1997 IEEE/ACM International Conference on, 1997, pp. 28-32.
[24] J. Balachandran, et al., “Efficient Link Architecture for On-Chip Serial links and Networks,” in System-on-Chip, 2006. International Symposium on, 2006, pp. 1-4.
[25] Z. Xiuyi, et al., “Thermal-Aware Task Scheduling for 3D Multicore Processors,” Parallel and Distributed Systems, IEEE Transactions on, vol. 21, pp. 60-71, 2010.
[26] M. J. E. Lee, et al., “CMOS high-speed I/Os—present and future,” in Computer Design, 2003. Proceedings. 21st International Conference on, 2003, pp. 454-461.
[27] D. Brooks, Signal Integrity Issues and Printed Circuit Board Design Jun. 24, 2003 ed.: Prentice Hall, pages.
[28] PCI-SIG. (2005, PCI Express™ Architecture, PCI Express™ Jitter and BER, Technical Library. Available: http://www.pcisig.com/specifications/pciexpress/technical_library/PCIe_Rj_Dj_BER_R1_{—}0.pdf
[29] G. H. Vergis, OR), “Integrated RAM thermal sensor,” U.S. Pat. No. 6,453,218, 2002.
[30] E. E. H. J. Davidson, NY), Bosco, Francis Edward (Poughkeepsie, N.Y.), Vakirtzis, Charles Kyriakos (New Windsor, N.Y.), “On-chip temperature sensing system,” U.S. Pat. No. 5,639,163, 1997.
[31] D. L. F. O. Hoff, Calif.), “MOS temperature sensing circuit,” U.S. Pat. No. 4,768,170, 1988.
[32] L. C. C. Delatorre, Houston, Tex., 77036), “Capacitive pressure sensor,” U.S. Pat. No. 4,322,775, 1982.
[33] J. E. P. V. Gragg Jr., AZ), “Silicon pressure sensor,” U.S. Pat. No. 4,317,126, 1982.
[34] Intel, “Mobile Intel Pentium 4 Processor-M Datasheet,” June 2003 2003.
[35] J. Clabes, et al., “Design and implementation of the POWER5™ microprocessor,” in Solid-State Circuits Conference, 2004. Digest of Technical Papers. ISSCC. 2004 IEEE International, 2004, pp. 56-57 Vol. 1.
[36] T. L. Floyd and D. Buchla, “Fundamentals of Analog Circuits,” 2nd edition ed: Prentice Hall, 2002, pp. 717-723, 734-737.
[37] R. J. v. d. Plassche, “CMOS Integrated Analog-to-Digital and Digital-to-Analog Converters,” in Analog Circuits and Signal Processing, 2nd ed: Kluwer Academic Publisher, 2003, pp. 1-4.
[38] W. Kester, “The Data Conversion Handbook,” ed: Elsevier: Newnes, 2005, pp. 147-259.
[39] P. R. Gray, et al., Analysis and Design of Analog Integrated Circuits, Fifth ed.: John Wiley & Sons, pages, 2009.
[40] R. Norman, et al., “An active reconfigurable circuit board,” in Circuits and Systems and TAISA Conference, 2008. NEWCAS-TAISA 2008. 2008 Joint 6th International IEEE Northeast Workshop on, 2008, pp. 351-354.
[41] T. Schiml, et al., “A 0.13 um CMOS platform with Cu/low-k interconnects for system on chip applications,” in VLSI Technology, 2001. Digest of Technical Papers. 2001 Symposium on, 2001, pp. 101-102.
[42] J. Becker, et al., “Adaptive systems-on-chip: architectures, technologies and applications,” in Integrated Circuits and Systems Design, 2001, 14th Symposium on., 2001, pp. 2-7.
[43] E. S. A. Snyder, NM), Campbell, David V. (Albuquerque, N. Mex.), “On-chip high frequency reliability and failure test structures,” U.S. Pat. No. 5,625,288, 1997.
[44] J. V. Muncy, et al., “Tracking Thermal Mini-Cycle Stress,” United State Patent, Application 20100049466.
[45] “International Technology Roadmap for Semiconductor (ITRS),” 2003.
[46] Q. Qinru, et al., “Dynamic power management of complex systems using generalized stochastic petri nets,” in Design Automation Conference, 2000. Proceedings 2000. 37th, 2000, pp. 352-356.
[47] O. Jaewon and M. Pedram, “Gated clock routing for low-power microprocessor design,” Computer-Aided Design of Integrated Circuits and Systems, IEEE Transactions on, vol. 20, pp. 715-722, 2001.
[48] R. Puri, et al., “Pushing ASIC performance in a power envelope,” in Design Automation Conference, 2003. Proceedings, 2003, pp. 788-793.
[49] A. Srivastava, et al., “Concurrent sizing, Vdd and Vth assignment for low-power design,” in Design, Automation and Test in Europe Conference and Exhibition, 2004. Proceedings, 2004, pp. 718-719 Vol. 1.
[50] J. Kao, et al., “Transistor Sizing Issues And Tool For Multi-threshold Cmos Technology,” in Design Automation Conference, 1997. Proceedings of the 34th, 1997, pp. 409-414.
[51] L. Changbo and H. Lei, “Distributed sleep transistor network for power reduction,” Very Large Scale Integration (VLSI) Systems, IEEE Transactions on, vol. 12, pp. 937-946, 2004.
[52] P. E. Gronowski, et al., “High-performance microprocessor design,” Solid-State Circuits, IEEE Journal of, vol. 33, pp. 676-686, 1998.
[53] “IEEE Standard Test Access Port and Boundary-Scan Architecture,” IEEE Std 1149.1-2001, pp. i-200, 2001.
[54] B. Eklow, et al., “IEEE 1149.6-A Practical Perspective,” presented at the International Test Conference (ITC), Charlotte, N.C., USA, 2003.
[55] “IEEE Standard for Reduced-Pin and Enhanced-Functionality Test Access Port and Boundary-Scan Architecture,” IEEE Std 1149.7-2009, pp. c1-985, 2010.
[56] “IEEE Standard Testability Method for Embedded Core-Based Integrated Circuits,” IEEE Std 1500-2005, pp. 0_{—}1-117, 2005.

1. An integrated circuit system interconnect device having an integrated circuit substrate comprising:
surface contacts for making direct contact with contacts of a plurality of integrated circuit components to interconnect said components to form said system;
wherein said substrate comprises support circuitry serving said components, said support circuitry comprising at least one of:
one or more voltage regulators provided within said substrate for receiving source power and delivering a voltage level to at least one of said surface contacts for delivering power to ones of said contacts of said plurality of integrated circuit components;
an array of heat transfer blocks distributed over and coupled to one surface of said substrate to draw heat from said substrate while allowing said substrate to expand and contract due to temperature variations during operation and storage without compromising mechanical and electrical integrity of said system, wherein another surface of said substrate comprises said surface contacts for interconnecting said plurality of components;
a distributed differential signal pair switch matrix permitting a selected one of said surface contacts to be paired with a selected one of a plurality of other ones of said surface contacts to support differential signaling;
distributed signal measurement circuitry for determining one or more of: power drawn; voltage level drops; current levels drawn; and signal integrity at at least some of said surface contacts;
one or more clock or reset trees;
analog circuitry for supporting substantially analog functions;
analog-to-digital (ADC) or digital-to-analog (DAC) circuits;
one or more trimmable analog components;
test circuitry to perform testing of circuitry;
at least one controller and circuitry permitting the controller to perform configuring of circuitry through said surface contacts; and
thermal and/or mechanical stress sensors distributed within said substrate.

2. The system as claimed in claim 1, wherein said voltage regulators comprise a number of voltage regulators distributed within said substrate for delivering regulated voltage where needed to said surface contacts.

3. The system as claimed in claim 2, wherein said voltage regulators are programmable, further comprising one or more power feed conductive paths for transporting external power, wherein said surface contacts are provided on a first surface of said substrate, said power feed conductive paths comprise contacts distributed over a second surface of said substrate that connect to said substrate to deliver power to said programmable voltage regulators.

4. The system as claimed in claim 3, further comprising passive devices mounted to said second surface in proximity to said contacts distributed over said second surface of said substrate.

5. The system as claimed in claim 4, wherein said passive devices are included in one or more power supply blocks connected to said contacts distributed over said second surface of said substrate and said power supply blocks having:
one or more power signal inputs; and
one or more configurable power regulator units working with said passive devices to deliver a desired power profile to said second surface contacts.

6. The system as claimed in claim 4, wherein said power supply blocks are integrated into said array of heat transfer blocks.

7. The system as claimed in claim 1, comprising said voltage regulators and said signal measurement circuitry, wherein said signal measurement circuitry is integrated with said voltage regulators.

8. The system as claimed in claim 1, comprising said heat transfer blocks, wherein said heat transfer blocks are provided in a rectangular array with spacing between said blocks.

9. The system as claimed in claim 1, comprising said heat transfer blocks, wherein said heat transfer blocks encapsulate power supply circuit components.

10. The system as claimed in claim 1, comprising said test circuitry, said test circuitry comprising one or more of test controllers, and a fault-tolerant cell architecture comprising cells distributed over said substrate, wherein said cells each comprise at least one of said test controllers.

11. The system as claimed in claim 10, wherein said test controllers are configured to have a field-programmable variable length scan chain path.

12. The system as claimed in claim 1, wherein said test circuitry comprises one or more test controllers.

13. The system as claimed in claim 12, wherein said test controllers are configured to perform substantially at the same time more than one test.

14. The system as claimed in claim 1, wherein said test circuitry comprises one or more self-test circuitry.

15. The system as claimed in claim 14, wherein said self-test circuitry is configured to perform a built-in self test of circuitry within said substrate.

16. The system as claimed in claim 14, wherein said self-test circuitry is configured to perform a built-in self test of circuitry external to said substrate and connected to said surface contacts.

17. The system as claimed in claim 1, comprising said test circuitry, wherein said test circuitry comprises a hardware assertion module.

18. The system as claimed in claim 1, comprising said thermal and/or mechanical stress sensors, further comprising a transient thermo-mechanical peak stress monitoring and prediction unit.

19. The system as claimed in claim 1, comprising said thermal and/or mechanical stress sensors, wherein said sensors comprise stress sensors, further comprising:
a pressure applicator for pressing components onto said first surface of said substrate; and
a stress analyzer connected to said stress sensors for determining if pressure applied to said components is uneven and/or at risk of causing damage to said components and/or said substrate.

20. The system as claimed in claim 1, comprising said distributed signal measurement circuitry.

21. The system as claimed in claim 20, wherein said signal measurement circuitry is integrated with said test circuitry.

22. The system as claimed in claim 20, wherein said signal measurement circuitry measures signal integrity.

23. The system as claimed in claim 20, wherein said signal measurement circuitry measures power drawn by said components.

24. The system as claimed in claim 1, comprising said distributed differential signal pair switch matrix.

25. The system as claimed in claim 24, comprising a differential amplifier selectably connectable to said differential pairs.

26. The system as claimed in claim 1, wherein said system is programmable, said system comprising:
at least one interconnect switch matrix for interconnecting said surface contacts as programmed for analog and/or digital signal transmission; and
a power supply comprising one or more power feed conductive paths for transporting external power.

27. The system as claimed in claim 1, wherein said substrate is singulated from a wafer and corresponds to an area of a single integrated circuit fabrication image field.

28. The system as claimed in claim 1, wherein said substrate is a large-area integrated circuit.

29. The system as claimed in claim 28, further comprising a pressure applicator for pressing components onto said surface contacts of said substrate.

30. The system as claimed in claim 1, wherein said surface contacts comprise alignment-insensitive contacts.

31. The system as claimed in claim 1, further comprising a compliant Z-axis film for improving electrical contact between said surface contacts and corresponding contacts of said integrated circuit component.

32. The system as claimed in claim 1, comprising said clock or reset trees.

33. The system as claimed in claim 32, further comprising fault tolerant interconnect circuitry between at least some of said clock or reset trees.

34. The system as claimed in claim 26, comprising one or more said ADC, wherein a digital output of said ADC is propagated through the interconnect switch matrix.

35. The system as claimed in claim 26, comprising one or more said DAC, wherein signals propagated through said interconnect switch matrix are converted to analog through said DAC.

36. The system as claimed in claim 1, comprising said trimmable analog components.

37. The system as claimed in claim 1, wherein said substrate is an interposer placed between integrated circuit components, said surface contacts being provided on a top surface and a bottom surface of said substrate.

38. The system as claimed in claim 37, wherein two or more of said substrates are provided in said system for stacking three or more integrated circuit components.

39. The system as claimed in claim 38, wherein two or more of said substrates are provided in said system with said substrates partly overlapping and stacked to allow said system to be layered and to spread out laterally, said substrates making direct contact between themselves.

40. The system as claimed in claim 37, wherein power supply is wire bonded to said substrate.

41. The system as claimed in claim 37, wherein test output data are communicated from said substrate without passing through said integrated circuit components.

42. The system as claimed in claim 37, wherein said system is packaged as a single component.

43. A method of manufacturing an integrated circuit system comprising a plurality of integrated circuit components, the method comprising:
using circuit design software tool and a programmable system as claimed in claim 26 to prototype said integrated circuit system and to generate a printed circuit board design for said components;
providing a printed circuit board according to said design;
assembling said integrated circuit system using said printed circuit board and said components.

44. A method of manufacturing an integrated circuit system comprising a plurality of integrated circuit components, the method comprising:
using circuit design software tool and a programmable system as claimed in claim 37, wherein said interposer is programmable, to prototype said integrated circuit system and to generate a non-programmable interposer design for said components;
providing a non-programmable interposer according to said design;
assembling said integrated circuit system using said non-programmable interposer and said components.

45. An integrated circuit substrate comprising:
surface contacts for making contacts with a plurality of integrated circuit components;
wherein some surface contacts receive and process external data from said surface contacts and drive some other surface contacts with processing results;
wherein said substrate comprises support circuitry serving said components, said support circuitry comprising at least one of:
one or more voltage regulators provided within said substrate for receiving source power and delivering a voltage level to at least one of said surface contacts for delivering power to ones of said contacts of said plurality of integrated circuit components;
a distributed differential signal pair switch matrix permitting a selected one of said surface contacts to be paired with a selected one of a plurality of other ones of said surface contacts to support differential signaling;
distributed signal measurement circuitry for determining one or more of:
power drawn; voltage level drops; current levels drawn; and signal integrity at at least some of said surface contacts;
analog circuitry for supporting substantially analog functions;
analog-to-digital (ADC) or digital-to-analog (DAC) circuits;
test circuitry to perform testing of circuitry;
at least one controller and circuitry permitting the controller to perform configuring of circuitry.

46. The system as claimed in claim 45, wherein said voltage regulators comprise a number of voltage regulators distributed within said substrate for delivering regulated voltage where needed to said surface contacts.

47. The system as claimed in claim 46, wherein said voltage regulators are programmable, further comprising one or more power feed conductive paths for transporting external power up to these voltage regulators.

48. The system as claimed in claim 45, comprising said voltage regulators and said signal measurement circuitry, wherein said signal measurement circuitry is integrated with said voltage regulators.

49. The system as claimed in claim 45, comprising said test circuitry, wherein said test circuitry comprises a hardware assertion module.

50. The system as claimed in claim 45, comprising said distributed signal measurement circuitry.

51. The system as claimed in claim 50, wherein said signal measurement circuitry is integrated with said test circuitry.

52. The system as claimed in claim 50, wherein said signal measurement circuitry measures signal integrity.

53. The system as claimed in claim 50, wherein said signal measurement circuitry measures power drawn by said components.

54. The system as claimed in claim 45, comprising said distributed differential signal pair switch matrix.

55. The system as claimed in claim 54, comprising a differential amplifier selectably connectable to said differential pairs.

56. The system as claimed in claim 45, wherein said system is programmable, said system comprising:
at least one interconnect switch matrix for interconnecting said surface contacts as programmed for analog and/or digital signal transmission; and
a power supply comprising one or more power feed conductive paths for transporting external power.

57. The system as claimed in claim 45 comprising one or more said ADC, wherein a digital output of said ADC is propagated through the interconnect switch matrix.

58. The system as claimed in claim 45, comprising one or more said DAC, wherein signals propagated through said interconnect switch matrix are converted to analog through said DAC.
